(19) United States
(12) Patent Application Publication
(10) Pub. No.: US 2025/0294894 A1
(43) Pub. Date: Sep. 18, 2025

(54) TVS DIODE

(71) Applicant: ROHM CO., LTD., Kyoto-shi, (JP)

(72) Inventors: Keishi WATANABE, Kyoto-shi, (JP); Kentaro WAKI, Kyoto-shi, (JP); Satoki TANIGUCHI, Kyoto-shi, (JP); Kohei MORITA, Kyoto-shi, (JP)

(73) Assignee: ROHM CO., LTD., (omitted)

(21) Appl. No.: 19/078,701

(22) Filed: Mar. 13, 2025

(30) Foreign Application Priority Data
Mar. 18, 2024 (JP) 2024-042497

(51) Int. Cl. H10D 89/60; H10D 8/00; H10D 8/50; H10D 62/10; H10D 84/00

(52) U.S. Cl. CPC H10D 89/611; H10D 8/411; H10D 8/50; H10D 62/126; H10D 84/221

(57) ABSTRACT

A semiconductor chip of a TVS diode includes a first pin junction portion of a first polarity direction and a diode pair region. The diode pair region includes a first reverse pin junction portion of a second polarity direction provided spaced apart from the first pin junction portion in a plan view, and a pn junction portion of the first polarity direction that forms a diode pair with the first reverse pin junction portion. The first pin junction portion includes a p-type first-terminal-side high-concentration region, an n-type first-terminal-side low-concentration region at a position overlapping the first-terminal-side high-concentration region in the plan view, an n-type first-terminal-side contact region, and a p-type first buffer region in contact with the first-terminal-side high-concentration region between the first-terminal-side high-concentration region and the first-terminal-side low-concentration region in a thickness direction of the semiconductor chip.

### CROSS-REFERENCE TO RELATED APPLICATION

This application is based upon and claims the benefit of priority from Japanese Patent Application No. 2024-042497, filed on Mar. 18, 2024, the entire contents of which are incorporated herein by reference.

### TECHNICAL FIELD

The present disclosure relates to a TVS diode.

### BACKGROUND

Patent document 1 discloses a diode chip including a TVS (Transient Voltage Suppressor) circuit.

### PRIOR ART DOCUMENT

### Patent Publication

[Patent document 1] Japan Patent Publication No. 2021-57490.

### BRIEF DESCRIPTION OF THE DRAWINGS

FIG. 1 is a schematic plan view of an exemplary TVS diode according to a first embodiment.

FIG. 2 is a schematic cross-sectional view of the TVS diode taken along line F2-F2 in

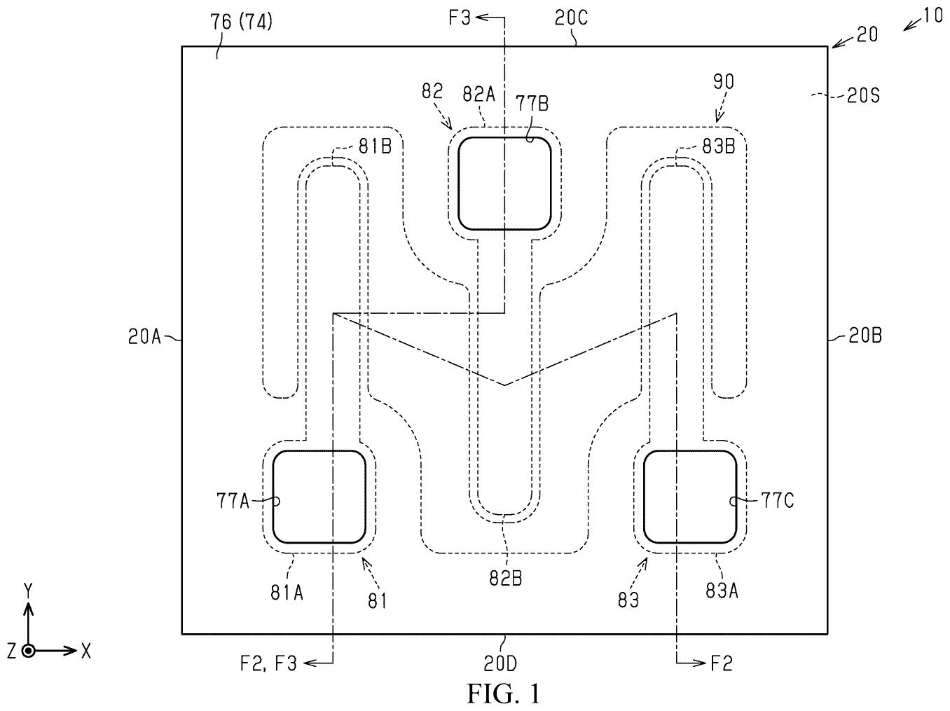

FIG. 1.

FIG. 3 is a schematic cross-sectional view of the TVS diode taken along line F3-F3 in FIG. 1.

FIG. 4 is a schematic plan view of a semiconductor chip.

FIG. 5 is a schematic cross-sectional view of the TVS diode taken along line F5-F5 in FIG. 3.

FIG. 6 is a schematic cross-sectional view that enlarges a portion of FIG. 5.

FIG. 7 is a schematic plan view of first to third connection electrodes and a wiring provided on a semiconductor chip.

FIG. 8 is a schematic circuit diagram of a TVS diode.

FIG. 9 is a schematic cross-sectional view illustrating an exemplary manufacturing process of the TVS diode of the first embodiment.

FIG. 10 is a schematic cross-sectional view showing a manufacturing process subsequent to the process shown in FIG. 9.

FIG. 11 is a schematic cross-sectional view showing a manufacturing process subsequent to the process shown in FIG. 10.

FIG. 12 is a schematic cross-sectional view showing a manufacturing process subsequent to the process shown in FIG. 11.

FIG. 13 is a schematic cross-sectional view showing a manufacturing process subsequent to the process shown in FIG. 12.

FIG. 14 is a schematic cross-sectional view showing a manufacturing process subsequent to the process shown in FIG. 13.

FIG. 15 is a schematic cross-sectional view showing a manufacturing process subsequent to the process shown in FIG. 14.

FIG. 16 is a schematic cross-sectional view showing a manufacturing process subsequent to the process shown in FIG. 15.

FIG. 17 is a schematic cross-sectional view showing a manufacturing process subsequent to the process shown in FIG. 16.

FIG. 18 is a schematic cross-sectional view showing a manufacturing process subsequent to the process shown in FIG. 17.

FIG. 19 is a schematic cross-sectional view showing a manufacturing process subsequent to the process shown in FIG. 18.

FIG. 20 is a schematic cross-sectional view showing a manufacturing process subsequent to the process shown in FIG. 19.

FIG. 21 is a schematic cross-sectional view showing a manufacturing process subsequent to the process shown in FIG. 20.

FIG. 22 is a schematic cross-sectional view showing a manufacturing process subsequent to the process shown in FIG. 21.

FIG. 23 is a schematic cross-sectional view showing a manufacturing process subsequent to the process shown in FIG. 22.

FIG. 24 is a schematic cross-sectional view showing a manufacturing process subsequent to the process shown in FIG. 23.

FIG. 25 is a schematic cross-sectional view showing a manufacturing process subsequent to the process shown in FIG. 24.

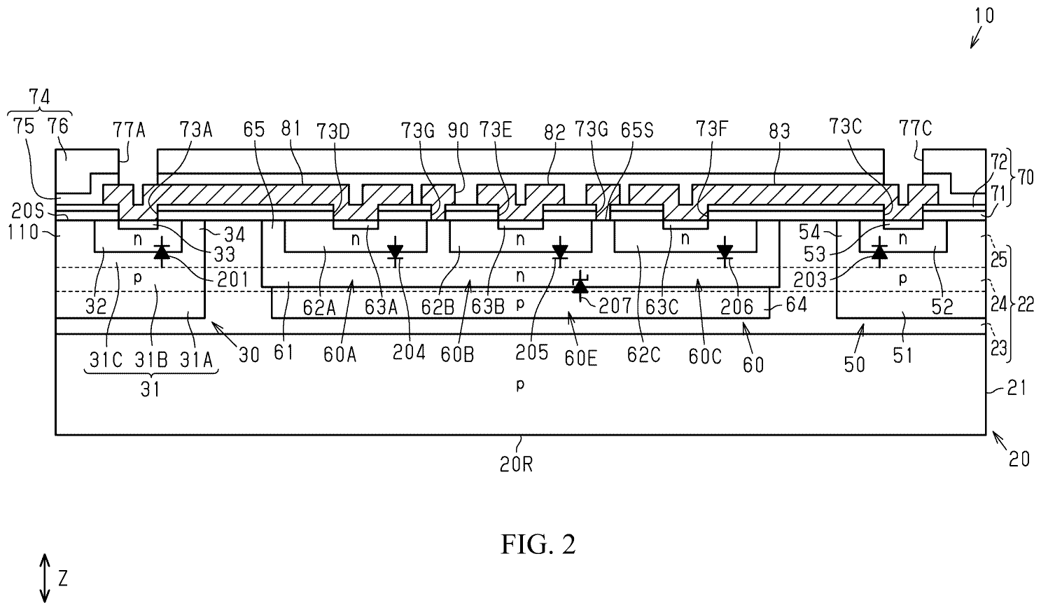

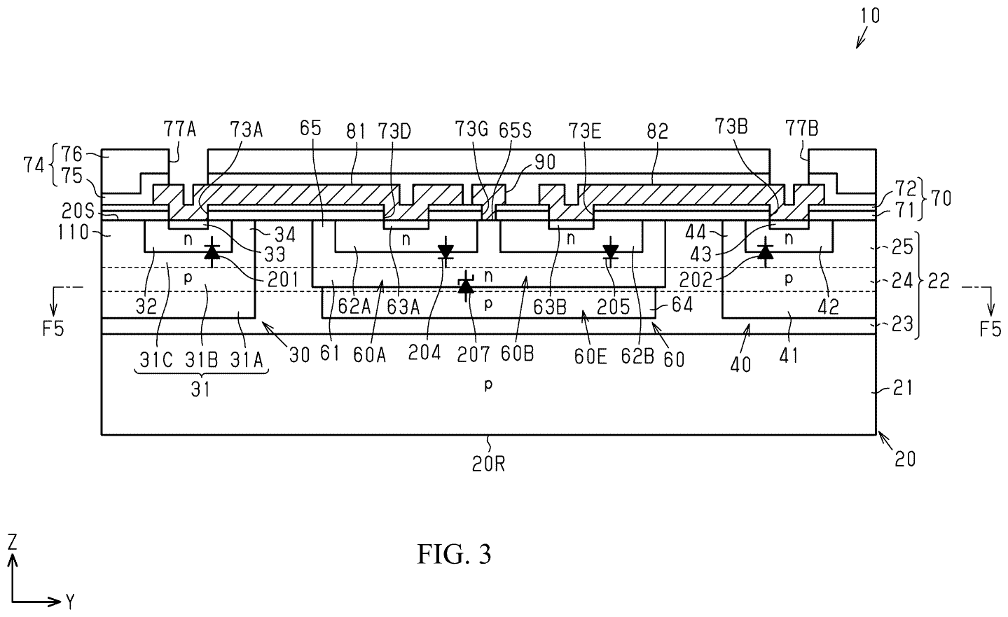

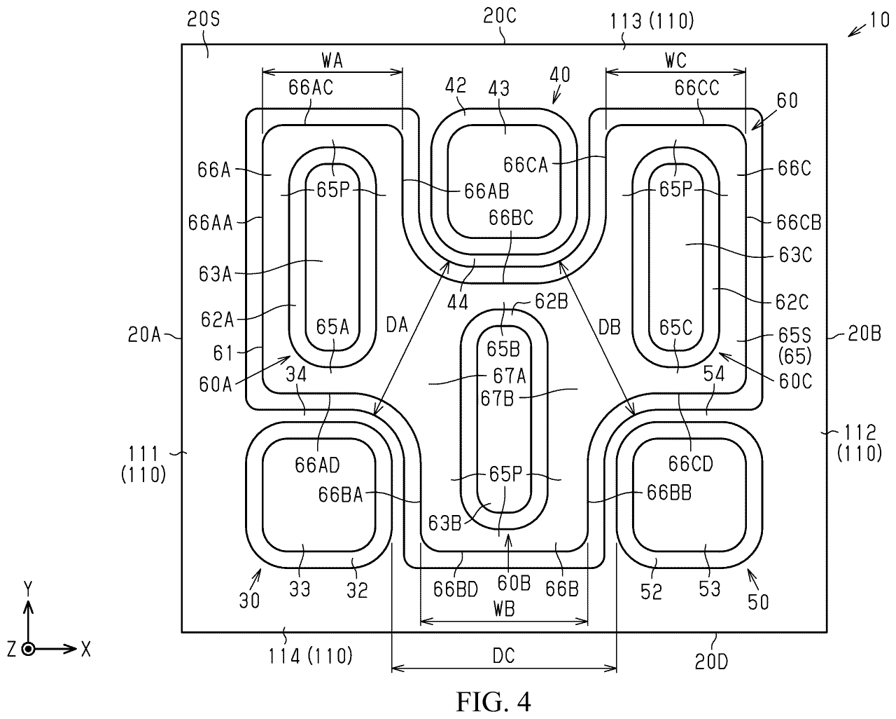

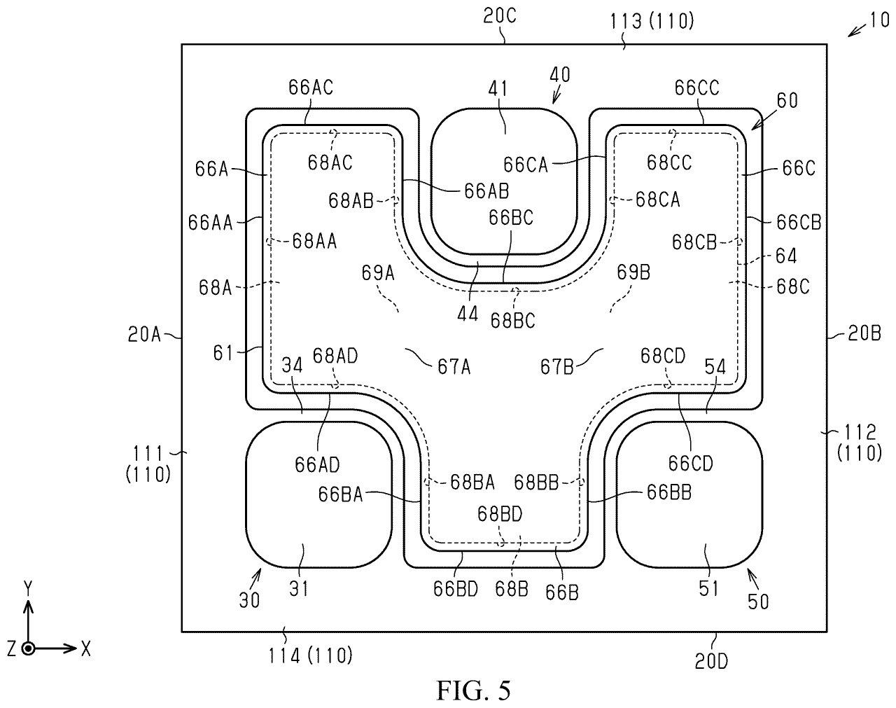

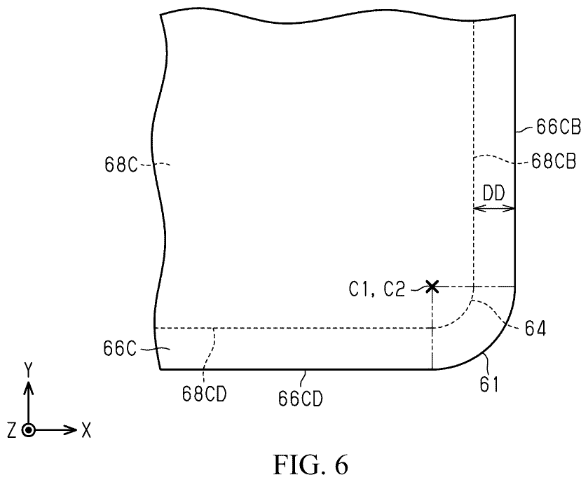

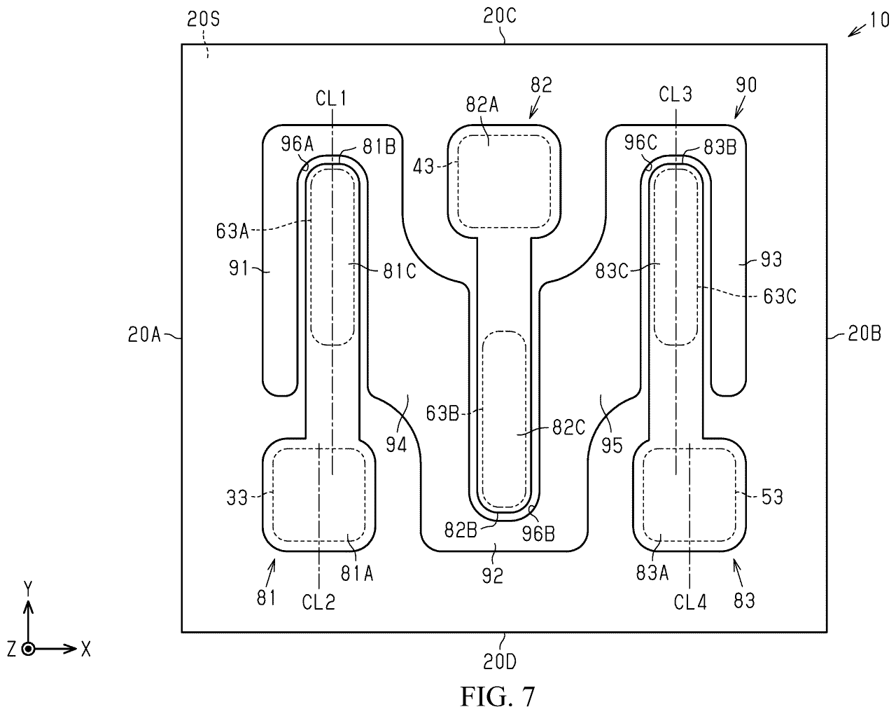

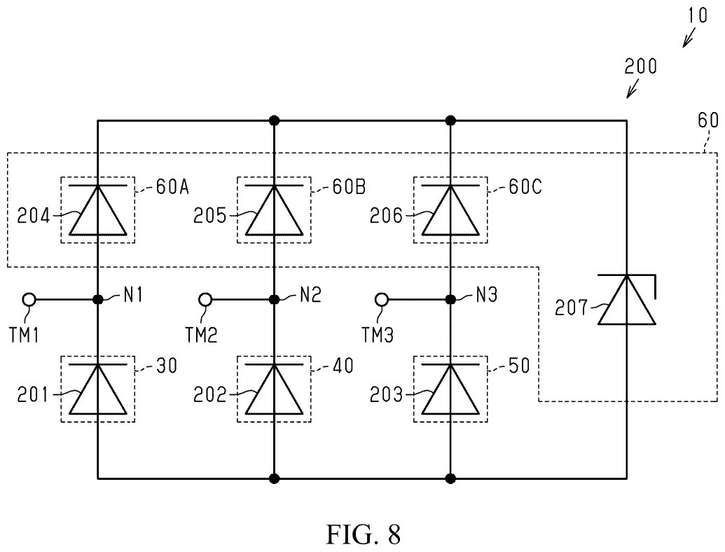

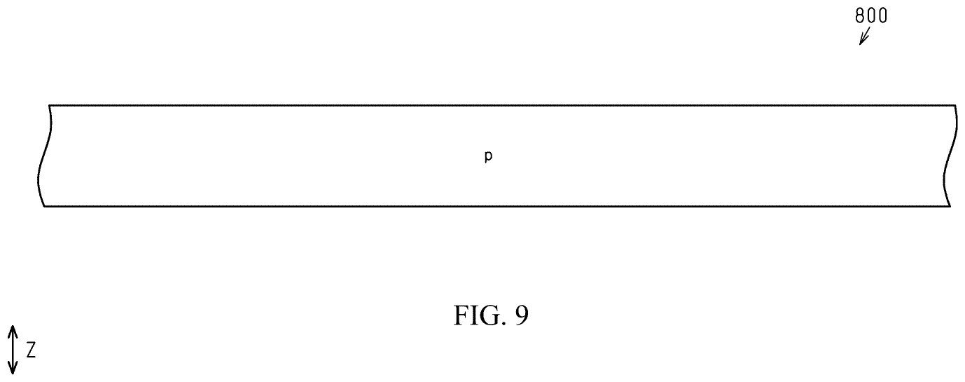

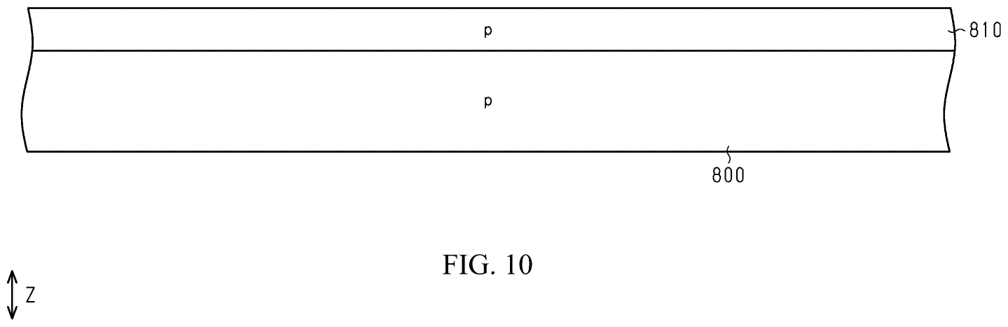

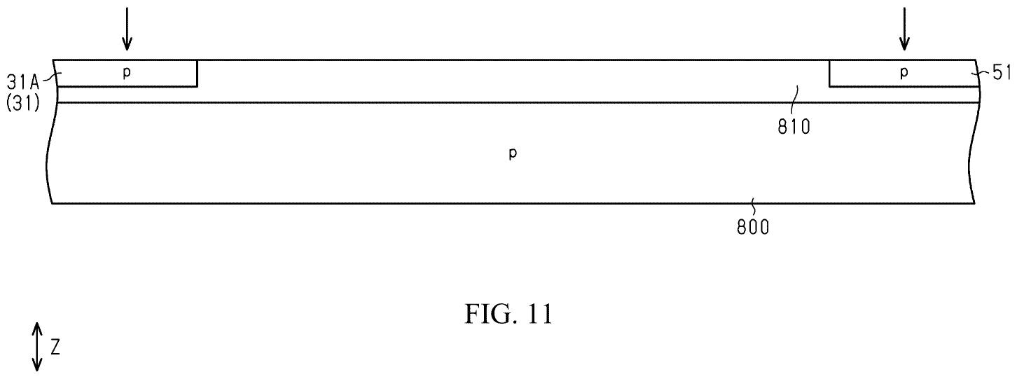

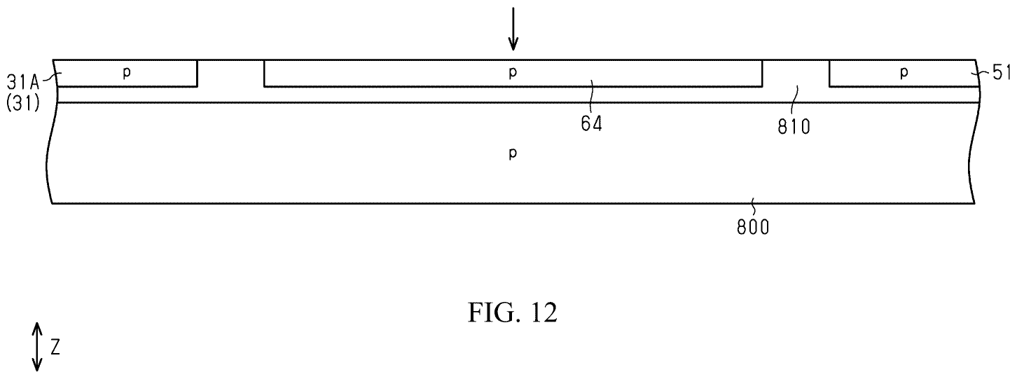

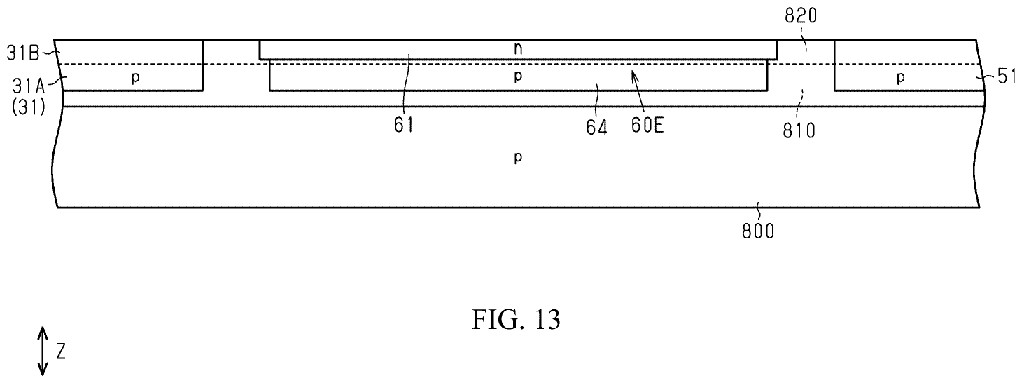

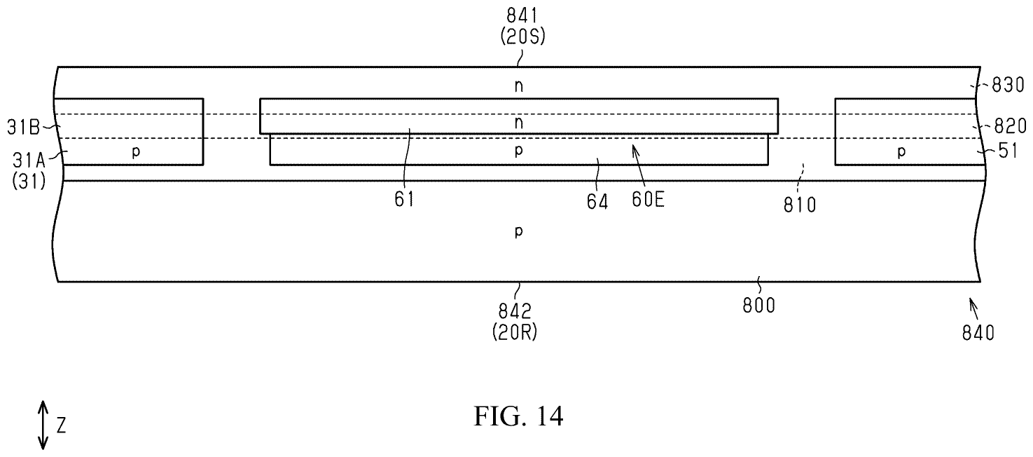

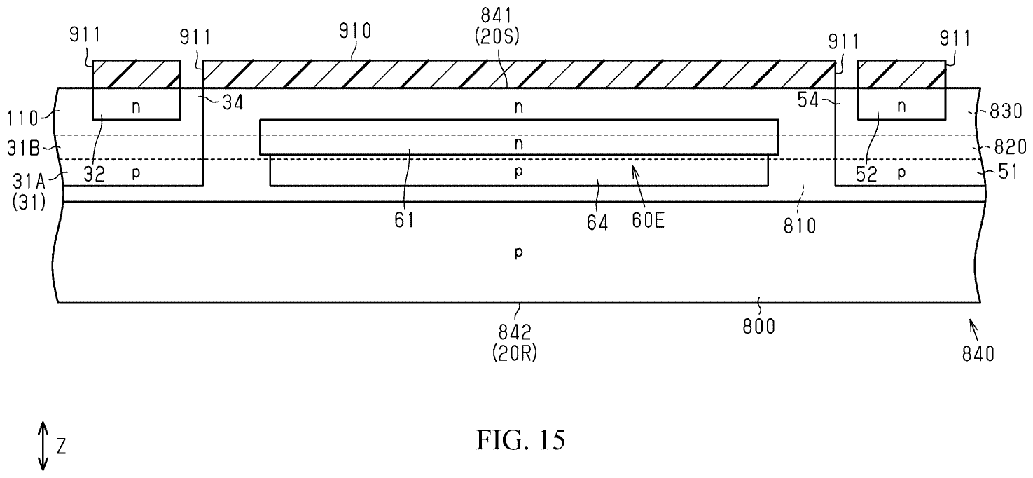

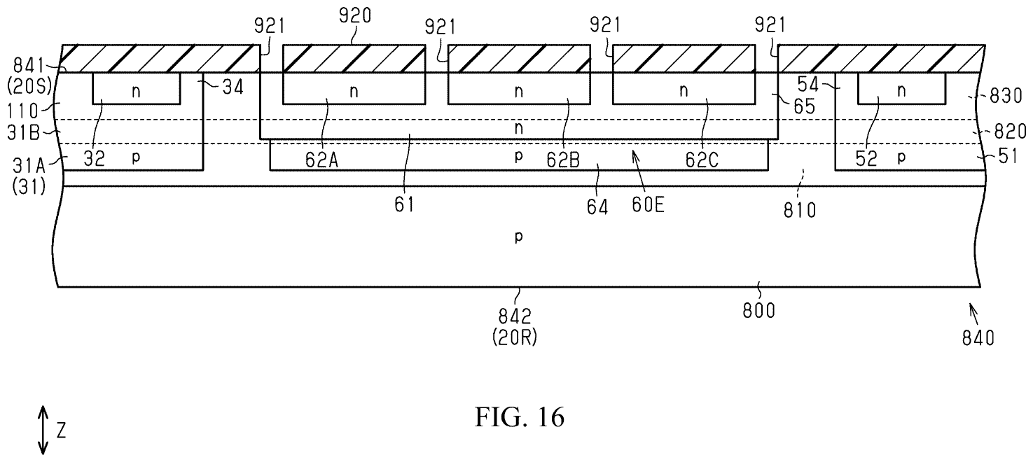

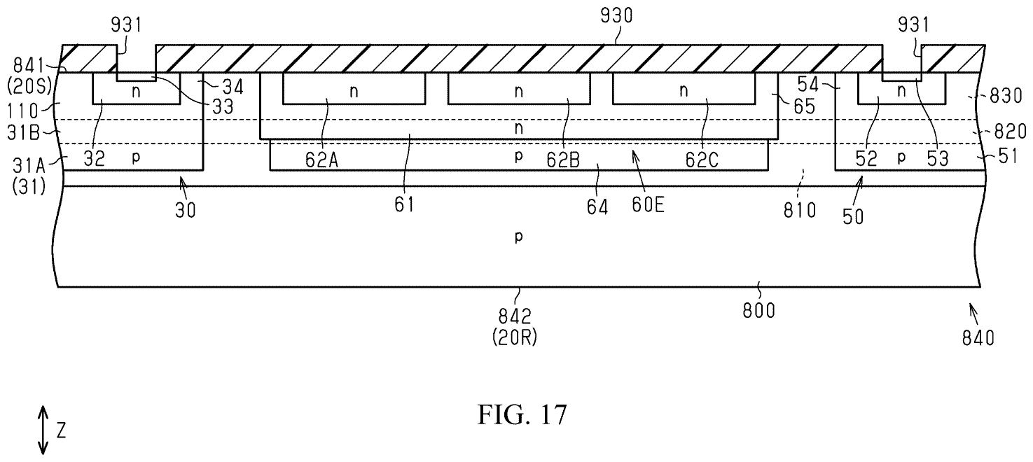

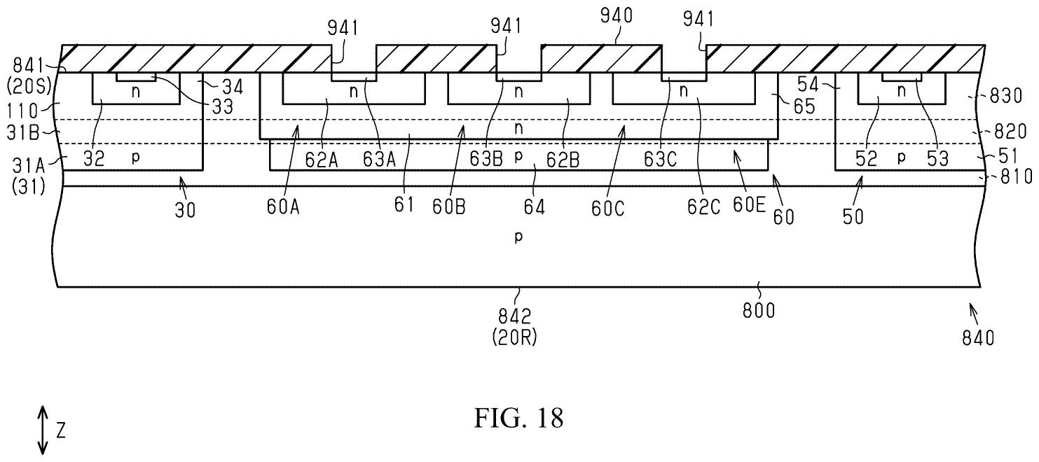

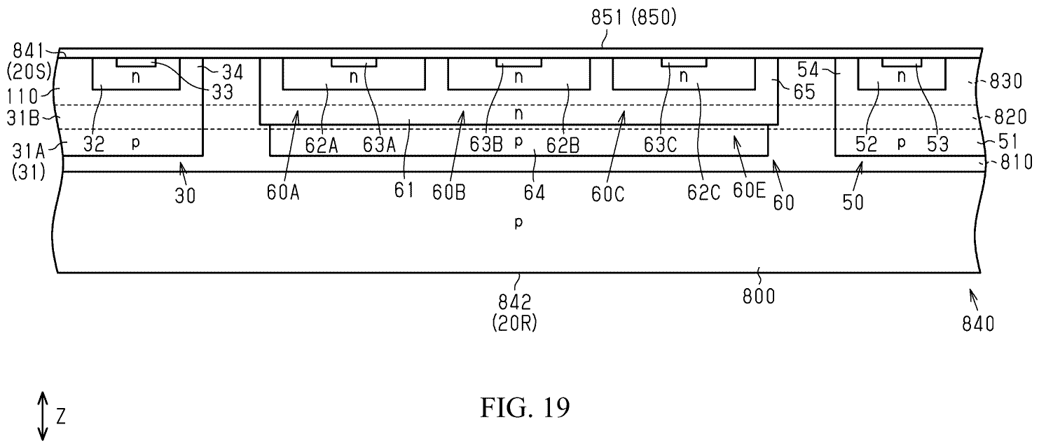

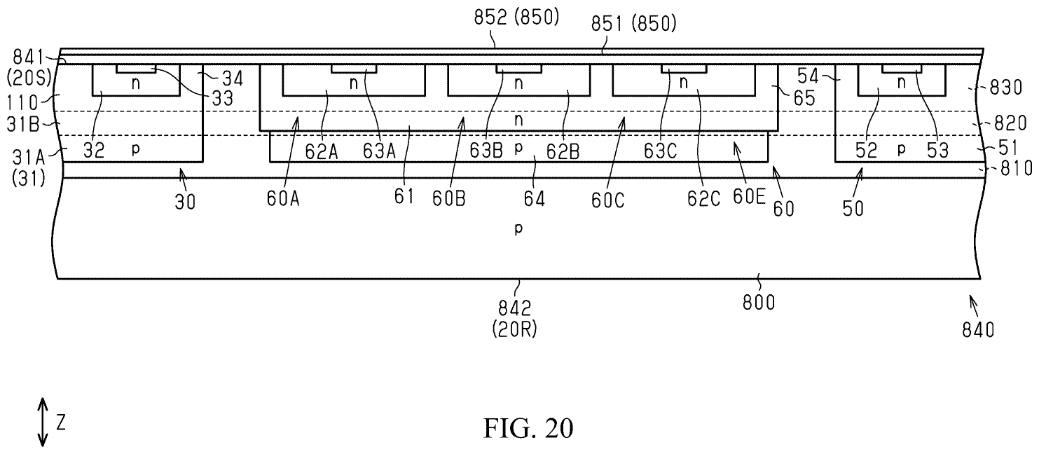

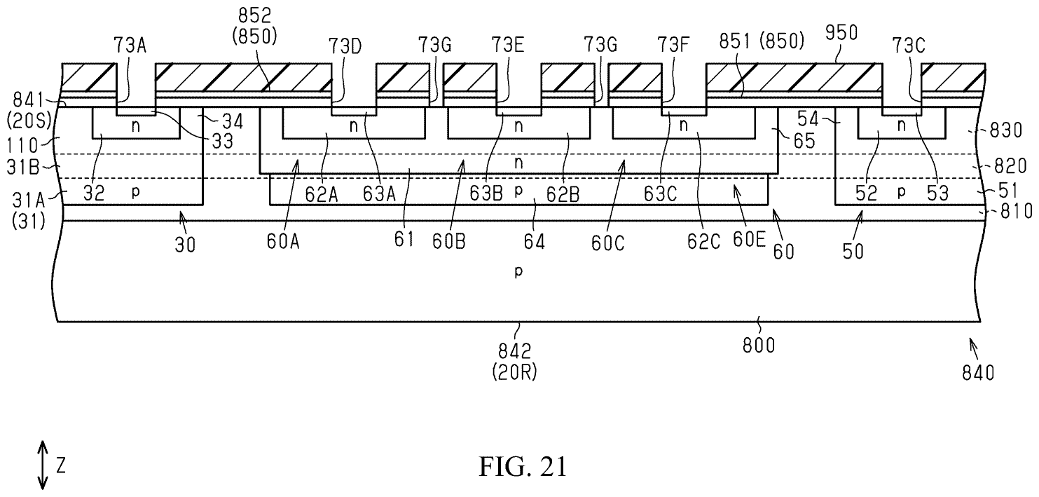

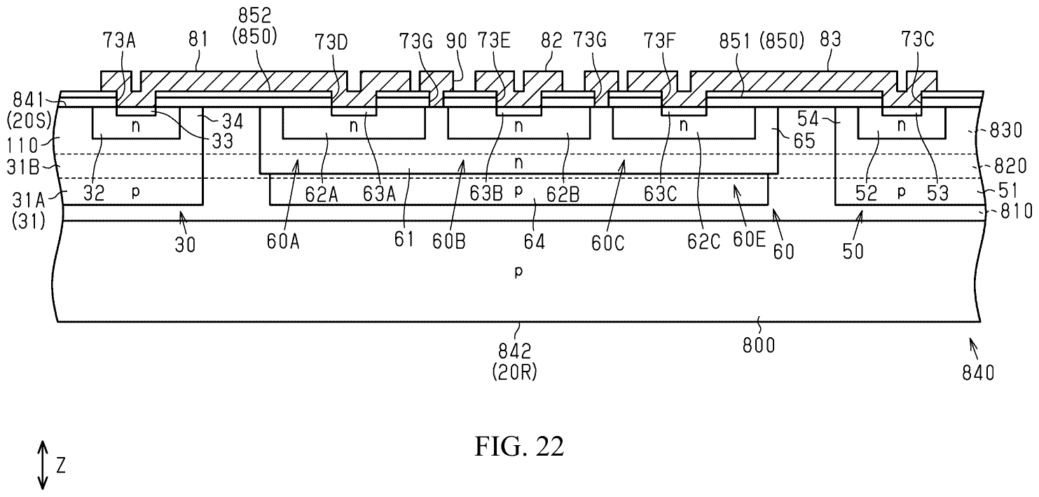

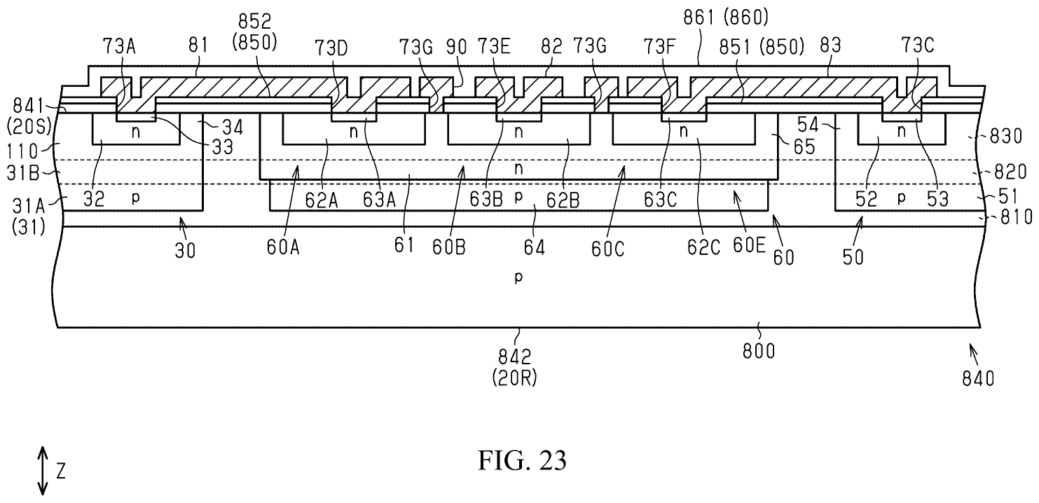

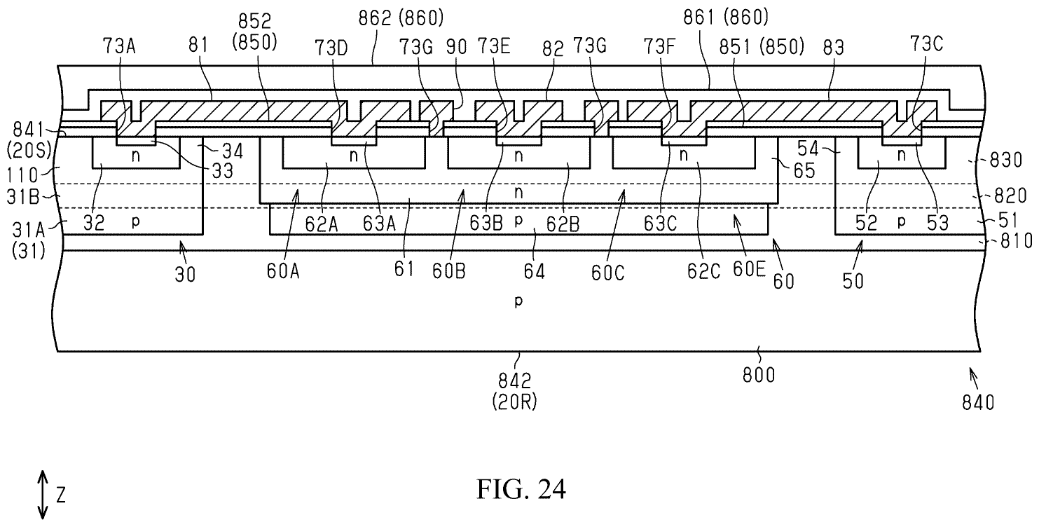

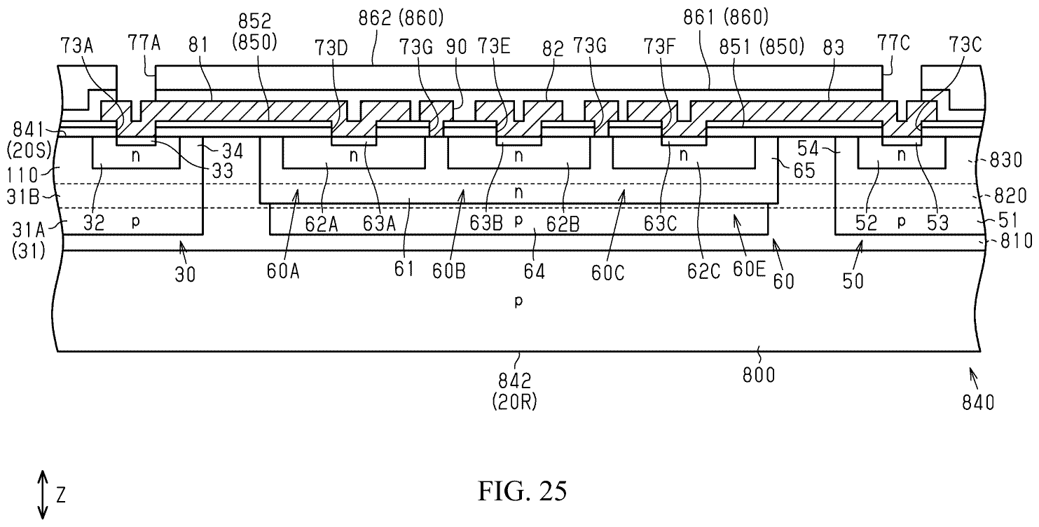

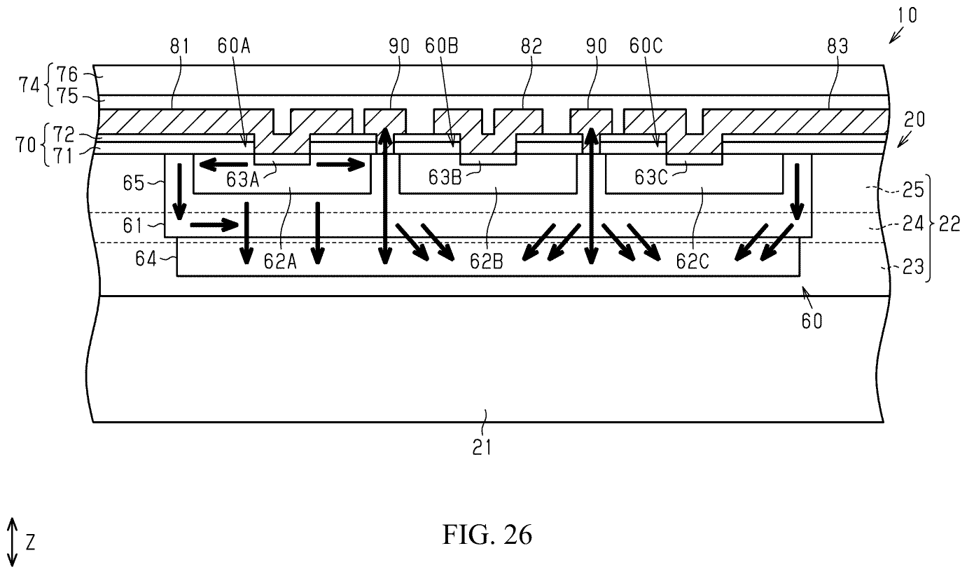

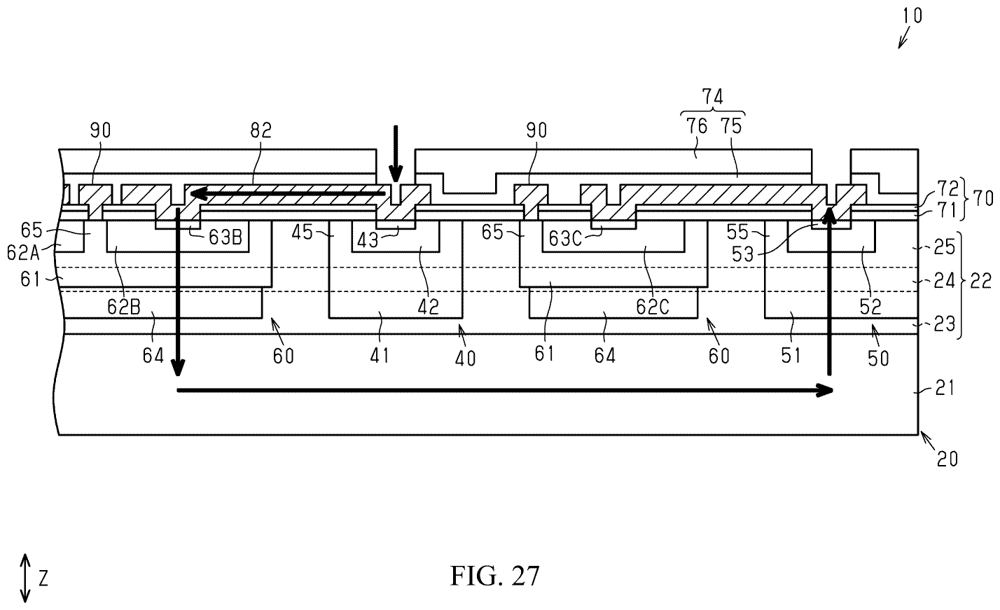

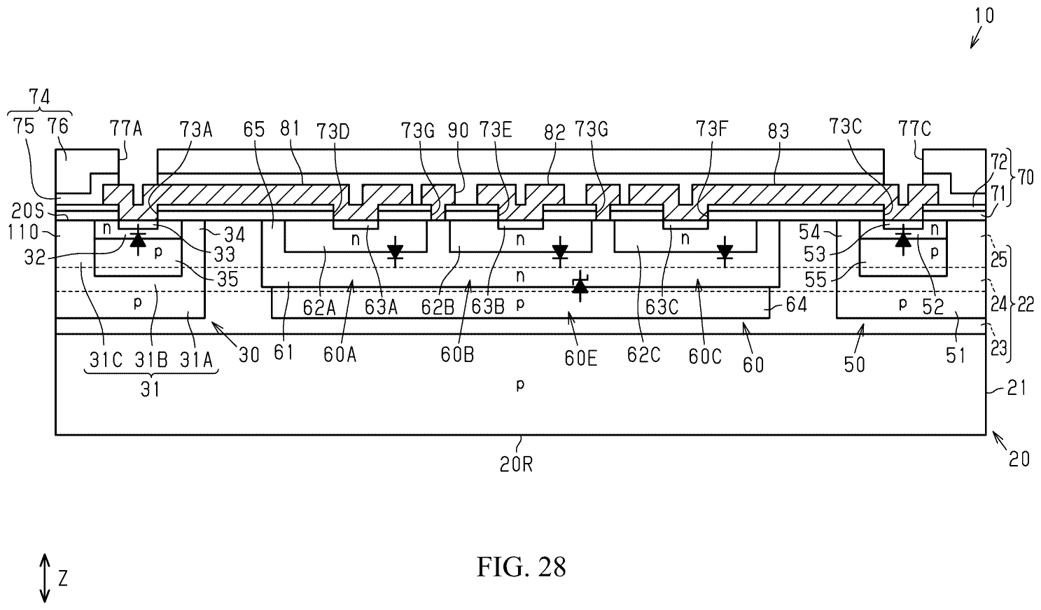

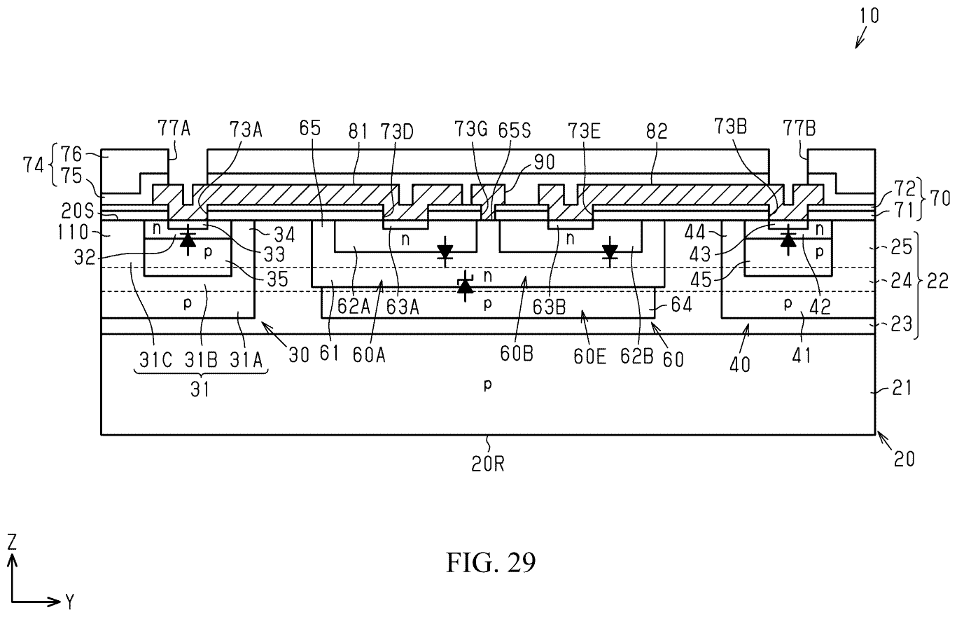

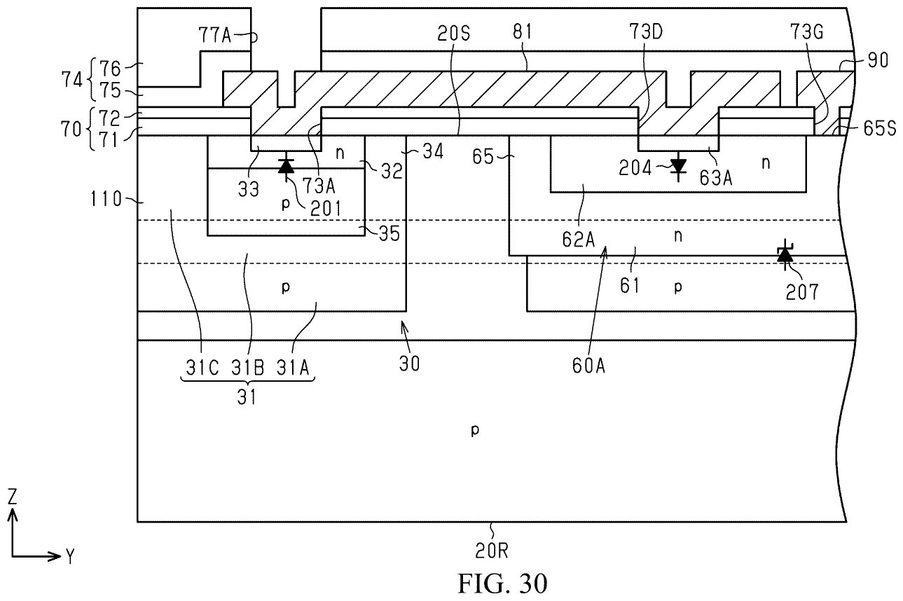

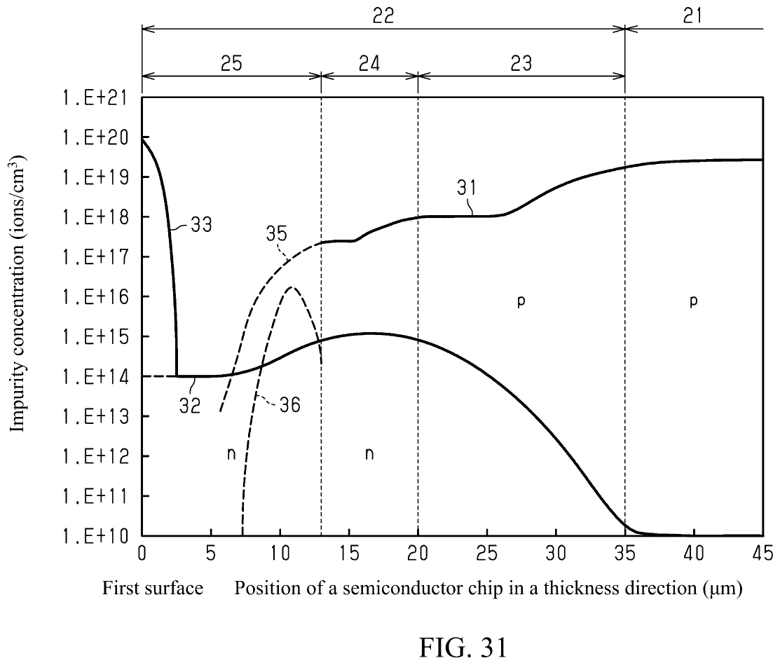

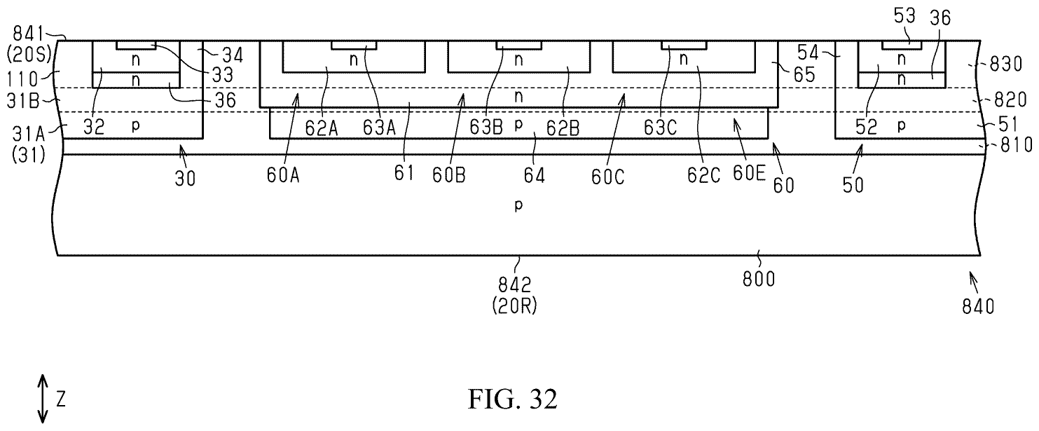

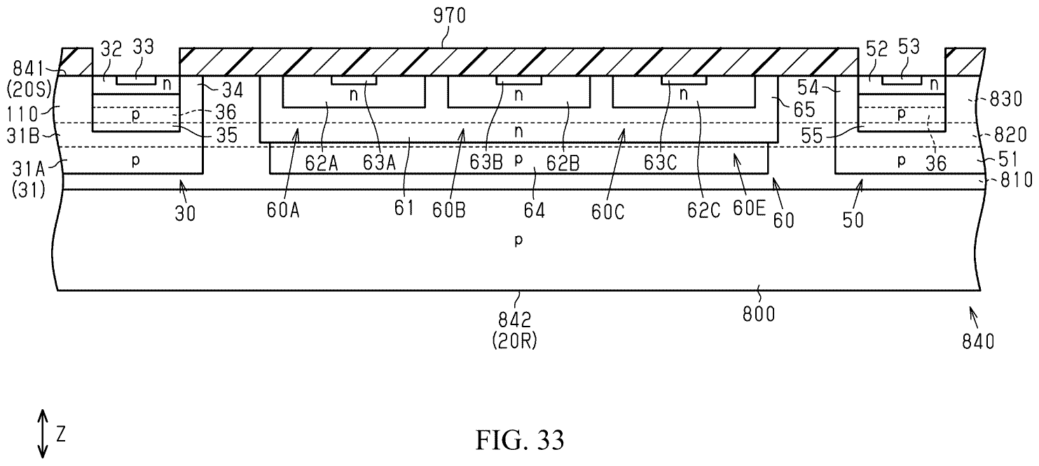

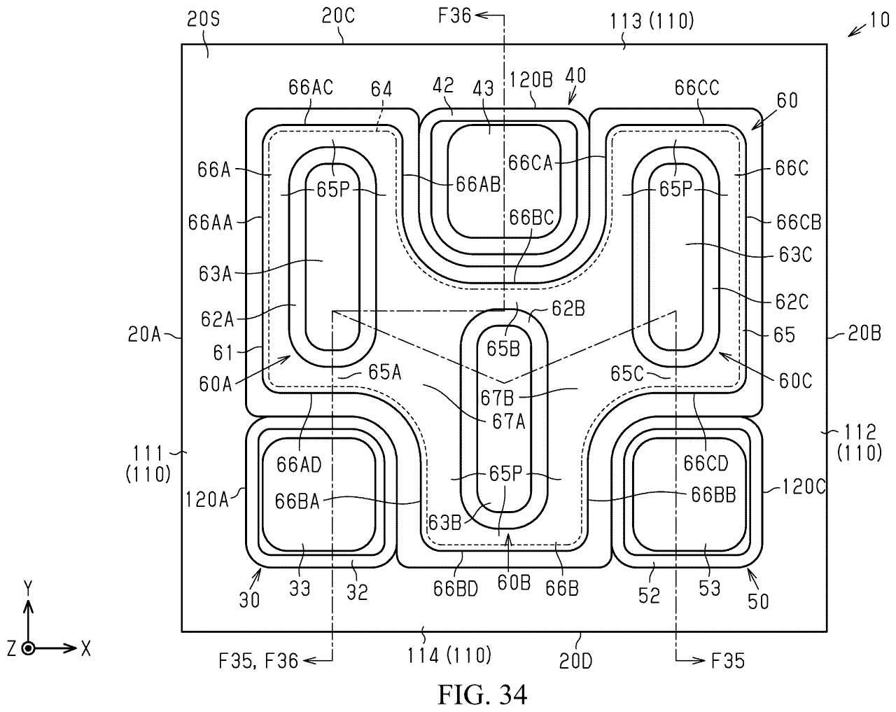

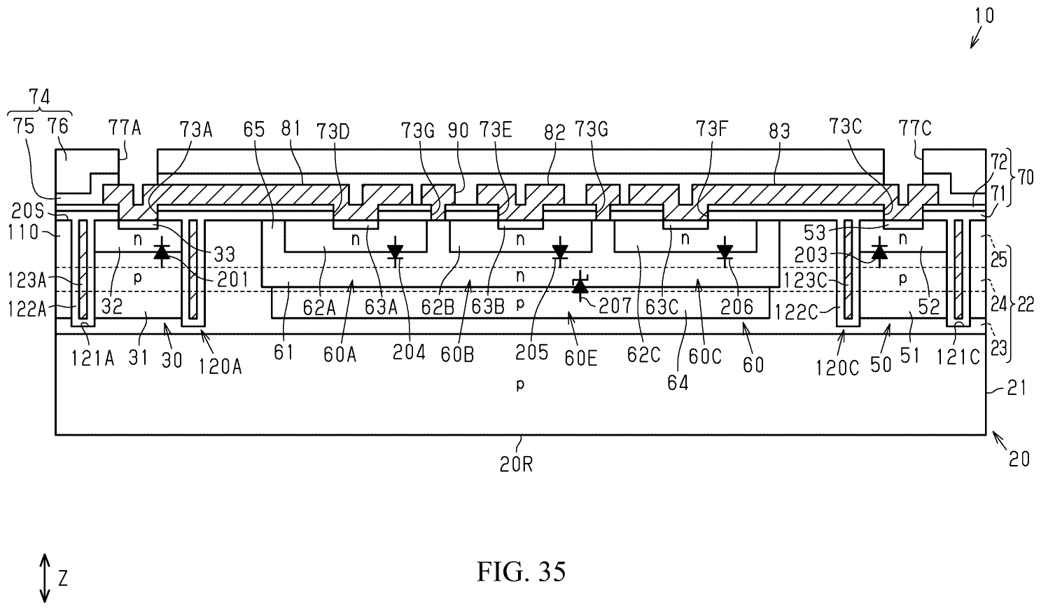

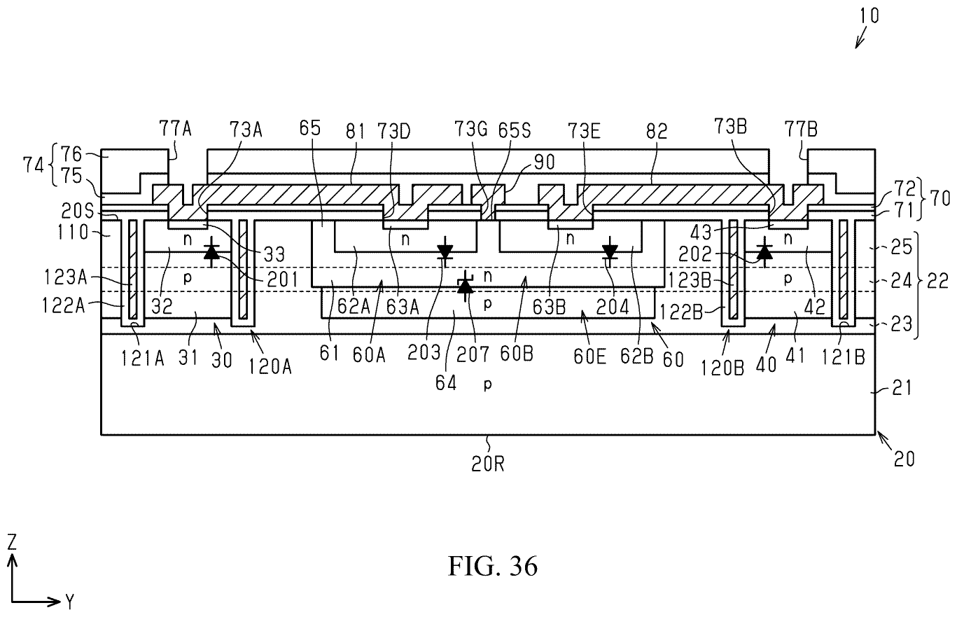

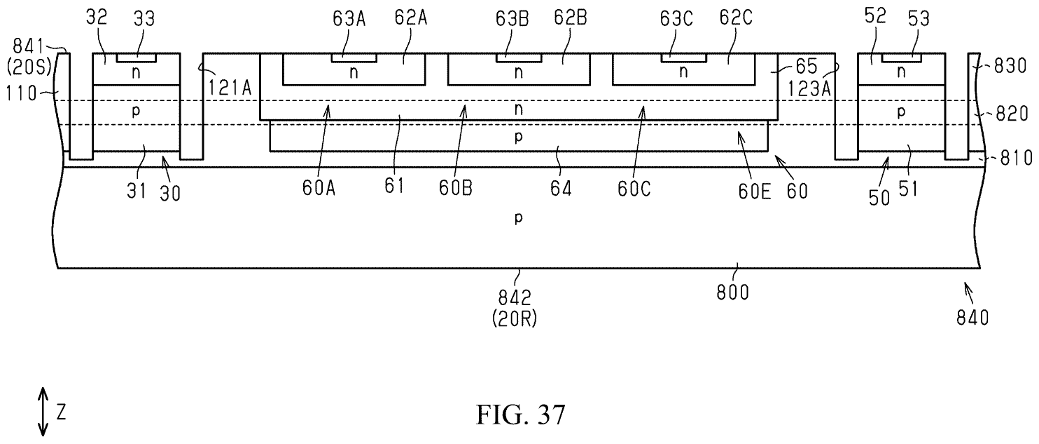

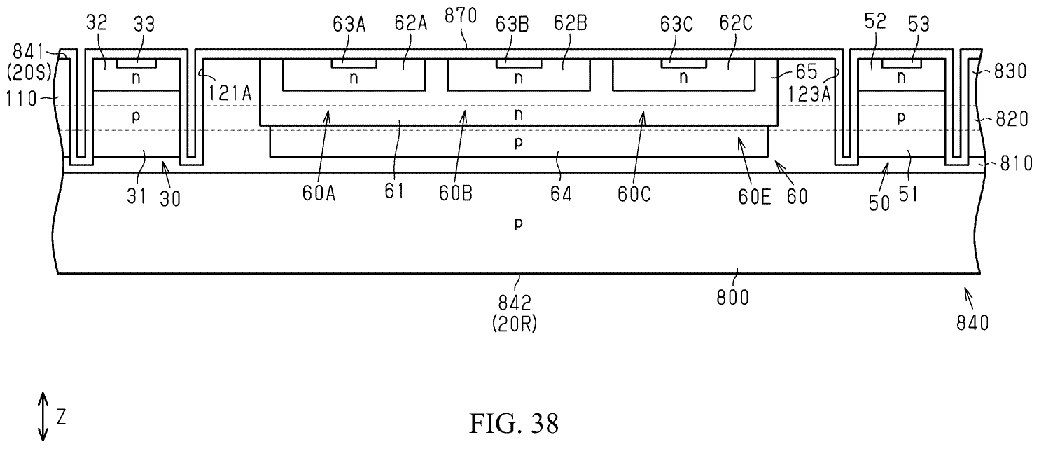

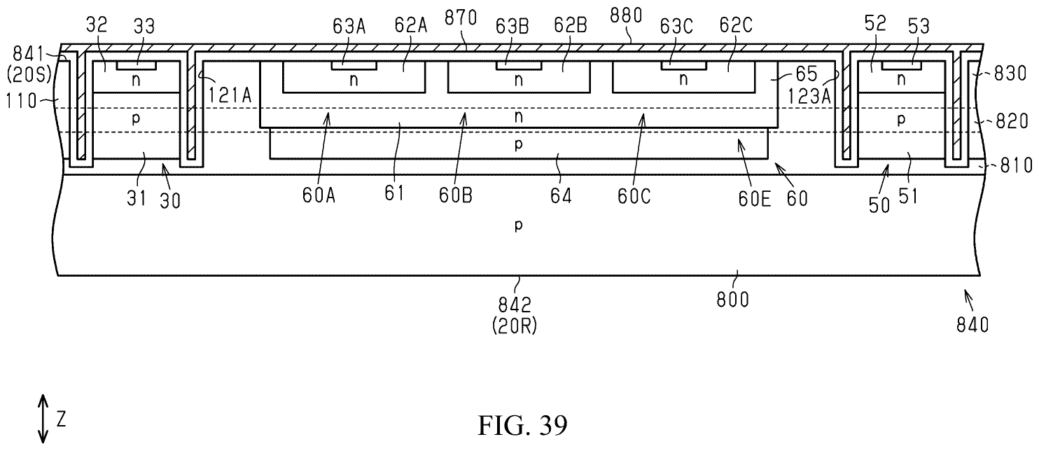

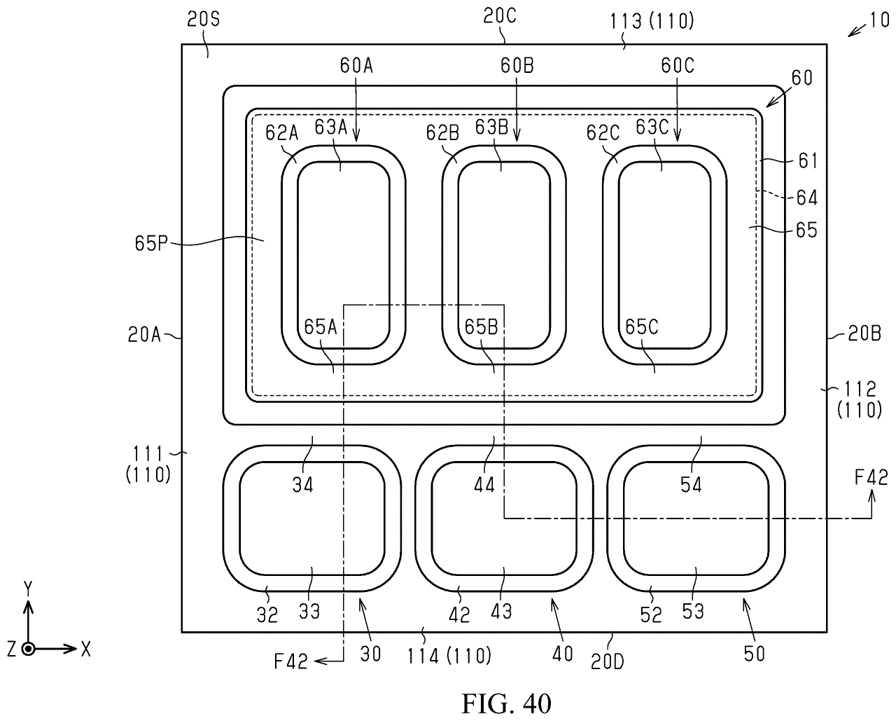

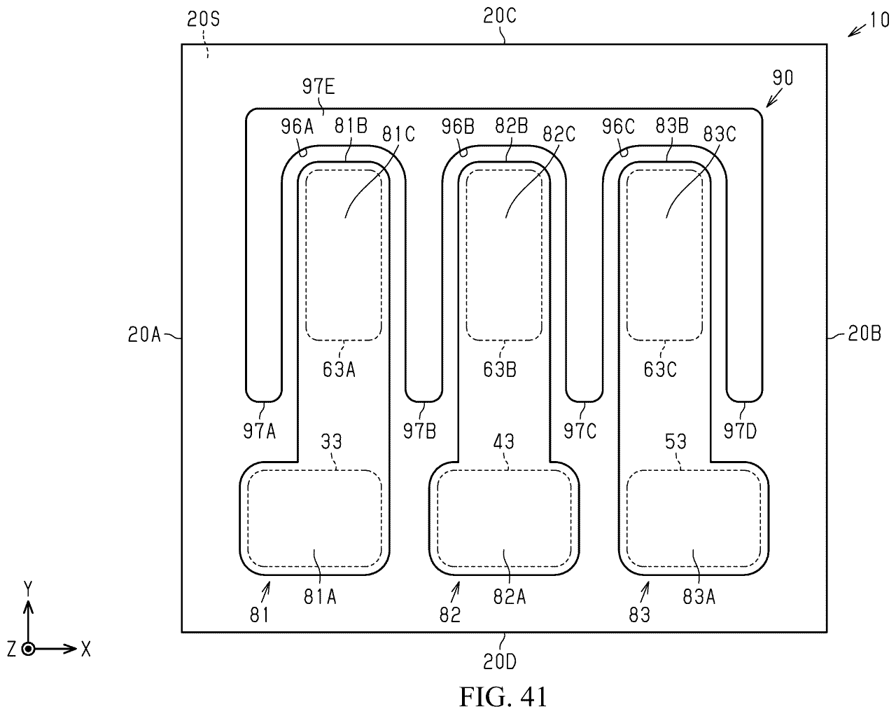

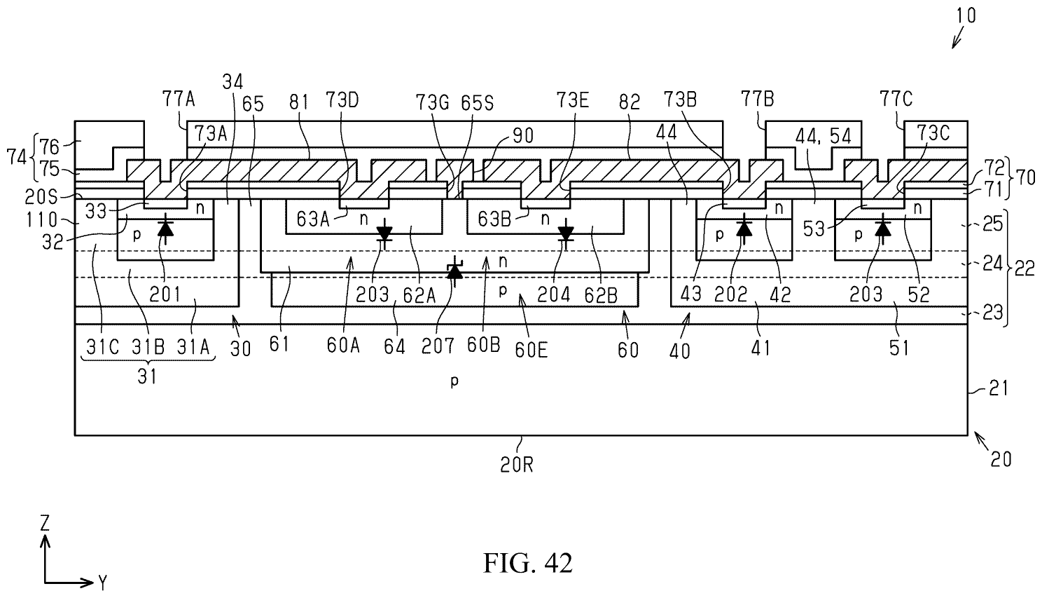

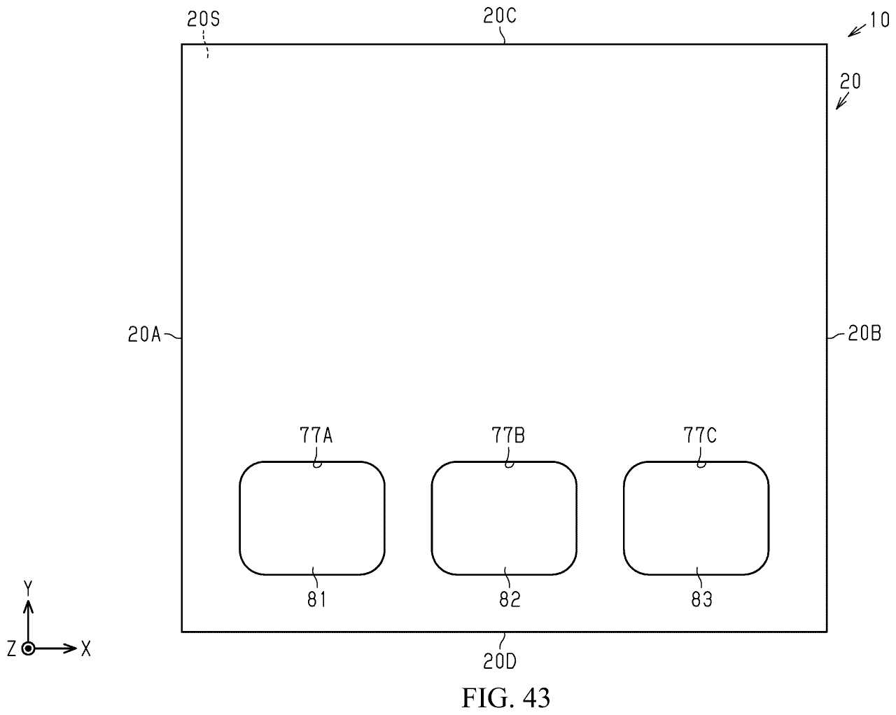

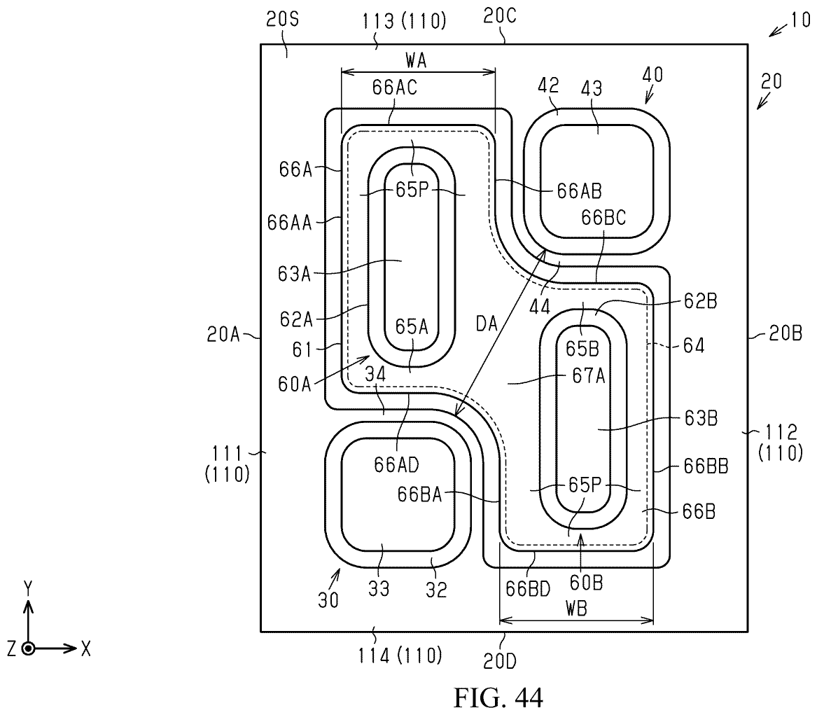

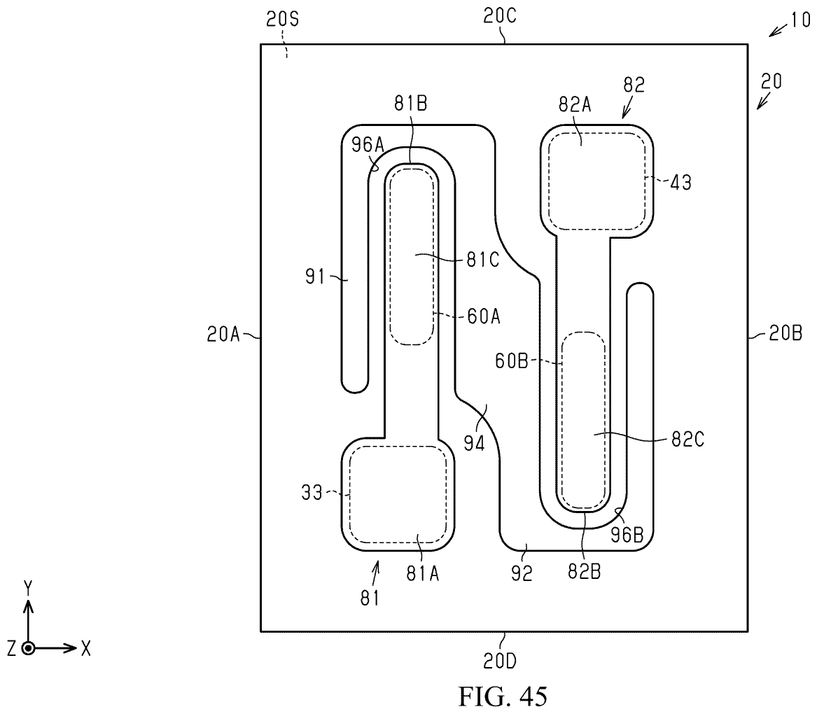

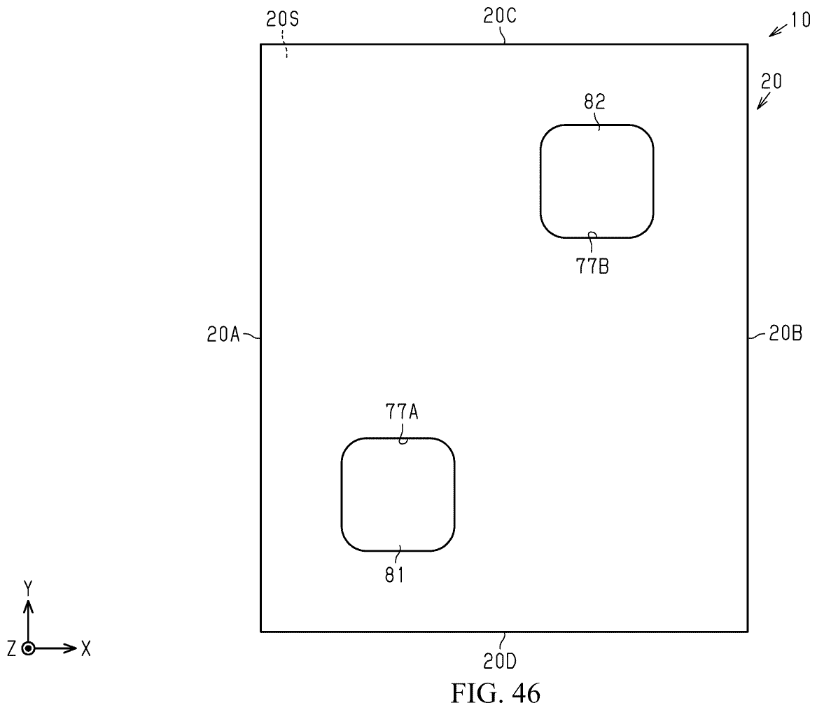

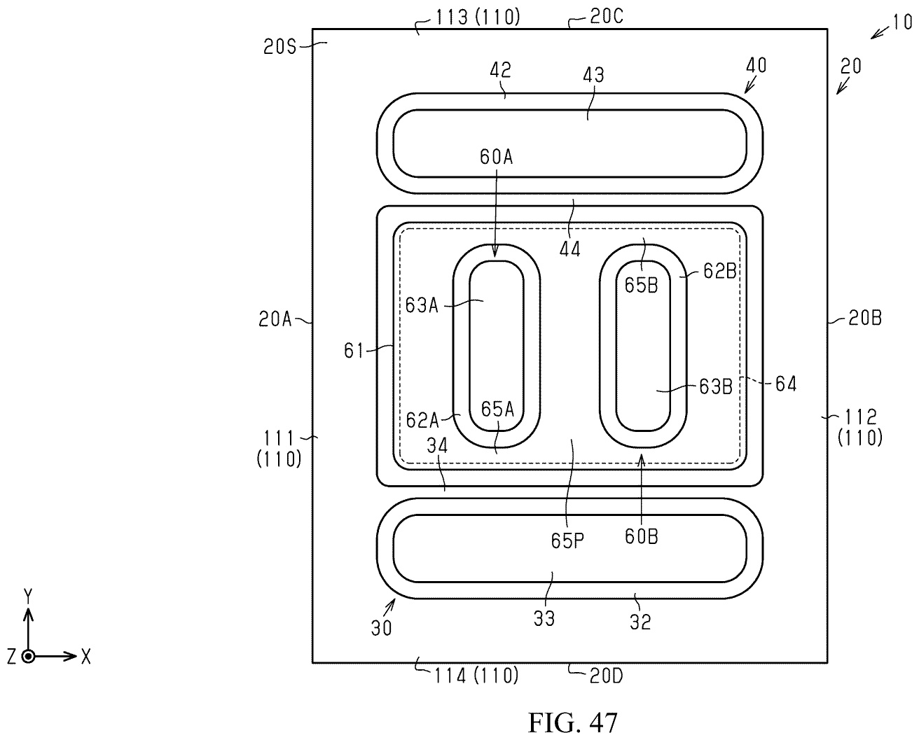

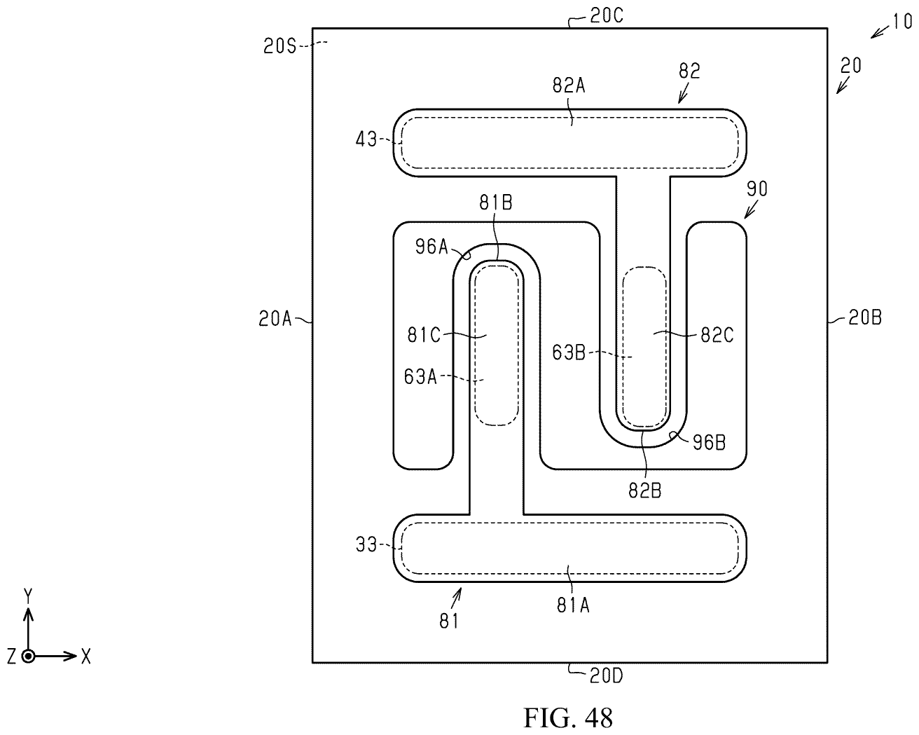

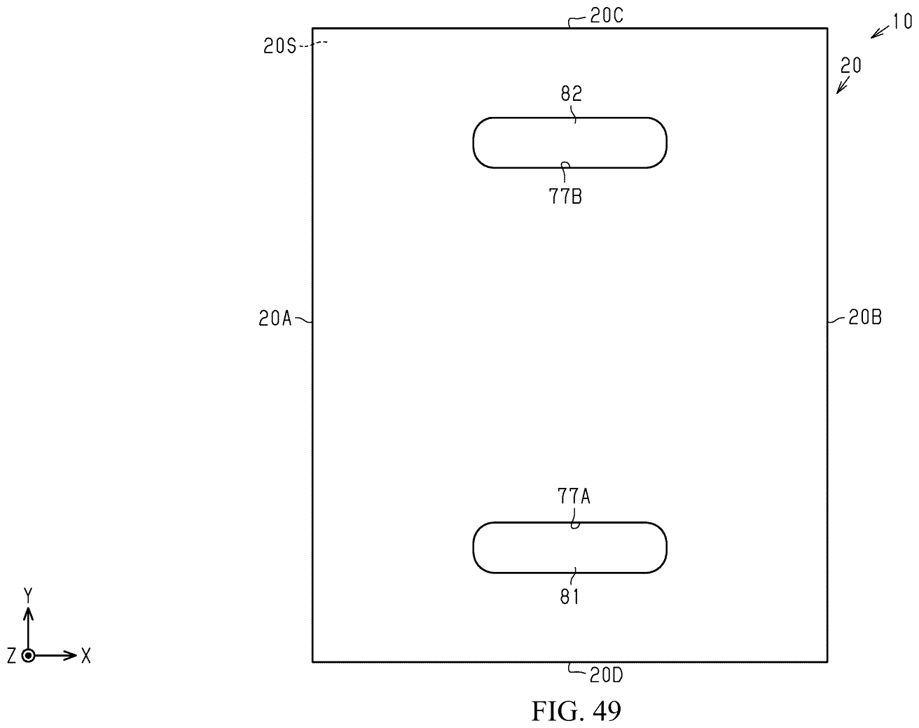

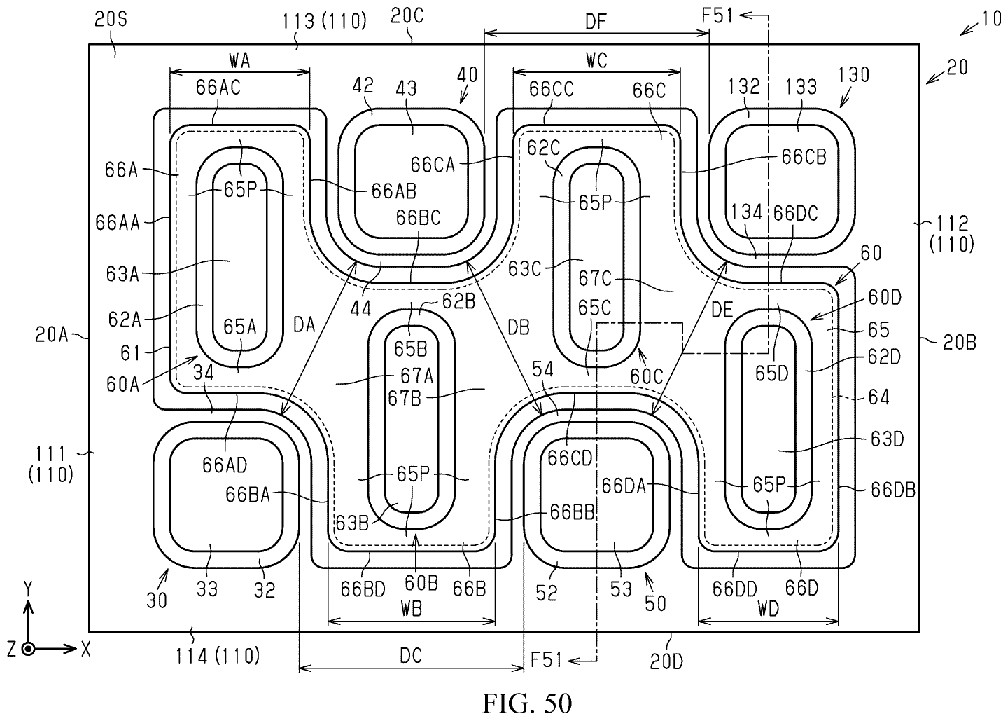

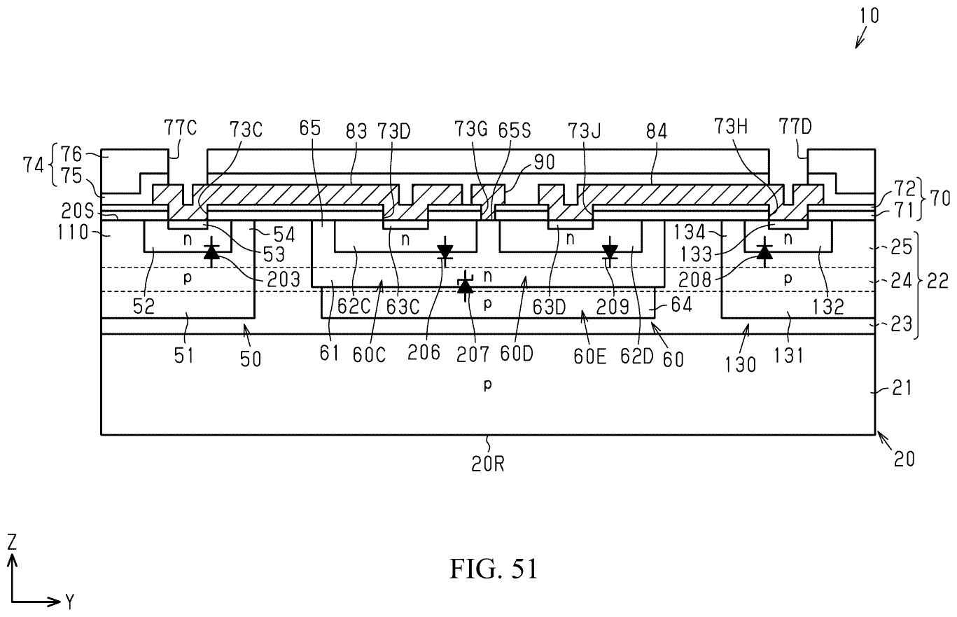

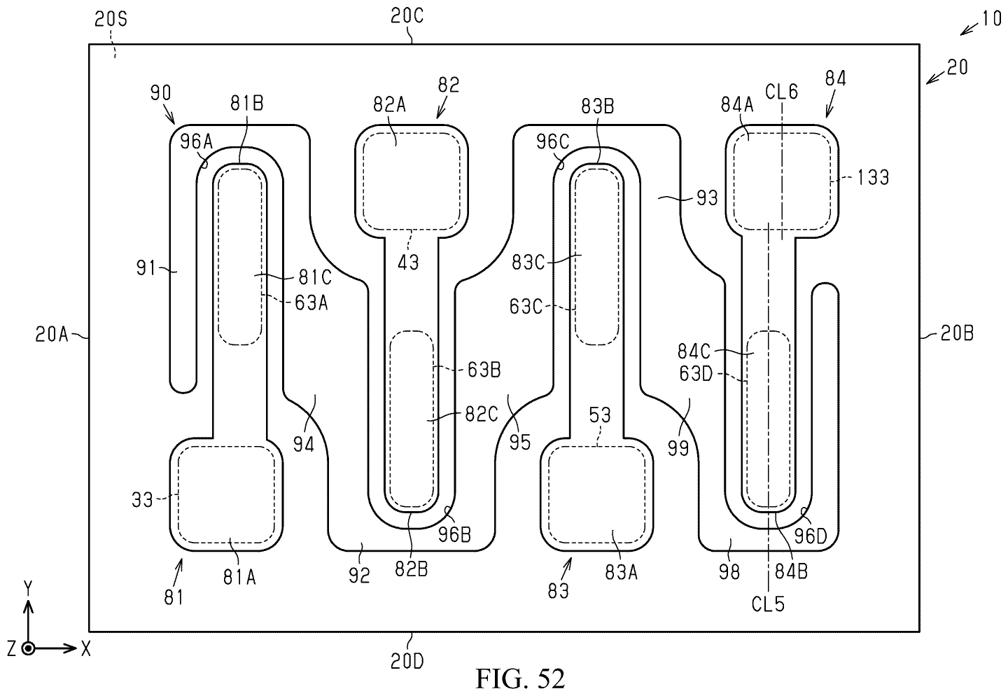

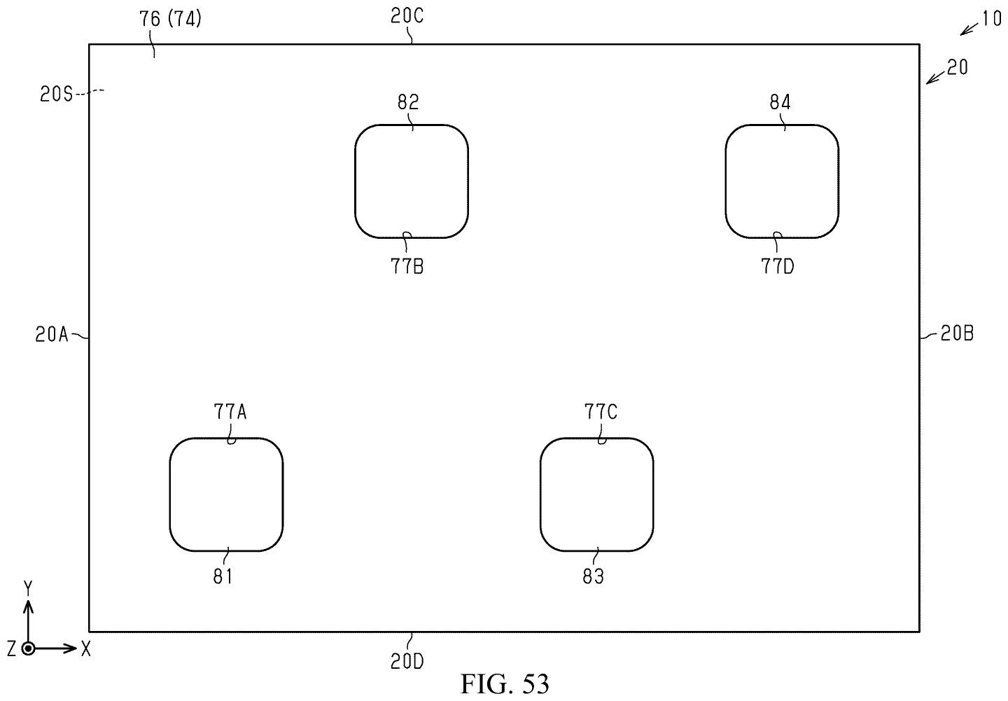

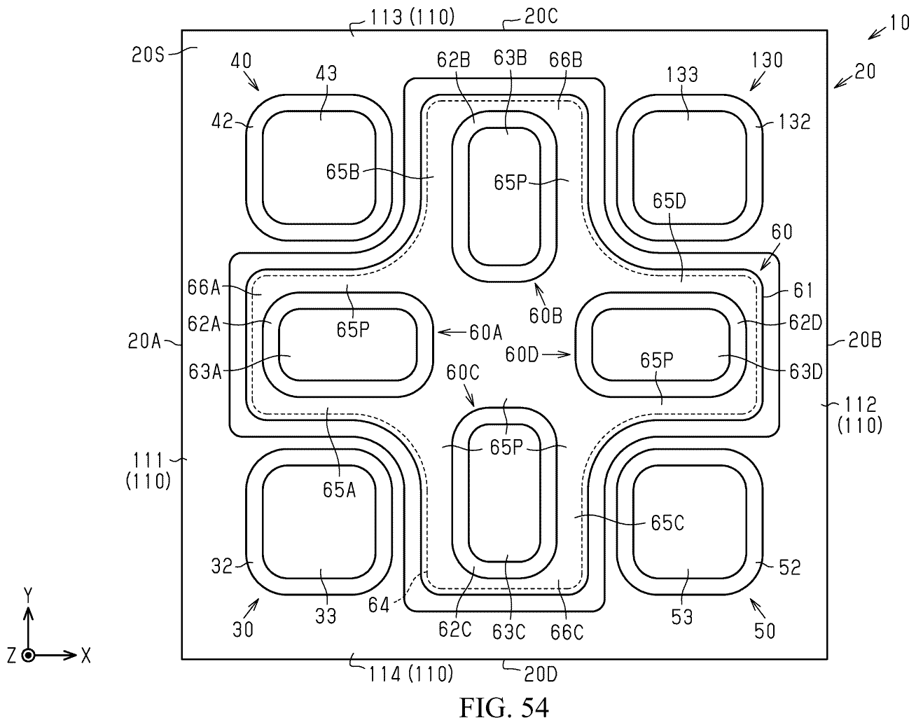

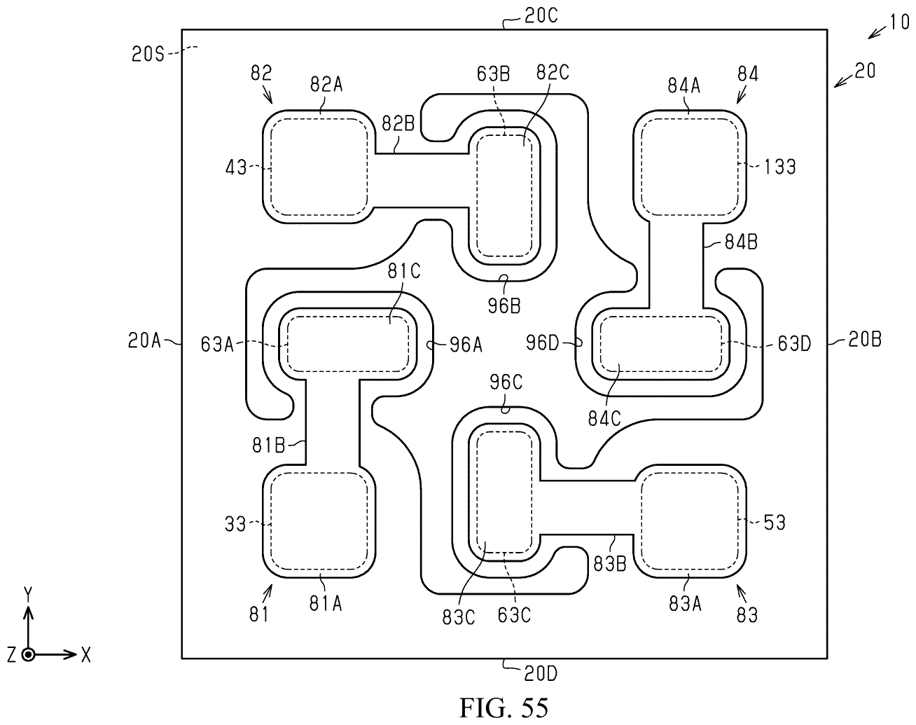

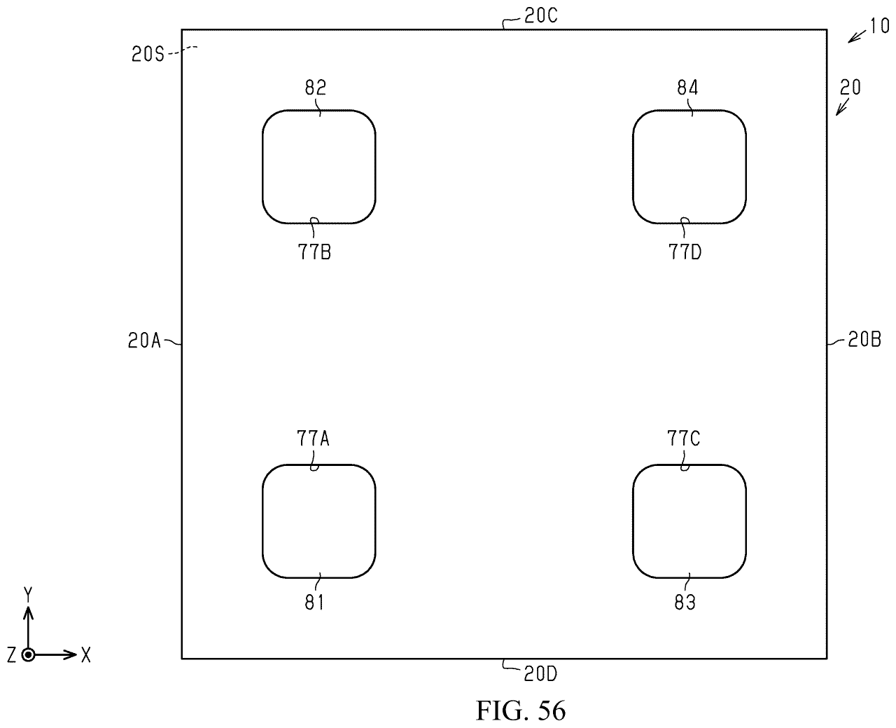

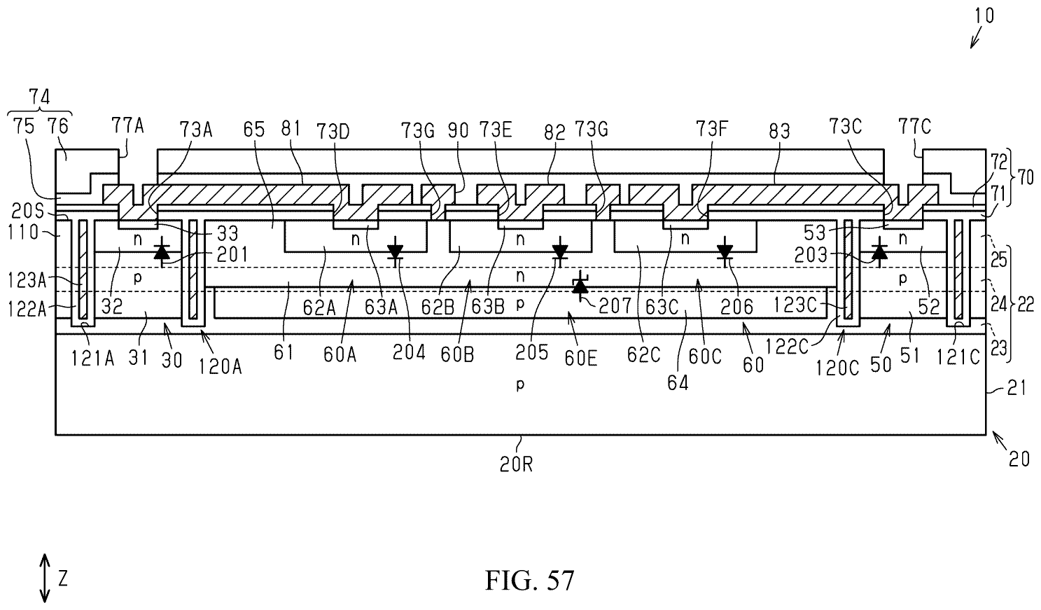

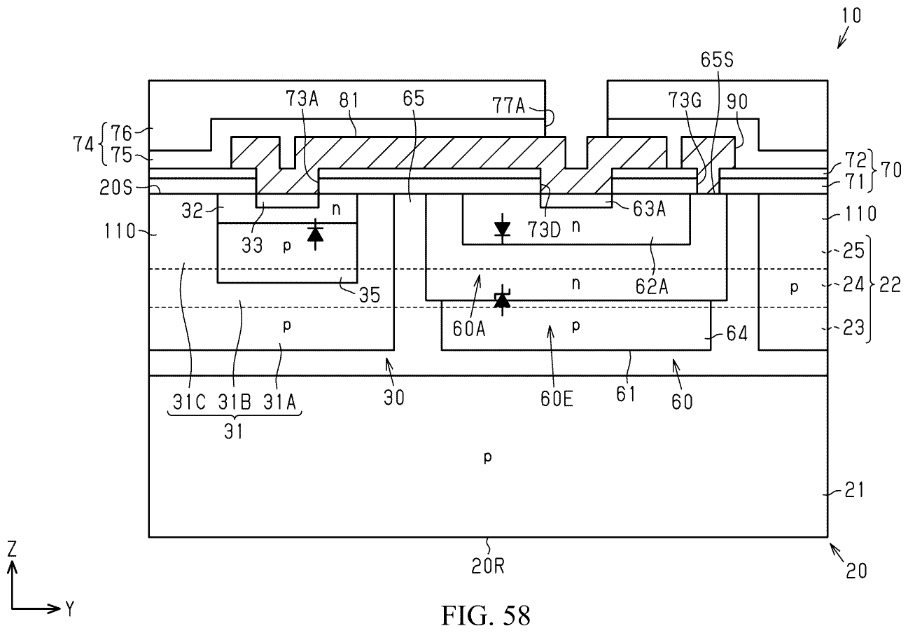

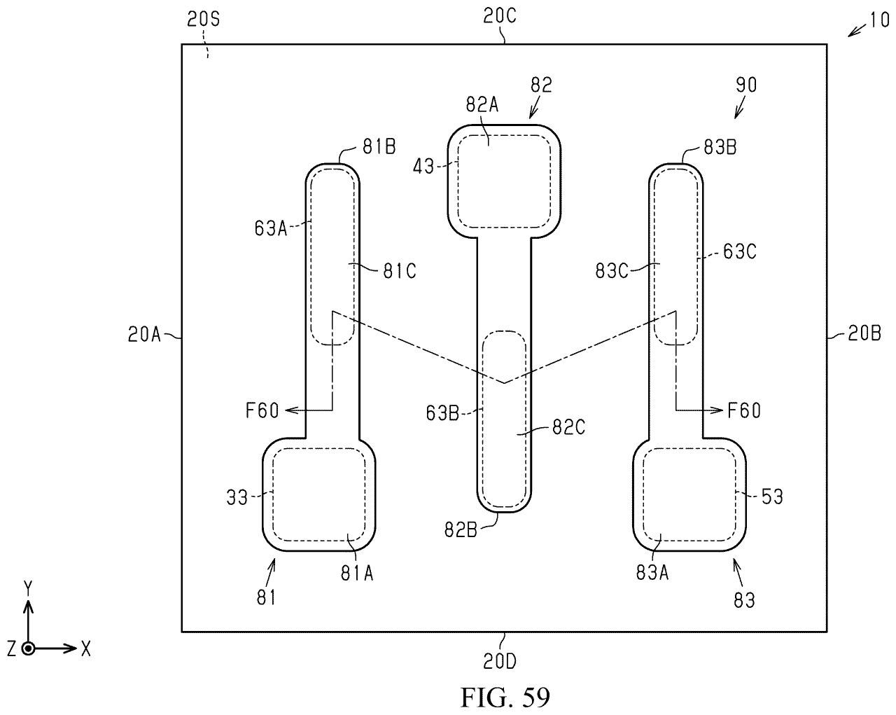

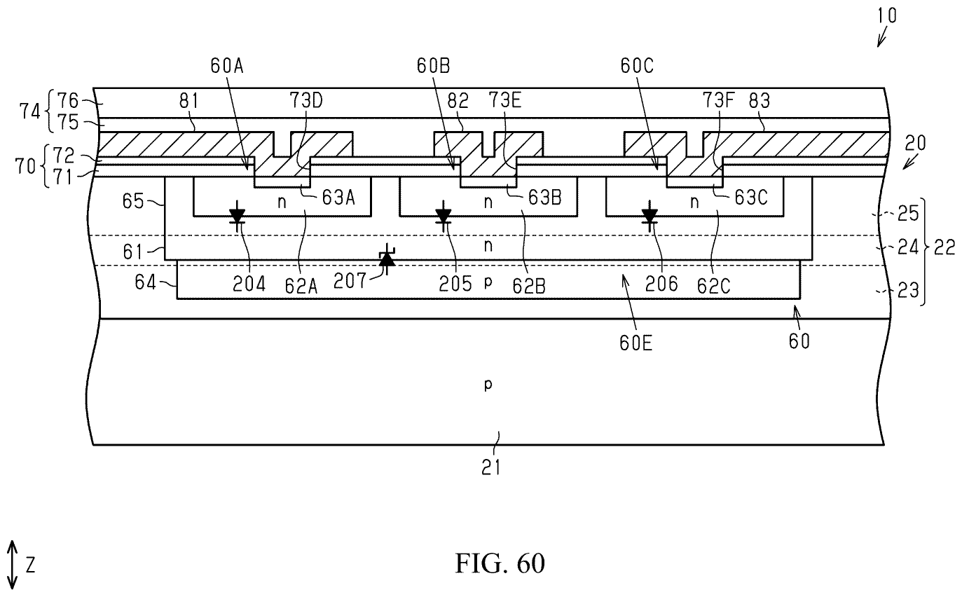

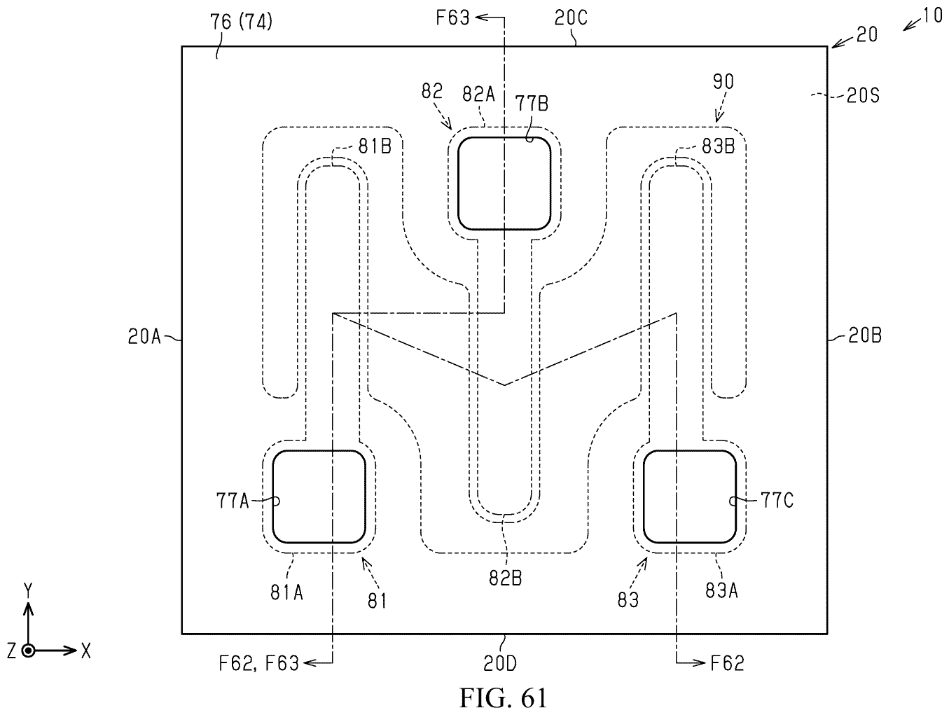

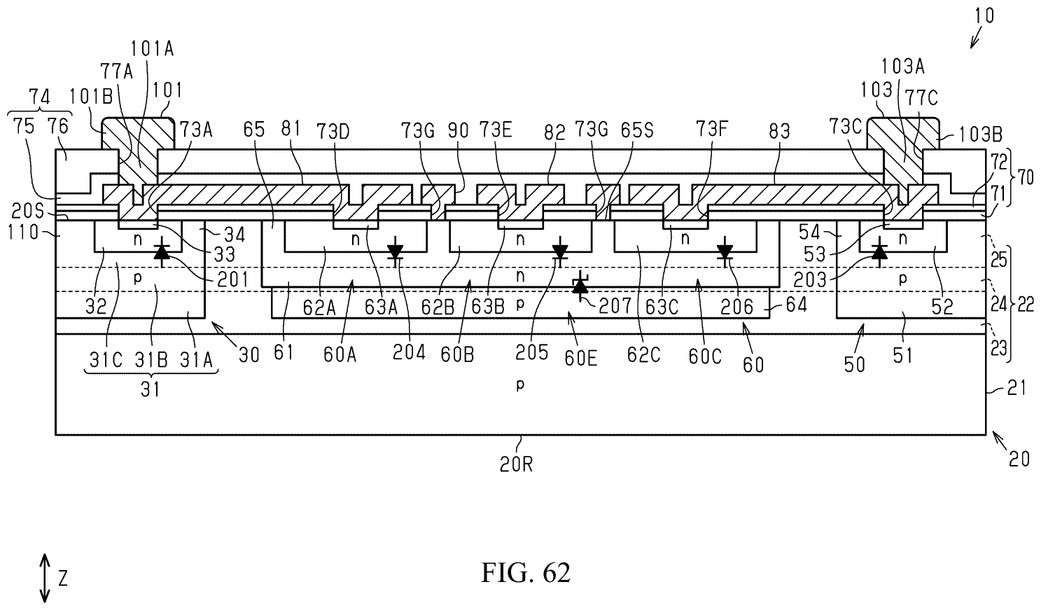

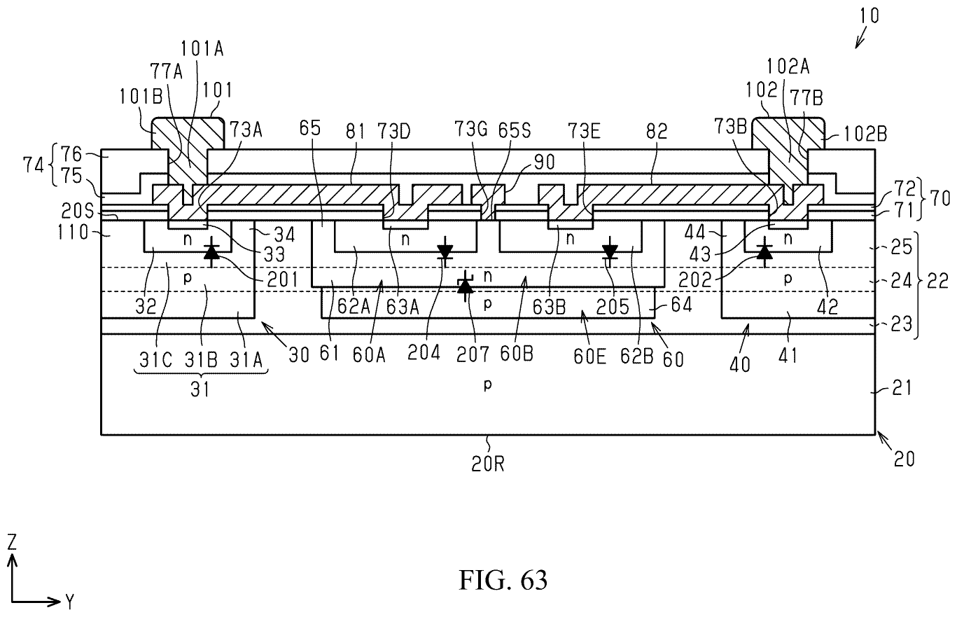

FIG. 26 is a schematic cross-sectional view that enlarges a diode pair region and its periphery of FIG. 2.

FIG. 27 is a schematic cross-sectional view of a second pin junction portion, a third pin junction portion, and their periphery.

FIG. 28 is a schematic cross-sectional view of a TVS diode of a second embodiment.

FIG. 29 is a schematic cross-sectional view of a TVS diode at a different position from that in FIG. 28.

FIG. 30 is a schematic cross-sectional view that enlarges a portion of FIG. 28.

FIG. 31 is a graph showing a relationship between a position of a semiconductor chip in a thickness direction and an impurity concentration.

FIG. 32 is a schematic cross-sectional view illustrating an exemplary manufacturing process of the TVS diode of the second embodiment.

FIG. 33 is a schematic cross-sectional view showing a manufacturing process subsequent to the process shown in FIG. 32.

FIG. 34 is a schematic plan view of a semiconductor chip in a TVS diode of a third embodiment.

FIG. 35 is a schematic cross-sectional view of the TVS diode taken along line F35-F35 in FIG. 34.

FIG. 36 is a schematic cross-sectional view of the TVS diode taken along line F36-F36 in FIG. 34.

FIG. 37 is a schematic cross-sectional view illustrating an exemplary manufacturing process of the TVS diode of the third embodiment.

FIG. 38 is a schematic cross-sectional view showing the manufacturing process subsequent to the process shown in FIG. 37.

FIG. 39 is a schematic cross-sectional view showing the manufacturing process subsequent to the process shown in FIG. 38.

FIG. 40 is a schematic plan view of a semiconductor chip in a TVS diode of a fourth embodiment.

FIG. 41 is a schematic plan view of first to third connection electrodes and a wiring provided on a semiconductor chip.

FIG. 42 is a schematic cross-sectional view of the TVS diode taken along line F42-F42 in FIG. 40.

FIG. 43 is a schematic plan view of a TVS diode.

FIG. 44 is a schematic cross-sectional view of a semiconductor chip in a TVS diode of a fifth embodiment.

FIG. 45 is a schematic plan view of a first connection electrode, a second connection electrode and a wiring provided on a semiconductor chip.

FIG. 46 is a schematic plan view of a TVS diode.

FIG. 47 is a schematic cross-sectional view of a semiconductor chip in a TVS diode of a sixth embodiment.

FIG. 48 is a schematic plan view of a first connection electrode, a second connection electrode and a wiring provided on a semiconductor chip.

FIG. 49 is a schematic plan view of a TVS diode.

FIG. 50 is a schematic cross-sectional view of a semiconductor chip in a TVS diode of a seventh embodiment.

FIG. 51 is a schematic cross-sectional view of the TVS diode taken along line F51-F51 in FIG. 50.

FIG. 52 is a schematic plan view of first to fourth connection electrodes and a wiring provided on a semiconductor chip.

FIG. 53 is a schematic plan view of a TVS diode.

FIG. 54 is a schematic cross-sectional view of a semiconductor chip in a TVS diode of an eighth embodiment.

FIG. 55 is a schematic plan view of a first connection electrode, a second connection electrode and a wiring provided on a semiconductor chip.

FIG. 56 is a schematic plan view of a TVS diode.

FIG. 57 is a schematic cross-sectional view of a variation of a TVS diode.

FIG. 58 is a schematic cross-sectional view of a variation of a TVS diode.

FIG. 59 is a schematic plan view of first to third connection electrodes and a wiring provided on a semiconductor chip in a variation of a TVS diode.

FIG. 60 is a schematic cross-sectional view of the TVS diode taken along line F60-F60 in FIG. 59.

FIG. 61 is a schematic cross-sectional view of a variation of a TVS diode.

FIG. 62 is a schematic cross-sectional view of the TVS diode taken along line F62-F62 in FIG. 61.

FIG. 63 is a schematic cross-sectional view of the TVS diode taken along line F63-F63 in FIG. 61.

### DETAILED DESCRIPTION OF THE EMBODIMENTS

Hereinafter, several embodiments of the TVS diode in the present disclosure are described with reference to the accompanying figures. Furthermore, for simplicity and clarity of illustration, components shown in the figures are not necessarily drawn to a specific scale. Additionally, to facilitate understanding, hatching lines may be omitted in cross-sectional views. The accompanying figures are merely illustrative of the embodiments of the present disclosure and should not be considered as limiting the present disclosure.

The following detailed description includes devices, systems, and methods embodying exemplary embodiments of the present disclosure. This detailed description is merely illustrative and is not intended to limit the embodiments of the present disclosure or the application and use of such embodiments.

The term “at least one” as used in this disclosure means “one or more” of a desired option. As an example, the term “at least one” as used in the present disclosure means “only one option” or “both of two options” if the number of options is two. As another example, the term “at least one” as used in the present disclosure means “only one option” or “any combination of two or more options” if the number of options is three or more.

As used in the present disclosure, “a dimension (depth, width, length) of A is equal to a dimension (depth, width, length) of B” or “a dimension (depth, width, length) of A and a dimension (depth, width, length) of B are equal to each other” also includes a relationship in which the difference between the dimension (depth, width, length) of A and the dimension (depth, width, length) of B is, for example, within 10% of the dimension (depth, width, length) of A. Additionally, as used in the present disclosure, “a concentration of A is equal to a concentration of B” or “a concentration of A and a concentration of B are equal to each other” also includes a relationship in which the difference between the concentration of A and the concentration of B is, for example, within 10% of the concentration of A.

### First Embodiment

### [Configuration of TVS Diode]

A configuration of a TVS diode 10 of a first embodiment is illustrated with reference to FIGS. 1 to 3. FIG. 1 schematically shows a planar structure of the TVS diode 10. FIG. 2 schematically shows the cross-sectional structure taken along line F2-F2 in FIG. 1. FIG. 3 schematically shows the cross-sectional structure taken along line F3-F3 in FIG. 1.

As shown in FIG. 1, the TVS diode 10 is a diode chip that includes a TVS circuit 200 (refer to FIG. 8) for protecting electrical circuits from ESD (Electro-Static Discharge). Furthermore, the details of the TVS circuit 200 are described later using FIG. 8. Such TVS diodes 10 are used, for example, to protect interfaces in electronic devices such as wearable devices, smartphones, or the like.

The TVS diode 10 includes a semiconductor chip 20 which is rectangular cuboid-shaped. The semiconductor chip 20 is formed of a material that includes, for example, silicon (Si). The semiconductor chip 20 may be said to be a flat plate with the Z direction being the thickness direction. Furthermore, hereafter, viewing the TVS diode 10 from the Z direction is referred to as a “plan view.” Additionally, among directions that are orthogonal to the Z direction, the directions orthogonal to each other are referred to as the “X direction” and the “Y direction.” Herein, the X direction is an example of a “second direction,” and the Y direction is an example of a “first direction.”

The semiconductor chip 20 includes a first surface 20S, a second surface 20R (refer to FIG. 2) opposite to the first surface 20S, and first to fourth side surfaces 20A to 20D as four side surfaces that connect the first surface 20S and the second surface 20R. In one example, the first surface 20S and the second surface 20R are formed of planes that are orthogonal to the Z direction. The first side surface 20A and the second side surface 20B form two end surfaces of the semiconductor chip 20 in the X direction. The third side surface 20C and the fourth side surface 20D form two end surfaces of the semiconductor chip 20 in the Y direction.

### (Cross-Sectional Structure of a TVS Diode)

As shown in FIG. 2 and FIG. 3, the semiconductor chip 20 includes a semiconductor substrate 21 and a semiconductor layer 22 provided on the semiconductor substrate 21.

The semiconductor substrate 21 is formed of a material including Si (silicon). In one example, a Si substrate is used for the semiconductor substrate 21. Furthermore, a SiC (silicon carbide) substrate may be used for the semiconductor substrate 21. The semiconductor substrate 21 is a flat plate with the Z direction being the thickness direction. The thickness of the semiconductor substrate 21 may be 10 μm or more and 800 μm or less. In one example, the thickness of the semiconductor substrate 21 is 30 μm or more and 400 μm or less.

The semiconductor substrate 21 includes p-type impurities. In one example, the semiconductor substrate 21 has a generally uniform p-type impurity concentration throughout its entire area. The p-type impurity concentration in the semiconductor substrate 21 may be 1×10¹⁹ cm⁻³ or more and 1×10²¹ cm⁻³ or less. In one example, the p-type impurity concentration in the semiconductor substrate 21 is 1×10¹⁹ cm⁻³ or more and 1×10²⁰ cm⁻³ or less.

The semiconductor layer 22 is formed of an epitaxial layer provided on the semiconductor substrate 21. In one example, the semiconductor layer 22 is formed of a laminated structure of a first semiconductor layer 23, a second semiconductor layer 24, and a third semiconductor layer 25. Furthermore, in FIG. 2 and FIG. 3, each of the boundary between the first semiconductor layer 23 and the second semiconductor layer 24, and the boundary between the second semiconductor layer 24 and the third semiconductor layer 25 is indicated by a dashed line.

The first semiconductor layer 23 is formed of a p-type epitaxial layer provided on an upper surface of the semiconductor substrate 21. The thickness of the first semiconductor layer 23 may be 5 μm or more and 20 μm or less. In one example, the thickness of the first semiconductor layer 23 is 10 μm or more and 18 μm or less. In one example, the thickness of the first semiconductor layer 23 is about 15 μm.

The p-type impurity concentration in the first semiconductor layer 23 is less than the p-type impurity concentration in the semiconductor substrate 21. The first semiconductor layer 23 has a concentration gradient in which the p-type impurity concentration decreases from the semiconductor substrate 21 toward the direction of crystal growth. That is, the p-type impurity concentration in the first semiconductor layer 23 includes a portion that decreases with increasing distance from the semiconductor substrate 21 in the Z direction. The degree of decrease in the p-type impurity concentration in the first semiconductor layer 23 increases with increasing distance from the semiconductor substrate 21. The p-type impurity concentration in the first semiconductor layer 23 gradually decreases until its minimum value falls within the range of 1×10¹⁵ cm⁻³ or more and 1×10¹⁷ cm⁻³ or less. The minimum value of the p-type impurity concentration in the first semiconductor layer 23 may be, for example, in the range of 1×10¹⁶ cm⁻³ or more and 1×10¹⁷ cm⁻³ or less.

The second semiconductor layer 24 is formed of an n-type epitaxial layer provided on the upper surface of the first semiconductor layer 23. The thickness of the second semiconductor layer 24 may be 1 μm or more and 10 μm or less. In one example, the thickness of the second semiconductor layer 24 is 5 μm or more and 8 μm or less. In one example, the thickness of the second semiconductor layer 24 is about 7 μm. Herein, n-type is an example of the “first conductivity type.” Furthermore, the second semiconductor layer 24 may also be formed of a p-type epitaxial layer.

The peak value of the n-type impurity concentration in the second semiconductor layer 24 may be 5×10¹⁴ cm⁻³ or more and 1×10¹⁵ cm⁻³ or less. In one example, the peak value of the n-type impurity concentration in the second semiconductor layer 24 is around 1×10¹⁵ cm⁻³. In one example, the n-type impurity concentration in the second semiconductor layer 24 gradually increases from the first semiconductor layer 23 toward the center of the second semiconductor layer 24 in the Z direction. Then, the n-type impurity concentration in the second semiconductor layer 24 gradually decreases from the center of the second semiconductor layer 24 in the Z direction toward the third semiconductor layer 25.

The third semiconductor layer 25 is formed of an n-type epitaxial layer provided on the upper surface of the second semiconductor layer 24. The third semiconductor layer 25 includes the first surface 20S of the semiconductor chip 20. The thickness of the third semiconductor layer 25 may be 5 μm or more and 20 μm or less. In one example, the thickness of the third semiconductor layer 25 is 8 μm or more and 15 μm or less. In one example, the thickness of the third semiconductor layer 25 is about 13 μm. Thus, the thickness of the third semiconductor layer 25 may be greater than the thickness of the second semiconductor layer 24. The thickness of the third semiconductor layer 25 may be thinner than that of the first semiconductor layer 23.

The n-type impurity concentration in the third semiconductor layer 25 may be 1×10¹³ cm⁻³ or more and 1×10¹⁵ cm⁻³ or less. In one example, the n-type impurity concentration in the third semiconductor layer 25 is 5×10¹³ cm⁻³ or more and 5×10¹⁴ cm⁻³ or less. In one example, the n-type impurity concentration in the third semiconductor layer 25 is 1×10¹⁴ cm⁻³ or more and less than 1×10¹⁵ cm⁻³. The n-type impurity concentration in the third semiconductor layer 25 gradually decreases with increasing distance from the second semiconductor layer 24 in the Z direction. That is, the third semiconductor layer 25 has a peak of the n-type impurity concentration in a region that is in contact with the second semiconductor layer 24 in the Z direction. The n-type impurity concentration is at a minimum in a region of the third semiconductor layer 25 close to the first surface 20S. In one example, the minimum value of the n-type impurity concentration in the third semiconductor layer 25 is 1×10¹⁴ cm⁻³. Thus, the minimum value of the n-type impurity concentration in the third semiconductor layer 25 is less than the minimum value of the n-type impurity concentration in the second semiconductor layer 24. In one example, the n-type impurity concentration in the third semiconductor layer 25 is less than the n-type impurity concentration in the second semiconductor layer 24.

Both the second semiconductor layer 24 and the third semiconductor layer 25 are configured as n-type high-resistance layers with a relatively low n-type impurity concentration. Both the second semiconductor layer 24 and the third semiconductor layer 25 may have a resistivity of 50 Ω·cm or more and 150 Ω·cm or less. In one example, both the second semiconductor layer 24 and the third semiconductor layer 25 may have a resistivity of 80 Ω·cm or more and 120 Ω·cm or less.

### (Pin Junction Portion)

As shown in FIG. 2 and FIG. 3, the semiconductor chip 20 includes a first pin (p-intrinsic-n) junction portion 30, a second pin junction portion 40, and a third pin junction portion 50. Each of the first pin junction portion 30, the second pin junction portion 40, and the third pin junction portion 50 is provided in the surface layer portion of the semiconductor chip 20 (a region close to the first surface 20S in the Z direction and including the first surface 20S of the semiconductor chip 20). Each of the first pin junction portion 30, the second pin junction portion 40, and the third pin junction portion 50 is a region of the semiconductor chip 20 where a pin diode of the first polarity direction is formed. Herein, the first polarity direction is the direction in which the forward current flows from the second surface 20R toward the first surface 20S of the semiconductor chip 20.

As shown in FIG. 2, the first pin junction portion 30 includes a first-terminal-side high-concentration region 31, a first-terminal-side low-concentration region 32, a first-terminal-side contact region 33, and a first partition region 34.

The first-terminal-side high-concentration region 31 is a p-type region provided across the first semiconductor layer 23, the second semiconductor layer 24, and the third semiconductor layer 25 in the Z direction. The first-terminal-side high-concentration region 31 is provided in a portion of the Z direction of the first semiconductor layer 23, the entirety of the second semiconductor layer 24, and a portion of the Z direction of the third semiconductor layer 25. Therefore, the first-terminal-side high-concentration region 31 is provided spaced apart from the first surface 20S toward the second surface 20R of the semiconductor chip 20. The first-terminal-side high-concentration region 31 is provided spaced apart from the semiconductor substrate 21 in the Z direction. The first-terminal-side high-concentration region 31 may be partitioned into a first region 31A, a second region 31B, and a third region 31C in the Z direction. Herein, p-type is an example of the “second conductivity type.”

The first region 31A is provided in the surface layer portion of the first semiconductor layer 23 (a region close to the second semiconductor layer 24 that includes the upper surface of the first semiconductor layer 23). The first region 31A is configured to suppress the decrease in p-type impurity concentration in the first semiconductor layer 23. That is, the first region 31A is configured to maintain a predetermined p-type impurity concentration. The p-type impurity concentration in the first region 31A may be 1×10¹⁷ cm⁻³ or more and 1×10¹⁹ cm⁻³ or less. In one example, the p-type impurity concentration in the first region 31A is 1×10¹⁸ cm⁻³.

The second region 31B is provided in the entirety of the Z direction of the second semiconductor layer 24 on the first region 31A. In one example, the second region 31B includes a region configured such that the p-type impurity concentration gradually decreases with increasing distance from the first region 31A in the Z direction. Therefore, the p-type impurity concentration in the second region 31B is less than or equal to the minimum value of the p-type impurity concentration in the first region 31A.

The third region 31C is provided in a region of the third semiconductor layer 25 that is close to the second semiconductor layer 24 on the second region 31B. In one example, the third region 31C has a p-type impurity concentration that gradually decreases with increasing distance from the second region 31B in the Z direction. Therefore, the p-type impurity concentration in the third region 31C is less than or equal to the p-type impurity concentration in the second region 31B.

The first-terminal-side low-concentration region 32 is provided at a position overlapping the first-terminal-side high-concentration region 31 in the plan view in a region closer to the first surface 20S than the first-terminal-side high-concentration region 31. In one example, the first-terminal-side low-concentration region 32 is provided on the third region 31C. The first-terminal-side low-concentration region 32 is an n-type region formed of the third semiconductor layer 25. The first-terminal-side low-concentration region 32 is exposed from the first surface 20S of the semiconductor chip 20. Therefore, the n-type impurity concentration in the first-terminal-side low-concentration region 32 is equal to the n-type impurity concentration in the third semiconductor layer 25. Consequently, the n-type impurity concentration in the first-terminal-side low-concentration region 32 may be 1×10¹⁴ cm⁻³ or more and 1×10¹⁵ cm⁻³ or less.

The first-terminal-side contact region 33 is an n-type region provided in the surface layer portion of the first-terminal-side low-concentration region 32. The first-terminal-side contact region 33 is exposed from the first surface 20S of the semiconductor chip 20. The first-terminal-side contact region 33 is spaced apart from the first-terminal-side high-concentration region 31 in the Z direction.

The n-type impurity concentration in the first-terminal-side contact region 33 is higher than the n-type impurity concentration in the first-terminal-side low-concentration region 32. The peak value of the n-type impurity concentration in the first-terminal-side contact region 33 may be 1×10¹⁸ cm⁻³ or more and 1×10²¹ cm⁻³ or less. In one example, the peak value of the n-type impurity concentration in the first-terminal-side contact region 33 is 5×10¹⁸ cm⁻³ or more and 1×10²⁰ cm⁻³ or less.

As such, in the first pin junction portion 30, the p-type first-terminal-side high-concentration region 31 forms the P layer of a pin diode, the n-type first-terminal-side low-concentration region 32 forms the I layer of the pin diode, and the n-type first-terminal-side contact region 33 forms the N layer of the pin diode. That is, the first-terminal-side high-concentration region 31, the first-terminal-side low-concentration region 32, and the first-terminal-side contact region 33 form a pin junction in the Z direction. Therefore, in the first pin junction portion 30, the pin diode (diode 201) of the first polarity direction is formed of the first-terminal-side high-concentration region 31, the first-terminal-side low-concentration region 32, and the first-terminal-side contact region 33.

The first partition region 34 is a p-type region provided to surround the first-terminal-side low-concentration region 32 in the plan view. The first partition region 34 partitions the first-terminal-side low-concentration region 32 from the third semiconductor layer 25 outside the first pin junction portion 30. The first partition region 34 is provided at a position overlapping the first-terminal-side high-concentration region 31 in the plan view in a region closer to the first surface 20S than the first-terminal-side high-concentration region 31. The first partition region 34 is provided to be spaced apart from the first-terminal-side contact region 33 in the plan view. The first partition region 34 is provided to surround the first-terminal-side contact region 33 in the plan view.

The p-type impurity concentration in the first partition region 34 may be higher than the p-type impurity concentration in the third region 31C of the first-terminal-side high-concentration region 31. In one example, the p-type impurity concentration in the first partition region 34 may be 1×10¹⁷ cm⁻³ or more and 1×10¹⁸ cm⁻³ or less. Furthermore, the p-type impurity concentration in the first partition region 34 may be arbitrarily changed within the range that can partition the first-terminal-side low-concentration region 32 from the third semiconductor layer 25.

In the first pin junction portion 30, the pin diode is formed of the first partition region 34, the first-terminal-side low-concentration region 32, and the first-terminal-side contact region 33. Thus, in the first pin junction portion 30, a first current path is provided in which a forward current flows in the order of the first-terminal-side high-concentration region 31, the first-terminal-side low-concentration region 32, and the first-terminal-side contact region 33, and a second current path is provided in which a forward current flows in the order of the first partition region 34, the first-terminal-side low-concentration region 32, and the first-terminal-side contact region 33.

As shown in FIG. 3, the second pin junction portion 40 includes a p-type second-terminal-side high-concentration region 41, an n-type second-terminal-side low-concentration region 42, an n-type second-terminal-side contact region 43, and a p-type second partition region 44. The second-terminal-side high-concentration region 41 is provided spaced apart from the first surface 20S toward the second surface 20R of the semiconductor chip 20. The second-terminal-side high-concentration region 41 is provided spaced apart from the first-terminal-side high-concentration region 31 in the plan view. The second-terminal-side low-concentration region 42 is provided at a position overlapping the second-terminal-side high-concentration region 41 in the plan view in a region closer to the first surface 20S than the second-terminal-side high-concentration region 41. The second-terminal-side contact region 43 is provided in the surface layer portion of the second-terminal-side low-concentration region 42. The second partition region 44 is provided at a position overlapping the second-terminal-side high-concentration region 41 in the plan view in a region closer to the first surface 20S than the second-terminal-side high-concentration region 41. The second partition region 44 is provided to surround the second-terminal-side low-concentration region 42 in the plan view. In the second pin junction portion 40, the pin diode (diode 202) is formed of the second-terminal-side high-concentration region 41, the second-terminal-side low-concentration region 42, and the second-terminal-side contact region 43. Additionally, in the second pin junction portion 40, the pin diode is formed of the second partition region 44, the second-terminal-side low-concentration region 42, and the second-terminal-side contact region 43.

Herein, the configurations of the second-terminal-side high-concentration region 41, the second-terminal-side low-concentration region 42, the second-terminal-side contact region 43, and the second partition region 44 are the same as those of the first-terminal-side high-concentration region 31, the first-terminal-side low-concentration region 32, the first-terminal-side contact region 33, and the first partition region 34 of the first pin junction portion 30. Therefore, detailed description is omitted.

As shown in FIG. 2, a third pin junction portion 50 includes a p-type third-terminal-side high-concentration region 51, an n-type third-terminal-side low-concentration region 52, an n-type third-terminal-side contact region 53, and a p-type third partition region 54. The third-terminal-side high-concentration region 51 is provided spaced apart from the first surface 20S toward the second surface 20R of the semiconductor chip 20. The third-terminal-side high-concentration region 51 is provided spaced apart from both the first-terminal-side high-concentration region 31 and the second-terminal-side high-concentration region 41 in the plan view. The third-terminal-side low-concentration region 52 is provided at a position overlapping the third-terminal-side high-concentration region 51 in the plan view in a region closer to the first surface 20S than the third-terminal-side high-concentration region 51. The third-terminal-side contact region 53 is provided in the surface layer portion of the third-terminal-side low-concentration region 52. The third partition region 54 is provided at a position overlapping the third-terminal-side high-concentration region 51 in the plan view in a region closer to the first surface 20S than the third-terminal-side high-concentration region 51. The third partition region 54 is provided to surround the third-terminal-side low-concentration region 52 in the plan view. In the third pin junction portion 50, the third-terminal-side high-concentration region 51, the third-terminal-side low-concentration region 52, and the third-terminal-side contact region 53 form a pin diode (diode 203). Additionally, in the third pin junction portion 50, the third partition region 54, the third-terminal-side low-concentration region 52, and the third-terminal-side contact region 53 form a pin diode.

Herein, the third-terminal-side high-concentration region 51, the third-terminal-side low-concentration region 52, the third-terminal-side contact region 53, and the third partition region 54 are the same as the first-terminal-side high-concentration region 31, the first-terminal-side low-concentration region 32, the first-terminal-side contact region 33 and the first partition region 34 of the first pin junction portion 30. Therefore, detailed description is omitted.

### (Diode Pair Region)

As shown in FIG. 2 and FIG. 3, the semiconductor chip 20 includes a diode pair region 60 that is provided spaced apart from each of the first pin junction portion 30, the second pin junction portion 40, and the third pin junction portion 50 in the plan view. The diode pair region 60 is provided in the surface layer portion of the semiconductor chip 20.

The diode pair region 60 includes a first reverse pin junction portion 60A, a second reverse pin junction portion 60B, a third reverse pin junction portion 60C, and a pn junction portion 60E. Each of the first reverse pin junction portion 60A, the second reverse pin junction portion 60B, and the third reverse pin junction portion 60C is a region of the semiconductor chip 20 where a pin diode of a second polarity direction is formed. Herein, the second polarity direction is the direction in which the forward current flows from the first surface 20S toward the second surface 20R of the semiconductor chip 20. That is, the second polarity direction is opposite to the first polarity direction.

The diode pair region 60 includes a high-concentration region 61, a first low-concentration region 62A, a second low-concentration region 62B, a third low-concentration region 62C, a first contact region 63A, a second contact region 63B, a third contact region 63C, an internal region 64, and a separation region 65. The first reverse pin junction portion 60A, the second reverse pin junction portion 60B, the third reverse pin junction portion 60C, and the pn junction portion 60E are formed of the high-concentration region 61, the first low-concentration region 62A, the second low-concentration region 62B, the third low-concentration region 62C, the first contact region 63A, the second contact region 63B, the third contact region 63C, the internal region 64, and the separation region 65.

The high-concentration region 61 is an n-type region provided at a position spaced apart from the first surface 20S and close to the second surface 20R from the first surface 20S of the semiconductor chip 20. The high-concentration region 61 is provided spaced apart from the first semiconductor layer 23 toward the first surface 20S from the first semiconductor layer 23 in the Z direction. The high-concentration region 61 is provided across the second semiconductor layer 24 and the third semiconductor layer 25 in the Z direction. The high-concentration region 61 is provided in a portion of the third semiconductor layer 25 in the Z direction.

The n-type impurity concentration in the high-concentration region 61 is higher than the n-type impurity concentration in the second semiconductor layer 24. The n-type impurity concentration in the high-concentration region 61 is higher than the n-type impurity concentration in the third semiconductor layer 25. The peak value of the n-type impurity concentration in the high-concentration region 61 may be 1×10¹⁸ cm⁻³ or more and 1×10²¹ cm⁻³ or less. In one example, the peak value of the n-type impurity concentration in the high-concentration region 61 is 5×10¹⁸ cm⁻³ or more and 1×10²⁰ cm⁻³ or less.

The first to third low-concentration regions 62A to 62C are n-type regions provided in a region closer to the first surface 20S than the high-concentration region 61. The first to third low-concentration regions 62A to 62C are spaced apart from each other in a plan view. Each of the first to third low-concentration regions 62A to 62C is provided at a position overlapping the high-concentration region 61 in the plan view. Each of the first to third low-concentration regions 62A to 62C is exposed from the first surface 20S of the semiconductor chip 20. The first to third low-concentration regions 62A to 62C are formed of the third semiconductor layer 25. Therefore, the n-type impurity concentration in each of the first to third low-concentration regions 62A to 62C may be equal to the n-type impurity concentration in the third semiconductor layer 25. Consequently, the n-type impurity concentration in each of the first to third low-concentration regions 62A to 62C may be 1×10¹⁴ cm⁻³ or more and 1×10¹⁵ cm⁻³ or less. In one example, the n-type impurity concentration in each of the first to third low-concentration regions 62A to 62C is 1×10¹⁴ cm⁻³.

The first contact region 63A is a p-type region provided in the surface layer portion of the first low-concentration region 62A. The first contact region 63A is exposed from the first surface 20S of the semiconductor chip 20. The first contact region 63A is spaced apart from the high-concentration region 61 in the Z direction. The p-type impurity concentration in the first contact region 63A is higher than the n-type impurity concentration in the first low-concentration region 62A.

The second contact region 63B is a p-type region provided in the surface layer portion of the second low-concentration region 62B. The second contact region 63B is exposed from the first surface 20S of the semiconductor chip 20. The second contact region 63B is spaced apart from the high-concentration region 61 in the Z direction. The p-type impurity concentration in the second contact region 63B is higher than the n-type impurity concentration in the second low-concentration region 62B. The p-type impurity concentration in the second contact region 63B is equal to the p-type impurity concentration in the first contact region 63A.

The third contact region 63C is a p-type region provided in the surface layer portion of the third low-concentration region 62C. The third contact region 63C is exposed from the first surface 20S of the semiconductor chip 20. The third contact region 63C is spaced apart from the high-concentration region 61 in the Z direction. The p-type impurity concentration in the third contact region 63C is higher than the n-type impurity concentration in the third low-concentration region 62C. The p-type impurity concentration in the third contact region 63C is equal to the p-type impurity concentration in the first contact region 63A.

The peak values of the p-type impurity concentrations in the first to third contact regions 63A to 63C may be 1×10¹⁸ cm⁻³ or more and 1×10²¹ cm⁻³ or less. In one example, the peak value of the p-type impurity concentration in each of the first to third contact regions 63A to 63C is 5×10¹⁸ cm⁻³ or more and 1×10²⁰ cm⁻³ or less.

As such, in the first reverse pin junction portion 60A, the p-type first contact region 63A forms the P layer of the pin diode, the n-type first low-concentration region 62A forms the I layer of the pin diode, and the n-type high-concentration region 61 forms the N layer of the pin diode. That is, the first contact region 63A, the first low-concentration region 62A, and the high-concentration region 61 form a pin junction in the Z direction. Therefore, in the first reverse pin junction portion 60A, the high-concentration region 61, the first low-concentration region 62A, and the first contact region 63A form the pin diode (diode 204) of the second polarity direction.

In the second reverse pin junction portion 60B, the p-type second contact region 63B forms the P layer of the pin diode, the n-type second low-concentration region 62B forms the I layer of the pin diode, and the n-type high-concentration region 61 forms the N layer of the pin diode. That is, the second contact region 63B, the second low-concentration region 62B, and the high-concentration region 61 form a pin junction in the Z direction. Therefore, in the second reverse pin junction portion 60B, the high-concentration region 61, the second low-concentration region 62B, and the second contact region 63B form a pin diode (diode 205) of the second polarity direction.

In the third reverse pin junction portion 60C, the p-type third contact region 63C forms the Player of the pin diode, the n-type third low-concentration region 62C forms the I layer of the pin diode, and the n-type high-concentration region 61 forms the N layer of the pin diode. That is, the third contact region 63C, the third low-concentration region 62C, and the high-concentration region 61 form a pin junction in the Z direction. Therefore, in the third reverse pin junction portion 60C, the high-concentration region 61, the third low-concentration region 62C, and the third contact region 63C form a pin diode (diode 206) of the second polarity direction.

The internal region 64 is a p-type region provided to be in contact with the high-concentration region 61 and closer to the second surface 20R of the semiconductor chip 20 than the high-concentration region 61. The internal region 64 is provided at a position overlapping the high-concentration region 61 in the plan view. The internal region 64 is provided across a region of the second semiconductor layer 24 that is close to the first semiconductor layer 23 and the surface layer portion of the first semiconductor layer 23 in the Z direction. The internal region 64 is provided to overlap each of the first low-concentration region 62A, the second low-concentration region 62B, and the third low-concentration region 62C in the plan view.

The internal region 64 is configured to suppress the decrease in p-type impurity concentration in the first semiconductor layer 23. That is, the internal region 64 is configured to maintain a predetermined p-type impurity concentration. The p-type impurity concentration in the internal region 64 may be 1×10¹⁶ cm⁻³ or more and 1×10¹⁹ cm⁻³ or less. In one example, the p-type impurity concentration in the internal region 64 is 1×10¹⁸ cm⁻³. Thus, the p-type impurity concentration in the internal region 64 may be equal to the p-type impurity concentration in the first region 31A of the first-terminal-side high-concentration region 31 in the first pin junction portion 30.

The pn junction portion 60E is formed of the p-type internal region 64 and the n-type high-concentration region 61. That is, the internal region 64 and the high-concentration region 61 form a pn junction in the Z direction. Therefore, the internal region 64 and the high-concentration region 61 form a pn diode (diode 207) of the first polarity direction. The pn diode is connected in the reverse direction to the pin diode of the first reverse pin junction portion 60A, the pin diode of the second reverse pin junction portion 60B, and the pin diode of the third reverse pin junction portion 60C. Thus, it can be said that the pn junction portion 60E is connected in the reverse direction to the first reverse pin junction portion 60A, the second reverse pin junction portion 60B, and the third reverse pin junction portion 60C. Herein, the breakdown voltage at the pn junction portion 60E can be set by the p-type impurity concentration in the internal region 64. That is, the p-type impurity concentration in the internal region 64 is adjusted according to the desired breakdown voltage at the pn junction portion 60E.

The separation region 65 is an n-type region provided in a region closer to the first surface 20S than the high-concentration region 61. The separation region 65 is provided at a position overlapping the high-concentration region 61 in the plan view. The separation region 65 is a region that separates the first low-concentration region 62A, the second low-concentration region 62B, and the third low-concentration region 62C. Therefore, the separation region 65 is provided to surround each of the first low-concentration region 62A, the second low-concentration region 62B, and the third low-concentration region 62C in the plan view.

The peak value of the n-type impurity concentration in the separation region 65 may be equal to the peak value of the n-type impurity concentration in the high-concentration region 61. In one example, the peak value of the n-type impurity concentration in the separation region 65 may be 1×10¹⁸ cm⁻³ or more and 1×10²¹ cm⁻³ or less. In one example, the peak value of the n-type impurity concentration in the separation region 65 is 5×10¹⁸ cm⁻³ or more and 1×10²⁰ cm⁻³ or less.

In the first reverse pin junction portion 60A, a pin diode is formed of the first contact region 63A, the first low-concentration region 62A, and a portion of the separation region 65 that surrounds the first low-concentration region 62A. Thus, in the first reverse pin junction portion 60A, a first current path is provided in which the forward current flows in the order of the first contact region 63A, the first low-concentration region 62A, and the high-concentration region 61, and a second current path is provided in which the forward current flows in the order of the first contact region 63A, the first low-concentration region 62A, and the separation region 65.

In the second reverse pin junction portion 60B, a pin diode is formed of the second contact region 63B, the second low-concentration region 62B, and a portion of the separation region 65 that surrounds the second low-concentration region 62B. Thus, in the second reverse pin junction portion 60B, a first current path is provided in which the forward current flows in the order of the second contact region 63B, the second low-concentration region 62B, and the high-concentration region 61, and a second current path is provided in which the forward current flows in the order of the second contact region 63B, the second low-concentration region 62B, and the separation region 65.

In the third reverse pin junction portion 60C, a pin diode is formed of the third contact region 63C, the third low-concentration region 62C, and a portion of the separation region 65 that surrounds the third low-concentration region 62C. Thus, in the third reverse pin junction portion 60C, a first current path is provided in which the forward current flows in the order of the third contact region 63C, the third low-concentration region 62C, and the high-concentration region 61, and a second current path is provided in which the forward current flows in the order of the third contact region 63C, the third low-concentration region 62C, and the separation region 65.

Each of the cathode of the pin diode of the first reverse pin junction portion 60A, the cathode of the pin diode of the second reverse pin junction portion 60B, and the cathode of the pin diode of the third reverse pin junction portion 60C is electrically connected to the cathode of the pn diode of the pn junction portion 60E. Therefore, each of the first to third reverse pin junction portions 60A to 60C forms a diode pair between itself and the pn junction portion 60E.

### (Configuration on Semiconductor Chip)

The TVS diode 10 includes an insulating layer 70 that covers the first surface 20S of the semiconductor chip 20. The insulating layer 70 may comprise a laminated structure formed of multiple insulating layers, or may comprise a single-layer structure formed of a single insulating layer. The insulating layer 70 may include at least one of a SiO₂ (silicon oxide) layer and a SiN (silicon nitride) layer. The insulating layer 70 may comprise a laminated structure in which a SiO₂ layer and a SiN layer are laminated in any order. The insulating layer 70 may also comprise a single-layer structure formed of either a SiO₂ layer or a SiN layer. The thickness of the insulating layer 70 may be 1 μm or more and 10 μm or less. In one example, the thickness of the insulating layer 70 is 2 μm or more and 3 μm or less.

In one example, the insulating layer 70 includes a laminated structure of a first insulating layer 71 and a second insulating layer 72. The first insulating layer 71 is in contact with the first surface 20S of the semiconductor chip 20. The first insulating layer 71 is a single-layer structure formed of a single SiO₂ layer. The first insulating layer 71 is also referred to as a field oxide film. The thickness of the first insulating layer 71 may be, for example, 14000 Å.

The second insulating layer 72 is provided on the first insulating layer 71. The second insulating layer 72 may include at least one of an USG (Undoped Silica Glass) layer, a PSG (Phosphor Silicate Glass) layer, and a BPSG (Boron Phosphor Silicate Glass) layer. In one example, the second insulating layer 72 is formed of a laminated structure of a USG layer and a BPSG layer. The thickness of the second insulating layer 72 is, for example, thinner than the thickness of the first insulating layer 71. The thickness of the second insulating layer 72 may be, for example, 6700 Å.

The insulating layer 70 includes first to sixth opening portions 73A to 73F and a wiring opening portion 73G that expose the first surface 20S of the semiconductor chip 20. Each of the first to sixth opening portions 73A to 73F and the wiring opening portion 73G penetrates the insulating layer 70 in the Z direction.

The first opening portion 73A exposes the first-terminal-side contact region 33 of the first pin junction portion 30. The second opening portion 73B exposes the second-terminal-side contact region 43 of the second pin junction portion 40. The third opening portion 73C exposes the third-terminal-side contact region 53 of the third pin junction portion 50. The fourth opening portion 73D exposes the first contact region 63A of the first reverse pin junction portion 60A. The fifth opening portion 73E exposes the second contact region 63B of the second reverse pin junction portion 60B. The sixth opening portion 73F exposes the third contact region 63C of the third reverse pin junction portion 60C.

The wiring opening portion 73G exposes the separation region 65 of the diode pair region 60. Therefore, the separation region 65 includes an exposed surface 65S that is exposed from the first surface 20S of the semiconductor chip 20.

The TVS diode 10 includes a first connection electrode 81, a second connection electrode 82, and a third connection electrode 83 provided on the insulating layer 70. Each of the first to third connection electrodes 81 to 83 is formed of a material that includes at least one of Cu (copper) and Al (aluminum). In one example, each of the first to third connection electrodes 81 to 83 is formed of AlCu. The thickness of each of the first to third connection electrodes 81 to 83 may be, for example, 42000 Å.

The first connection electrode 81 electrically connects the first-terminal-side contact region 33 of the first pin junction portion 30 and the first contact region 63A of the first reverse pin junction portion 60A. The first connection electrode 81 is in contact with the first-terminal-side contact region 33 through the first opening portion 73A of the insulating layer 70. The first connection electrode 81 is in contact with the first contact region 63A through the fourth opening portion 73D of the insulating layer 70.

The second connection electrode 82 electrically connects the second-terminal-side contact region 43 of the second pin junction portion 40 and the second contact region 63B of the second reverse pin junction portion 60B. The second connection electrode 82 is in contact with the second-terminal-side contact region 43 through the second opening portion 73B of the insulating layer 70. The second connection electrode 82 is in contact with the second contact region 63B through the fifth opening portion 73E of the insulating layer 70.

The third connection electrode 83 electrically connects the third-terminal-side contact region 53 of the third pin junction portion 50 and the third contact region 63C of the third reverse pin junction portion 60C. The third connection electrode 83 is in contact with the third-terminal-side contact region 53 through the third opening portion 73C of the insulating layer 70. The third connection electrode 83 is in contact with the third contact region 63C through the sixth opening portion 73F of the insulating layer 70.

The TVS diode 10 includes a wiring 90 connected to the exposed surface 65S of the separation region 65 of the diode pair region 60. The wiring 90 is formed of a material including at least one of Cu and Al. In one example, the wiring 90 is formed of AlCu. That is, the wiring 90 may be formed of the same material as each of the first to third connection electrodes 81 to 83. Furthermore, the detailed configuration of the wiring 90 are described later.

The TVS diode 10 includes a protective layer 74 that covers the insulating layer 70, the first to third connection electrodes 81 to 83, and the wiring 90. The protective layer 74 is an insulating layer that protects the semiconductor chip 20. The protective layer 74 may comprise a laminated structure in which multiple insulating layers are laminated, or may comprise a single-layer structure formed of a single insulating layer.

In one example, the protective layer 74 comprises a laminated structure of a first protective layer 75 and a second protective layer 76. In one example, the first protective layer 75 may be a passivation layer, and the second protective layer 76 may be a resin layer.

The first protective layer 75 may comprise a single-layer structure that includes a SiO₂ layer or a SiN layer, or may comprise a laminated structure in which a SiO₂ layer and a SiN layer are laminated in any order. In one example, the first protective layer 75 is a single-layer structure formed of a SiN layer.

The second protective layer 76 may include a photosensitive resin. The second protective layer 76 may include at least one of PI (polyimide), PA (polyamide), and PBO (polybenzoxazole) as an example of a photosensitive resin. In one example, the second protective layer 76 includes PI.

The protective layer 74 includes first to third terminal opening portions 77A to 77C. The first to third terminal opening portions 77A to 77C penetrate the protective layer 74 in the Z direction. The first terminal opening portion 77A partially exposes the first connection electrode 81. The first terminal opening portion 77A is provided at a position overlapping the first opening portion 73A of the insulating layer 70 in the plan view. The second terminal opening portion 77B partially exposes the second connection electrode 82. The second terminal opening portion 77B is provided at a position overlapping the second opening portion 73B of the insulating layer 70 in the plan view. The third terminal opening portion 77C partially exposes the third connection electrode 83. The third terminal opening portion 77C is provided at a position overlapping the third opening portion 73C of the insulating layer 70 in the plan view.

### [Planar Structure of TVS Diode]

Referring to FIG. 1 and FIGS. 4 to 7, the planar structure of the TVS diode 10 is illustrated. FIG. 4 schematically shows the planar structure of the first surface 20S of the semiconductor chip 20. FIG. 5 schematically shows the cross-sectional structure of the semiconductor chip 20 taken along line F5-F5 in FIG. 3. FIG. 6 schematically shows a cross-sectional structure that enlarges portions of both the high-concentration region 61 and the internal region 64 of FIG. 5. Furthermore, in FIG. 5 and FIG. 6, hatching lines are omitted for easier understanding of the figures. FIG. 7 schematically shows the planar structure of the first to third connection electrodes 81 to 83 and the wiring 90 of the TVS diode 10.

### (Semiconductor Chip)

As shown in FIG. 4, the TVS diode 10 includes an outer peripheral region 110 provided on the outer periphery of the first surface 20S of the semiconductor chip 20. The outer peripheral region 110 is a region that includes p-type impurities. The outer peripheral region 110 is provided to surround the first pin junction portion 30, the second pin junction portion 40, the third pin junction portion 50, and the diode pair region 60 in the plan view.

The outer peripheral region 110 is integrated with the first-terminal-side high-concentration region 31 (refer to FIG. 2) and the first partition region 34 of the first pin junction portion 30, the second-terminal-side high-concentration region 41 (refer to FIG. 3) and the second partition region 44 of the second pin junction portion 40, and the third-terminal-side high-concentration region 51 (refer to FIG. 2) and the third partition region 54 of the third pin junction portion 50. The concentration gradient of the p-type impurity in the outer peripheral region 110 is similar to that of the first-terminal-side high-concentration region 31 and the first partition region 34, for example.

The outer peripheral region 110 includes a first region 111 extending along the first side surface 20A, a second region 112 extending along the second side surface 20B, a third region 113 extending along the third side surface 20C, and a fourth region 114 extending along the fourth side surface 20D in the plan view.

The first pin junction portion 30, the second pin junction portion 40, and the third pin junction portion 50 are disposed spaced apart from each other. More specifically, the first pin junction portion 30 and the third pin junction portion 50 are disposed at the same position as each other in the Y direction and are spaced apart from each other in the X direction. The first pin junction portion 30 and the third pin junction portion 50 are disposed at the end closer to the fourth side surface 20D among the two ends of the first surface 20S of the semiconductor chip 20 in the Y direction. The first pin junction portion 30 is disposed at the end closer to the first side surface 20A among the two ends of the first surface 20S in the X direction. The third pin junction portion 50 is disposed at the end closer to the second side surface 20B among the two ends of the first surface 20S in the X direction.

The second pin junction portion 40 is disposed at different positions in the X and Y directions relative to both the first pin junction portion 30 and the third pin junction portion 50. The second pin junction portion 40 is disposed at the end closer to the third side surface 20C among the two ends of the first surface 20S of the semiconductor chip 20 in the Y direction. The second pin junction portion 40 is disposed at the center in the X direction of the first surface 20S. Therefore, it can be said that the second pin junction portion 40 is disposed between the first pin junction portion 30 and the third pin junction portion 50 in the X direction when viewed from the Y direction.

The first partition region 34 of the first pin junction portion 30 is connected to the first region 111 and the fourth region 114 of the outer peripheral region 110. As a result, the first-terminal-side low-concentration region 32 of the first pin junction portion 30 is partitioned by the first region 111, the fourth region 114, and the first partition region 34 in the plan view. The first partition region 34 includes a first portion that extends in the X direction and is connected to the first region 111, a second portion that extends in the Y direction and is connected to the fourth region 114, and a connection portion that connects the first portion and the second portion. The connection portion is curved in the plan view.

The first-terminal-side low-concentration region 32 is rectangular in the plan view. Each of the four corner portions of the rectangular first-terminal-side low-concentration region 32 is curved. The first-terminal-side contact region 33 is rectangular in the plan view. Each of the four corner portions of the rectangular first-terminal-side contact region 33 is curved. The first-terminal-side contact region 33 is slightly smaller than the first-terminal-side low-concentration region 32 in the plan view.

The second partition region 44 of the second pin junction portion 40 is connected to the third region 113 of the outer peripheral region 110. The second partition region 44 is of a U-shape that opens toward the third region 113 in the plan view. The second-terminal-side low-concentration region 42 of the second pin junction portion 40 is partitioned by the third region 113 and the second partition region 44 in the plan view. The second partition region 44 includes a first portion and a second portion that extend in the Y direction and are connected to the third region 113, and a third portion that extends in the X direction and is disposed spaced apart from the third region 113 toward the fourth side surface 20D. The first portion and the second portion are disposed spaced apart from each other in the X direction. The second partition region 44 includes a first connection portion that connects the first portion and the third portion, and a second connection portion that connects the second portion and the third portion. Each connection portion is curved in the plan view.

The second-terminal-side low-concentration region 42 is rectangular in the plan view. Each of the four corner portions of the rectangular second-terminal-side low-concentration region 42 is curved. The second-terminal-side low-concentration region 42 may have the same size and shape as the first-terminal-side low-concentration region 32, for example. The second-terminal-side contact region 43 is rectangular in the plan view. Each of the four corner portions of rectangular second-terminal-side contact region 43 is curved. The second-terminal-side contact region 43 is slightly smaller than the second-terminal-side low-concentration region 42 in the plan view. The second-terminal-side contact region 43 may have the same size and shape as the first-terminal-side contact region 33, for example.

The third partition region 54 of the third pin junction portion 50 is connected to the second region 112 and the fourth region 114 of the outer peripheral region 110. Therefore, the third-terminal-side low-concentration region 52 of the third pin junction portion 50 is partitioned by the second region 112, the fourth region 114, and the third partition region 54 in the plan view. The third partition region 54 includes a first portion that extends in the X direction and is connected to the second region 112, a second portion that extends in the Y direction and is connected to the fourth region 114, and a connection portion that connects the first portion and the second portion. The connection portion is curved in the plan view.

The third-terminal-side low-concentration region 52 is rectangular in the plan view. Each of the four corner portions of the rectangular third-terminal-side low-concentration region 52 is curved. The third-terminal-side low-concentration region 52 may have the same size and shape as the first-terminal-side low-concentration region 32, for example. The third-terminal-side contact region 53 is rectangular in the plan view. Each of the four corner portions of the rectangular third-terminal-side contact region 53 is curved. The third-terminal-side contact region 53 is slightly smaller than the third-terminal-side low-concentration region 52 in the plan view. The third-terminal-side contact region 53 may have the same size and shape as the first-terminal-side contact region 33, for example.

In one example, the shortest distance DA between the first partition region 34 and the second partition region 44 is equal to the shortest distance DB between the second partition region 44 and the third partition region 54. The shortest distance DC between the first partition region 34 and the third partition region 54 may be less than or equal to the shortest distances DA and DB.

The diode pair region 60 is provided in the region surrounded by the outer peripheral region 110, the first partition region 34, the second partition region 44, and the third partition region 54 in the plan view. Therefore, the diode pair region 60 is provided in each of the following: between the first pin junction portion 30 and the second pin junction portion 40, between the second pin junction portion 40 and the third pin junction portion 50, and between the first pin junction portion 30 and the third pin junction portion 50.

The diode pair region 60 includes the first region 66A, the second region 66B, and the third region 66C.

The first region 66A is a region located side by side with the first pin junction portion 30 in the Y direction. The first region 66A is disposed closer to the third side surface 20C than the first pin junction portion 30. The first region 66A is provided with the first inverse pin junction portion 60A. Therefore, it can be said that the first pin junction portion 30 and the first inverse pin junction portion 60A are located side by side in the Y direction in the plan view. The first region 66A includes a region located side by side with the second pin junction portion 40 in the X direction. The first region 66A is disposed closer to the first side surface 20A than the second pin junction portion 40 in the X direction. Viewed from the X direction, the first inverse pin junction portion 60A includes a portion that overlaps the second pin junction portion 40.

The first region 66A is substantially rectangular in the plan view. In one example, the first region 66A has a substantially rectangular shape with its longitudinal direction in the Y direction and its lateral direction in the X direction. The first region 66A includes the first to fourth sides 66AA to 66AD. The first side 66AA is a side of the first region 66A close to the first side surface 20A and extends in the Y direction in the plan view. The second side 66AB is a side of the first region 66A close to the second side surface 20B and extends in the Y direction in the plan view. The length of the second side 66AB in the Y direction is shorter than the length of the first side 66AA in the Y direction. The third side 66AC is a side of the first region 66A close to the third side surface 20C and extends in the X direction in the plan view. The fourth side 66AD is a side of the first region 66A close to the fourth side surface 20D and extends in the X direction in the plan view. The length of the fourth side 66AD in the X direction is shorter than the length of the third side 66AC in the X direction.

The first region 66A includes a corner portion between the first side 66AA and the third side 66AC, a corner portion between the first side 66AA and the fourth side 66AD, and a corner portion between the second side 66AB and the third side 66AC. Each corner portion is curved in the plan view.

The second region 66B is a region located side by side with the second pin junction portion 40 in the Y direction. The second region 66B is disposed closer to the fourth side surface 20D than the second pin junction portion 40. The second region 66B is provided with the second reverse pin junction portion 60B. Therefore, it can be said that the second pin junction portion 40 and the second reverse pin junction portion 60B are located side by side in the Y direction in the plan view. The second region 66B includes a region disposed between the first pin junction portion 30 and the third pin junction portion 50 in the X direction. As a result, the second region 66B includes a region positioned to be shifted in the Y direction relative to the first region 66A. The second region 66B is disposed closer to the second side surface 20B than the first region 66A in the X direction. Viewed from the X direction, the second reverse pin junction portion 60B includes a portion that overlaps both the first pin junction portion 30 and the third pin junction portion 50.

The second region 66B is substantially rectangular in the plan view. In one example, the second region 66B has a substantially rectangular shape with its longitudinal direction in the Y direction and its lateral direction in the X direction. The second region 66B includes first to fourth sides 66BA to 66BD. The first side 66BA is a side of the second region 66B close to the first side surface 20A and extends in the Y direction in the plan view. The length of the first side 66BA in the Y direction is equal to, for example, the length of the second side 66AB of the first region 66A in the Y direction. The second side 66BB is a side of the second region 66B close to the second side surface 20B and extends in the Y direction in the plan view. The length of the second side 66BB in the Y direction is equal to the length of the first side 66BA in the Y direction. The third side 66BC is a side of the second region 66B close to the third side surface 20C and extends in the X direction in the plan view. The fourth side 66BD is a side of the second region 66B close to the fourth side surface 20D and extends in the X direction in the plan view. Each of the first side 66BA, the second side 66BB, and the fourth side 66BD is disposed closer to the fourth side surface 20D than the first region 66A in the Y direction. The length of the fourth side 66BD in the X direction is longer than the length of the third side 66BC in the X direction. The length of the third side 66BC in the X direction is shorter than the length of the third side 66AC of the first region 66A in the X direction.

The second region 66B includes a corner portion between the first side 66BA and the fourth side 66BD, and a corner portion between the second side 66BB and the fourth side 66BD. Each corner portion is curved in the plan view.

The third region 66C is a region located side by side with the third pin junction portion 50 in the Y direction. The third region 66C is disposed closer to the third side surface 20C than the third pin junction portion 50. The third region 66C is disposed at the same position in the Y direction as the first region 66A. The third region 66C is disposed spaced apart from the first region 66A in the X direction. The third region 66C is provided with the third reverse pin junction portion 60C. Therefore, it can be said that the third pin junction portion 50 and the third reverse pin junction portion 60C are located side by side in the Y direction in the plan view. The third region 66C includes a region located side by side with the second pin junction portion 40 in the X direction. The third region 66C is disposed closer to the second side surface 20B than the second pin junction portion 40 in the X direction. As a result, it can be said that the second pin junction portion 40 is disposed between the first region 66A and the third region 66C in the X direction. Viewed from the X direction, the third reverse pin junction portion 60C includes a portion that overlaps the second pin junction portion 40.

The third region 66C is substantially rectangular in the plan view. In one example, the third region 66C has a substantially rectangular shape with its longitudinal direction in the Y direction and its lateral direction in the X direction. The third region 66C includes first to fourth sides 66CA to 66CD. The first side 66CA is a side of the third region 66C close to the first side surface 20A and extends in the Y direction in the plan view. The length of the first side 66CA in the Y direction is equal to, for example, the length of the second side 66AB of the first region 66A in the Y direction. The second side 66CB is a side of the third region 66C close to the second side surface 20B and extends in the Y direction in the plan view. The length of the second side 66CB in the Y direction is longer than the length of the first side 66CA in the Y direction. The length of the second side 66CB in the Y direction is equal to, for example, the length of the first side 66AA of the first region 66A in the Y direction. The third side 66CC is a side of the third region 66C close to the third side surface 20C and extends in the X direction in the plan view. The fourth side 66CD is a side of the third region 66C close to the fourth side surface 20D and extends in the X direction in the plan view. The length of the third side 66CC in the X direction is longer than the length of the fourth side 66CD in the X direction. The length of the third side 66CC in the X direction is equal to, for example, the length of the third side 66AC of the first region 66A in the X direction. The length of the fourth side 66CD in the X direction is equal to, for example, the length of the fourth side 66AD of the first region 66A in the X direction.

The third region 66C includes a corner portion between the first side 66CA and the third side 66CC, a corner portion between the second side 66CB and the fourth side 66CD, and a corner portion between the second side 66CB and the third side 66CC. Each corner portion is curved in the plan view.

In the example shown in FIG. 4, the width dimension (the dimension in the X direction) WB of the second region 66B is larger than the width dimension (the dimension in the X direction) WA of the first region 66A and the width dimension (the dimension in the X direction) WC of the third region 66C. Additionally, the width dimension WA of the first region 66A is equal to the width dimension WC of the third region 66C. Furthermore, the width dimension WA of the first region 66A, the width dimension WB of the second region 66B, and the width dimension WC of the third region 66C may be arbitrarily changed. In one example, the width dimension WA of the first region 66A may be different from the width dimension WC of the third region 66C. In one example, the width dimension WB of the second region 66B may be equal to the width dimension WA of the first region 66A. In one example, the width dimension WB of the second region 66B may be equal to the width dimension WC of the third region 66C.

The diode pair region 60 includes a first connection region 67A that connects the first region 66A and the second region 66B, and a second connection region 67B that connects the second region 66B and the third region 66C. The first connection region 67A is provided between the first region 66A and the second region 66B in the X direction, and the second connection region 67B is provided between the second region 66B and the third region 66C in the X direction. The first connection region 67A is disposed between the first pin junction portion 30 and the second pin junction portion 40 in a direction that intersects both the X direction and the Y direction in the plan view. The second connection region 67B is disposed between the second pin junction portion 40 and the third pin junction portion 50 in a direction that intersects both the X direction and the Y direction in the plan view.

The first connection region 67A connects the second side 66AB of the first region 66A and the third side 66BC of the second region 66B, and connects the fourth side 66AD of the first region 66A and the first side 66BA of the second region 66B. Both ends of the first connection region 67A in the Y direction are curved in the plan view. The radius of curvature of both ends of the first connection region 67A in the Y direction is larger than the radius of curvature of each corner portion of the first region 66A.

The second connection region 67B connects the second side 66BB of the second region 66B and the fourth side 66CD of the third region 66C, and connects the third side 66BC of the second region 66B and the first side 66CA of the third region 66C. Both ends of the second connection region 67B in the Y direction are curved in the plan view. The radius of curvature of both ends of the second connection region 67B in the Y direction is larger than the radius of curvature of each corner portion of the third region 66C.

The first low-concentration region 62A of the first reverse pin junction portion 60A has an elliptical shape with its longitudinal direction in the Y direction and its lateral direction in the X direction in the plan view. In one example, the dimension in the X direction (width dimension) of the first low-concentration region 62A is smaller than the dimension in the X direction of the first-terminal-side low-concentration region 32 of the first pin junction portion 30. In one example, the width dimension of the first low-concentration region 62A is smaller than the dimension in the X direction of the first-terminal-side contact region 33 of the first pin junction portion 30. In one example, the dimension in the Y direction (length dimension) of the first low-concentration region 62A is larger than the dimension in the Y direction of the first-terminal-side low-concentration region 32.

The first contact region 63A of the first reverse pin junction portion 60A has an elliptical shape with its longitudinal direction in the Y direction and its lateral direction in the X direction in the plan view. The first contact region 63A is slightly smaller than the first low-concentration region 62A in the plan view. The dimension in the X direction (width dimension) of the first contact region 63A is smaller than the dimension in the X direction of the first-terminal-side contact region 33. The dimension in the Y direction (length dimension) of the first contact region 63A is larger than the dimension in the Y direction of the first-terminal-side low-concentration region 32.

The second reverse pin junction portion 60B is disposed closer to the fourth side surface 20D relative to the first reverse pin junction portion 60A. The second reverse pin junction portion 60B includes a region that overlaps the first reverse pin junction portion 60A when viewed from the X direction. More specifically, both the second low-concentration region 62B and the second contact region 63B of the second reverse pin junction portion 60B include regions that overlap both the first low-concentration region 62A and the first contact region 63A of the first reverse pin junction portion 60A.

The second low-concentration region 62B has an elliptical shape with its longitudinal direction in the Y direction and its lateral direction in the X direction in the plan view. In one example, the dimension in the X direction (width dimension) of the second low-concentration region 62B is smaller than the dimension in the X direction of the second-terminal-side low-concentration region 42 of the second pin junction portion 40. In one example, the width of the second low-concentration region 62B is smaller than the dimension in the X direction of the second-terminal-side contact region 43 of the second pin junction portion 40. In one example, the dimension in the Y direction (length dimension) of the second low-concentration region 62B is larger than the dimension in the Y direction of the second-terminal-side low-concentration region 42. In one example, the width dimension and the length dimension of the second low-concentration region 62B are equal to the width dimension and the length dimension of the first low-concentration region 62A.

The second contact region 63B has an elliptical shape with its longitudinal direction in the Y direction and its lateral direction in the X direction in the plan view. The second contact region 63B is smaller than the second low-concentration region 62B in the plan view. The dimension in the X direction (width dimension) of the second contact region 63B is smaller than the dimension in the X direction of the second-terminal-side contact region 43. The dimension in the Y direction (length dimension) of the second contact region 63B is larger than the dimension in the Y direction of the second-terminal-side low-concentration region 42. In one example, the width dimension and the length dimension of the second contact region 63B are equal to the width dimension and the length dimension of the first contact region 63A.

The third reverse pin junction portion 60C is disposed closer to the third side surface 20C than the second reverse pin junction portion 60B. The third reverse pin junction portion 60C includes a region that overlaps the second reverse pin junction portion 60B when viewed from the X direction. More specifically, both the third low-concentration region 62C and the third contact region 63C of the third reverse pin junction portion 60C include regions that overlap both the second low-concentration region 62B and the second contact region 63B. Additionally, the third reverse pin junction portion 60C is disposed at the same position in the Y direction as the first reverse pin junction portion 60A.

The third low-concentration region 62C has an elliptical shape with its longitudinal direction in the Y direction and its lateral direction in the X direction in the plan view. In one example, the dimension in the X direction (width dimension) of the third low-concentration region 62C is smaller than the dimension in the X direction of the third-terminal-side low-concentration region 52 of the third pin junction portion 50. In one example, the width dimension of the third low-concentration region 62C is smaller than the dimension in the X direction of the third-terminal-side contact region 53 of the third pin junction portion 50. In one example, the dimension in the Y direction (length dimension) of the third low-concentration region 62C is larger than the dimension in the Y direction of the third-terminal-side low-concentration region 52. In one example, the width dimension and the length dimension of the third low-concentration region 62C are equal to the width dimension and the length dimension of the first low-concentration region 62A.

The third contact region 63C has an elliptical shape with its longitudinal direction in the Y direction and its lateral direction in the X direction in the plan view. The third contact region 63C is slightly smaller than the third low-concentration region 62C in the plan view. The dimension in the X direction (width dimension) of the third contact region 63C is smaller than the dimension in the X direction of the third-terminal-side contact region 53. The dimension in the Y direction (length dimension) of the third contact region 63C is larger than the dimension in the Y direction of the third-terminal-side low-concentration region 52. In one example, the width dimension and the length dimension of the third contact region 63C are equal to the width dimension and the length dimension of the first contact region 63A.

The high-concentration region 61 has the same area as the diode pair region 60 in the plan view. The shape and size of the high-concentration region 61 in the plan view are the same as the shape and size of the diode pair region 60.

The separation region 65 is the region that excludes the first low-concentration region 62A, the second low-concentration region 62B, the third low-concentration region 62C, the first contact region 63A, the second contact region 63B, and the third contact region 63C from the high-concentration region 61 in the plan view. Therefore, both the first connection region 67A and the second connection region 67B are provided with the separation region 65 in the plan view. The separation region 65 is provided around the entire outer edge of the diode pair region 60 (high-concentration region 61). The separation region 65 is provided to surround the entire perimeter of the first low-concentration region 62A in the first region 66A. The separation region 65 is provided to surround the entire perimeter of the second low-concentration region 62B in the second region 66B. The separation region 65 is provided to surround the entire perimeter of the third low-concentration region 62C in the third region 66C.

The area of the separation region 65 in the plan view is larger than the sum of the area of the first low-concentration region 62A in the plan view, the area of the second low-concentration region 62B in the plan view, and the area of the third low-concentration region 62C in the plan view.

As shown in FIG. 5, the internal region 64 is provided to overlap all of the first region 66A, the second region 66B, and the third region 66C in the plan view. The internal region 64 is provided to overlap both the first connection region 67A and the second connection region 67B in the plan view. In one example, the internal region 64 is slightly smaller than the high-concentration region 61 in the plan view.

The internal region 64 includes the first region 68A, the second region 68B, the third region 68C, the first connection region 69A, and the second connection region 69B, similar to the diode pair region 60.

The first region 68A is provided at a position overlapping the first region 66A in the plan view. The first region 68A is slightly smaller than the first region 66A in the plan view. The first region 68A includes first to fourth sides 68AA to 68AD. The first to fourth sides 68AA to 68AD are sides that correspond to the first to fourth sides 66AA to 66AD of the first region 66A. The first to fourth sides 68AA to 68AD are disposed inside the first region 66A relative to the first to fourth sides 66AA to 66AD in the plan view. That is, it can be said that the first region 68A is disposed within the first region 66A in the plan view. Additionally, the first region 68A is disposed to overlap the entirety of the first low-concentration region 62A (refer to FIG. 4) in the plan view.

The second region 68B is disposed at a position overlapping the second region 66B in the plan view. The second region 68B is slightly smaller than the second region 66B in the plan view. The second region 68B includes first to fourth sides 68BA to 68BD. The first to fourth sides 68BA to 68BD are sides that correspond to the first to fourth sides 66BA to 66BD of the second region 66B. The first to fourth sides 68BA to 68BD are disposed inside the second region 66B relative to the first to fourth sides 66BA to 66BD in the plan view. That is, it can be said that the second region 68B is disposed within the second region 66B in a plan view. Additionally, the second region 68B is disposed to overlap the entirety of the second low-concentration region 62B (refer to FIG. 4) in the plan view.

The third region 68C is disposed at a position overlapping the third region 66C in the plan view. The third region 68C is slightly smaller than the third region 66C in the plan view. The third region 68C includes first to fourth sides 68CA to 68CD. The first to fourth sides 68CA to 68CD are sides that correspond to the first to fourth sides 66CA to 66CD of the third region 66C. The first to fourth sides 68CA to 68CD are disposed inside the third region 66C relative to the first to fourth sides 66CA to 66CD in the plan view. That is, it can be said that the third region 68C is disposed within the third region 66C in the plan view. Additionally, the third region 68C is disposed to overlap the entirety of the third low-concentration region 62C (refer to FIG. 4) in the plan view.

The first connection region 69A is disposed at a position overlapping the first connection region 67A in the plan view. The first connection region 69A is slightly smaller than the first connection region 67A in the plan view. The first connection region 69A is disposed within the first connection region 67A in the plan view. The first connection region 69A connects the second side 68AB of the first region 68A and the third side 68BC of the second region 68B, and connects the fourth side 68AD of the first region 68A and the first side 68BA of the second region 68B. Both ends of the first connection region 69A in the Y direction are curved in the plan view. The radius of curvature of the both ends of the first connection region 69A in the Y direction is larger than the radius of curvature of each corner portion of the first region 68A.

The second connection region 69B is disposed at a position overlapping the second connection region 67B in the plan view. The second connection region 69B is slightly smaller than the second connection region 67B in the plan view. The second connection region 69B is disposed within the second connection region 67B in the plan view. The second connection region 69B connects the second side 68BB of the second region 68B and the fourth side 68CD of the third region 68C, and connects the third side 68BC of the second region 68B and the first side 68CA of the third region 68C. Both ends of the second connection region 69B in the Y direction are curved in the plan view. The radius of curvature of the both ends of the second connection region 69B in the Y direction is larger than the radius of curvature of each corner portion of the third region 68C.

As such, the internal region 64 is provided to overlap the entirety of the first low-concentration region 62A, the entirety of the second low-concentration region 62B, and the entirety of the third low-concentration region 62C in the plan view. Additionally, the internal region 64 has a shape similar to that of the high-concentration region 61 (diode pair region 60) in the plan view.

As shown in FIG. 6, the distance DD between the outer peripheral edge of the internal region 64 and the outer peripheral edge of the high-concentration region 61 is, for example, constant across the entirety of the outer peripheral edge of the internal region 64. The distance DD may be, for example, about 5 μm. Furthermore, the center of curvature C1 of the corner portion of the internal region 64 may be at the same position as the center of curvature C2 of the corner portion of the high-concentration region 61 that corresponds to the above-mentioned corner portion of the internal region 64. As a result, the radius of curvature of the corner portion of the internal region 64 is smaller than the radius of curvature of the corner portion of the high-concentration region 61.

### (Connection Electrodes and Wiring)

As shown in FIG. 7, the first connection electrode 81, the second connection electrode 82, and the third connection electrode 83 are each disposed within the outer peripheral region 110 (refer to FIG. 4) in the plan view. The first connection electrode 81, the second connection electrode 82, and the third connection electrode 83 are disposed spaced apart from each other.

The first connection electrode 81 is disposed closer to the first side surface 20A than the center of the semiconductor chip 20 in the X direction in the plan view. The first connection electrode 81 extends along the Y direction. The first connection electrode 81 includes a pin connection portion 81A and a wiring portion 81B that extends in the Y direction from the pin connection portion 81A toward the third side surface 20C. In one example, the pin connection portion 81A and the wiring portion 81B are integrated.

The pin connection portion 81A is disposed at a position overlapping the first pin junction portion 30 (refer to FIG. 4) in the plan view. The pin connection portion 81A is rectangular in the plan view. The pin connection portion 81A is disposed within the first-terminal-side low-concentration region 32 (refer to FIG. 4) of the first pin junction portion 30 in the plan view. The pin connection portion 81A is slightly larger than the first-terminal-side contact region 33 of the first pin junction portion 30 in the plan view.

The wiring portion 81B is strip-shaped with a width in the X direction in the plan view. The width dimension of the wiring portion 81B is smaller than the dimension in the X direction of the pin connection portion 81A. The wiring portion 81B is disposed to be shifted in the X direction relative to the pin connection portion 81A. More specifically, a virtual line CL1 extended in the Y direction at the center of the width of the wiring portion 81B is positioned closer to the second side surface 20B than a virtual line CL2 extended in the Y direction at the center of the X direction of the pin connection portion 81A.

The wiring portion 81B is provided to cover the first contact region 63A of the first reverse pin junction portion 60A in the plan view. In one example, the wiring portion 81B covers the entirety of the first contact region 63A in the plan view. Therefore, the width dimension of the wiring portion 81B is larger than the width dimension of the first contact region 63A. On the other hand, the width dimension of the wiring portion 81B is smaller than the width dimension of the first low-concentration region 62A. The front end portion of the wiring portion 81B is curved in the plan view.

A reverse pin connection portion 81C is provided at a position overlapping the first contact region 63A in the wiring portion 81B. The reverse pin connection portion 81C is connected to the first contact region 63A.

The second connection electrode 82 extends along the Y direction. The second connection electrode 82 is disposed spaced apart from the first connection electrode 81 toward the second side surface 20B in the X direction. The second connection electrode 82 includes a portion that overlaps the first connection electrode 81 when viewed from the X direction. In one example, the second connection electrode 82 is disposed at the center in the X direction of the semiconductor chip 20 in the plan view.

The second connection electrode 82 includes a pin connection portion 82A and a wiring portion 82B that extends in the Y direction toward the fourth side surface 20D from the pin connection portion 82A. In one example, the pin connection portion 82A and the wiring portion 82B are integrated.

The pin connection portion 82A is disposed at a position overlapping the second pin junction portion 40 (refer to FIG. 4) in the plan view. The pin connection portion 82A is rectangular in the plan view. The pin connection portion 82A is disposed within the second-terminal-side low-concentration region 42 of the second pin junction portion 40 (refer to FIG. 4) in the plan view. The pin connection portion 82A is slightly larger than the second-terminal-side contact region 43 of the second pin junction portion 40 in the plan view. In one example, the size and shape of the pin connection portion 82A are the same as the size and shape of the pin connection portion 81A.

The wiring portion 82B is strip-shaped with a width in the X direction in the plan view. The width dimension of the wiring portion 82B is smaller than the X direction dimension of the pin connection portion 82A. The wiring portion 82B is provided to cover the second contact region 63B of the second reverse pin junction portion 60B in the plan view. In one example, the wiring portion 82B covers the entirety of the second contact region 63B in the plan view. Therefore, the width dimension of the wiring portion 82B is larger than the width dimension of the second contact region 63B. On the other hand, the width dimension of the wiring portion 82B is smaller than the width dimension of the second low-concentration region 62B. The front end portion of the wiring portion 82B is curved in the plan view. In one example, the size and shape of the wiring portion 82B are the same as the size and shape of the wiring portion 81B. The wiring portion 82B is connected to the center in the X direction of the pin connection portion 82A.

A reverse pin connection portion 82C is provided at a position overlapping the second contact region 63B in the wiring portion 82B. The reverse pin connection portion 82C is connected to the second contact region 63B.

The third connection electrode 83 extends along the Y direction. The third connection electrode 83 is disposed spaced apart from the second connection electrode 82 toward the second side surface 20B in the X direction. The third connection electrode 83 includes a portion that overlaps the second connection electrode 82 when viewed from the X direction. In one example, the third connection electrode 83 is disposed at the same position in the Y direction as the first connection electrode 81.

The third connection electrode 83 includes a pin connection portion 83A and a wiring portion 83B that extends in the Y direction toward the third side surface 20C from the pin connection portion 83A. In one example, the pin connection portion 83A and the wiring portion 83B are integrated.

The pin connection portion 83A is disposed at a position overlapping the third pin junction portion 50 (refer to FIG. 4) in the plan view. The pin connection portion 83A is rectangular in the plan view. The pin connection portion 83A is disposed within the third-terminal-side low-concentration region 52 of the third pin junction portion 50 in the plan view (refer to FIG. 4). The pin connection portion 83A is slightly larger than the third-terminal-side contact region 53 of the third pin junction portion 50 in the plan view. In one example, the size and shape of the pin connection portion 83A are the same as those of the pin connection portion 81A.

The wiring portion 83B is strip-shaped with a width in the X direction in the plan view. The width dimension of the wiring portion 83B is smaller than the dimension in the X direction of the pin connection portion 83A. The wiring portion 83B is disposed to be shifted in the X direction relative to the pin connection portion 83A. More specifically, a virtual line CL3 extending in the Y direction at the center of the width of the wiring portion 83B is positioned closer to the first side surface 20A than a virtual line CL4 extending in the Y direction at the center of the X direction of the pin connection portion 83A.

The wiring portion 83B is provided to cover the third contact region 63C of the third reverse pin junction portion 60C in the plan view. In one example, the wiring portion 83B covers the entirety of the third contact region 63C in the plan view. Therefore, the width dimension of the wiring portion 83B is larger than the width dimension of the third contact region 63C. On the other hand, the width dimension of the wiring portion 83B is smaller than the width dimension of the third low-concentration region 62C. The front end portion of the wiring portion 83B is curved in the plan view. In one example, the size and shape of the wiring portion 83B are the same as those of the wiring portion 81B.

A reverse pin connection portion 83C is provided at a position where the wiring portion 83B overlaps the third contact region 63C. The reverse pin connection portion 83C is connected to the third contact region 63C. The reverse pin connection portion 83C has an elliptical shape with its longitudinal direction in the Y direction and its lateral direction in the X direction in the plan view.

The wiring 90 is disposed within the outer peripheral region 110 in the plan view. The wiring 90 is provided to overlap the diode pair region 60 (high-concentration region 61) in the plan view as shown in FIG. 4. The outer peripheral edge of the wiring 90 includes a portion that is provided to overlap the outer peripheral edge of the diode pair region 60 (high-concentration region 61) in the plan view. In one example, the entire area of the wiring 90 is provided to overlap the separation region 65 in the plan view. Therefore, the wiring 90 is provided to avoid the first pin junction portion 30, the second pin junction portion 40, and the third pin junction portion 50 in the plan view. The wiring 90 is provided to partially surround each of the first connection electrode 81, the second connection electrode 82, and the third connection electrode 83 in the plan view.

The wiring 90 includes the first region 91, the second region 92, the third region 93, the first connection region 94, and the second connection region 95.

The first region 91 is provided to overlap the first region 66A of the diode pair region 60 (refer to FIG. 4) in the plan view. The portions of the outer peripheral edge of the first region 91 that correspond to the first to third sides 66AA to 66AC (refer to FIG. 4 together) of the first region 66A are provided to overlap the first to third sides 66AA to 66AC in the plan view.

The first region 91 includes a first recess 96A that is provided to avoid the first connection electrode 81 in the plan view. The first recess 96A opens toward the first pin junction portion 30. The wiring portion 81B of the first connection electrode 81 is disposed inside the first recess 96A. As a result, the first region 91 is provided to partially surround the first connection electrode 81 in the plan view. Furthermore, the first recess 96A is provided to avoid the first low-concentration region 62A of the first region 66A (refer to FIG. 4) in the plan view. Therefore, the first region 91 is provided to surround the first low-concentration region 62A in the plan view.

By providing the first recess 96A, it can be said that the first region 91 is partially connected to the separation region 65 (refer to FIG. 4) in the first region 66A. More specifically, as shown in FIG. 4, the separation region 65 in the first region 66A includes a wiring connection region 65P where the wiring 90 is connected, and a first separation region 65A that overlaps the first connection electrode 81 (refer to FIG. 7) in the plan view. The first separation region 65A is provided at the end closer to the first pin junction portion 30 among both ends of the first region 66A in the Y direction. The first separation region 65A is a region of the first region 66A between the first low-concentration region 62A and the fourth side 66AD in the plan view. The wiring connection region 65P is provided to partially surround the first low-concentration region 62A in the plan view. That is, the wiring connection region 65P is provided to partially surround the first reverse pin junction portion 60A in the plan view. Therefore, the first region 91 connected to the wiring connection region 65P (refer to FIG. 7) is provided to partially surround the first reverse pin junction portion 60A in the plan view.

The second region 92 (refer to FIG. 7) is provided to overlap the second region 66B of the diode pair region 60 in the plan view. The portions of the outer periphery edge of the second region 92 that correspond to the first side 66BA, the second side 66BB, and the fourth side 66BD of the second region 66B are provided to overlap the first side 66BA, the second side 66BB, and the fourth side 66BD in the plan view. As a result, the second region 92 includes a region positioned to be shifted in the Y direction relative to the first region 91.

As shown in FIG. 7, the second region 92 includes a second recess 96B that is provided to avoid the second connection electrode 82 in the plan view. The second recess 96B opens toward the second pin junction portion 40 (refer to FIG. 4). The wiring portion 82B of the second connection electrode 82 is disposed inside the second recess 96B. As a result, the second region 92 is provided to partially surround the second connection electrode 82 in the plan view. Additionally, the second recess 96B is provided to avoid the second low-concentration region 62B of the second region 66B (refer to FIG. 4) in the plan view. Therefore, the second region 92 is provided to surround the second low-concentration region 62B in the plan view.

By providing the second recess 96B, it can be said that the second region 92 is partially connected to the separation region 65 in the second region 66B. More specifically, as shown in FIG. 4, the separation region 65 in the second region 66B includes a wiring connection region 65P where the wiring 90 is connected, and a second separation region 65B that overlaps the second connection electrode 82 in the plan view. The second separation region 65B is provided at the end closer to the second pin junction portion 40 among both ends of the second region 66B in the Y direction. The second separation region 65B is a region of the second region 66B between the second low-concentration region 62B and the third side 66BC in the plan view. The wiring connection region 65P is provided to partially surround the second low-concentration region 62B in the plan view. That is, the wiring connection region 65P is provided to partially surround the second reverse pin junction portion 60B in the plan view. Therefore, the second region 92 connected to the wiring connection region 65P (refer to FIG. 7) is provided to partially surround the second reverse pin junction portion 60B in the plan view.

The third region 93 (refer to FIG. 7) is provided to overlap the third region 66C of the diode pair region 60 in the plan view. The portions of the outer periphery edge of the third region 93 that correspond to the first to third sides 66CA to 66CC are provided to overlap the first to third sides 66CA to 66CC in the plan view.

As shown in FIG. 7, the third region 93 includes a third recess 96C that is provided to avoid the third connection electrode 83 in the plan view. The third recess 96C opens toward the third pin junction portion 50. The wiring portion 83B of the third connection electrode 83 is disposed inside the third recess 96C. As a result, the third region 93 is provided to partially surround the third connection electrode 83 in the plan view. Additionally, the third recess 96C is provided to avoid the third low-concentration region 62C (refer to FIG. 4 together) of the third region 66C in the plan view. Therefore, the third region 93 is provided to surround the third low-concentration region 62C in the plan view.

By providing the third recess 96C, it can be said that the third region 93 is partially connected to the separation region 65 in the third region 66C. More specifically, as shown in FIG. 4, the separation region 65 in the third region 66C includes a wiring connection region 65P where the wiring 90 is connected, and a third separation region 65C that overlaps the third connection electrode 83 in the plan view. The third separation region 65C is provided at the end closer to the third pin junction portion 50 among both ends of the third region 66C in the Y direction. The third separation region 65C is a region of the third region 66C between the third low-concentration region 62C and the fourth side 66CD in the plan view. The wiring connection region 65P is provided to partially surround the third low-concentration region 62C in the plan view. That is, the wiring connection region 65P is provided to partially surround the third reverse pin junction portion 60C in the plan view. Therefore, the third region 93 connected to the wiring connection region 65P (refer to FIG. 7) is provided to partially surround the third reverse pin junction portion 60C in the plan view.

As shown in FIG. 7, the first connection region 94 is provided to overlap the first connection region 67A of the diode pair region 60 in the plan view (refer to FIG. 4 together). The shape and size of the first connection region 94 are the same as those of the first connection region 67A. The first connection region 94 is connected across the entire area of the first connection region 67A. That is, the first connection region 67A is formed of the wiring connection region 65P.

The second connection region 95 is provided to overlap the second connection region 67B of the diode pair region 60 in the plan view (refer to FIG. 4 together). The shape and size of the second connection region 95 are the same as those of the second connection region 67B. The second connection region 95 is connected across the entire area of the second connection region 67B. That is, the second connection region 67B is formed of the wiring connection region 65P.

The area of the wiring 90 in the plan view is larger than the area of the first connection electrode 81 in the plan view. The area of the wiring 90 in the plan view is larger than the area of the second connection electrode 82 in the plan view. The area of the wiring 90 in the plan view is larger than the area of the third connection electrode 83 in the plan view. On the other hand, the area of the wiring 90 in the plan view is smaller than the area of the high-concentration region 61 in the plan view. In one example, the wiring 90 is provided not to extend beyond the outer edge of the high-concentration region 61 in the plan view.

The area of the wiring 90 in the plan view is smaller than the area of the separation region 65 (refer to FIG. 4) in the plan view. In one example, the area of the wiring 90 in the plan view may be 75% or more and 97% or less of the area of the separation region 65 in the plan view. In one example, the area of the wiring 90 in the plan view may be 80% or more and 95% or less of the area of the separation region 65 in the plan view. In one example, the area of the wiring 90 in the plan view may be 85% or more and 95% or less of the area of the separation region 65 in the plan view. In one example, the area of the wiring 90 in the plan view may be 90% or more and 95% or less of the area of the separation region 65 in the plan view. In one example, the area of the wiring 90 in the plan view may be 85% or more and 90% or less of the area of the separation region 65 in the plan view.

### (Terminal Opening Portions)

As shown in FIG. 1, the first terminal opening portion 77A, the second terminal opening portion 77B, and the third terminal opening portion 77C are disposed spaced apart from each other. More specifically, the first terminal opening portion 77A and the third terminal opening portion 77C are disposed at the same position as each other in the Y direction and spaced apart from each other in the X direction. The first terminal opening portion 77A and the third terminal opening portion 77C are disposed closer to the fourth side surface 20D than the center of the first surface 20S of the semiconductor chip 20 in the Y direction. The first terminal opening portion 77A is disposed closer to the first side surface 20A than the center of the first surface 20S in the X direction. The third terminal opening portion 77C is disposed closer to the second side surface 20B than the center of the first surface 20S in the X direction.

The second terminal opening portion 77B is disposed at different positions in the X and Y directions relative to both the first terminal opening portion 77A and the third terminal opening portion 77C. The second terminal opening portion 77B is disposed closer to the third side surface 20C than the center of the first surface 20S of the semiconductor chip 20 in the Y direction. The second terminal opening portion 77B is disposed at the center of the first surface 20S in the X direction. Therefore, it can be said that the second terminal opening portion 77B is disposed between the first terminal opening portion 77A and the third terminal opening portion 77C in the X direction when viewed from the Y direction.

As shown in FIG. 1 and FIG. 4, the first terminal opening portion 77A is provided at a position overlapping the first pin junction portion 30 in the plan view. The second terminal opening portion 77B is provided at a position overlapping the second pin junction portion 40 in the plan view. The third terminal opening portion 77C is provided at a position overlapping the third pin junction portion 50 in the plan view.

The first terminal opening portion 77A exposes the pin connection portion 81A of the first connection electrode 81 in the plan view. The second terminal opening portion 77B exposes the pin connection portion 82A of the second connection electrode 82 in the plan view. The third terminal opening portion 77C exposes the pin connection portion 83A of the third connection electrode 83 in the plan view.

### [Circuit Configuration of TVS Diode]

Next, referring to FIG. 8, a TVS circuit 200 of the TVS diode 10 is described. FIG. 8 schematically shows the circuit configuration of the TVS diode 10.

As shown in FIG. 8, the TVS circuit 200 includes first to sixth diodes 201 to 206, a Zener diode 207, and first to third terminals TM1 to TM3. Herein, the first terminal TM1 may be formed of, for example, the portion of the first connection electrode 81 exposed from the first terminal opening portion 77A. The second terminal TM2 may be formed of, for example, the portion of the second connection electrode 82 exposed from the second terminal opening portion 77B. The third terminal TM3 may be formed of, for example, the portion of the third connection electrode 83 exposed from the third terminal opening portion 77C.

The first diode 201 forms a pin diode of the first pin junction portion 30. The second diode 202 forms a pin diode of the second pin junction portion 40. The third diode 203 forms a pin diode of the third pin junction portion 50. The fourth diode 204 forms a pin diode of the first reverse pin junction portion 60A. The fifth diode 205 forms a pin diode of the second reverse pin junction portion 60B. The sixth diode 206 forms a pin diode of the third reverse pin junction portion 60C.

The cathode of the first diode 201 is electrically connected to the anode of the fourth diode 204. The first terminal TM1 is electrically connected to a node N1 between the cathode of the first diode 201 and the anode of the fourth diode 204. The cathode of the second diode 202 is electrically connected to the anode of the fifth diode 205. The second terminal TM2 is electrically connected to a node N2 between the cathode of the second diode 202 and the anode of the fifth diode 205.

The cathode of the third diode 203 is electrically connected to the anode of the sixth diode 206. The third terminal TM3 is electrically connected to a node N3 between the cathode of the third diode 203 and the anode of the sixth diode 206.

The Zener diode 207 is connected in parallel with the series of the first diode 201 and the fourth diode 204, the series of the second diode 202 and the fifth diode 205, and the series of the third diode 203 and the sixth diode 206. The anode of the Zener diode 207 is electrically connected to the anode of the first diode 201, the anode of the second diode 202, and the anode of the third diode 203. The cathode of the Zener diode 207 is electrically connected to the cathode of the fourth diode 204, the cathode of the fifth diode 205, and the cathode of the sixth diode 206. As such, the Zener diode 207 forms a common reverse-connected diode with respect to the fourth diode 204, the fifth diode 205, and the sixth diode 206.

In one example, the first terminal TM1 and the third terminal TM3 form input terminals, and the second terminal TM2 forms a ground terminal. Therefore, when a voltage is applied to the first terminal TM1, the current flows from the first terminal TM1 through the second diode 202, the Zener diode 207, and the third diode 203 to the second terminal TM2. Additionally, when a voltage is applied to the third terminal TM3, the current flows from the third terminal TM3 through the fifth diode 205, the Zener diode 207, and the third diode 203 to the second terminal TM2. Furthermore, the first terminal TM1 and the second terminal TM2 may form the input terminals, and the third terminal TM3 may form the ground terminal. The second terminal TM2 and the third terminal TM3 may form the input terminals, and the first terminal TM1 may form the ground terminal.

### [Method for Manufacturing a TVS Diode]

Referring to FIG. 9 to FIG. 25, an example of the method for manufacturing the TVS diode 10 is described. FIG. 9 to FIG. 25 show cross-sectional structures during manufacturing processes of the TVS diode 10.

As shown in FIG. 9, the method for manufacturing the TVS diode 10 includes a process of preparing a semiconductor wafer 800. The semiconductor wafer 800 is, for example, a Si wafer. The semiconductor wafer 800 includes p-type impurities. As p-type impurities, for example, B (boron) may be used.

As shown in FIG. 10, the method for manufacturing the TVS diode 10 includes a process of forming a first epitaxial layer 810. In this process, Si is crystallized and grown from the upper surface of the semiconductor wafer 800 using an epitaxial growth method. The p-type impurity concentration diffuses into Si during the crystallization and growth of the semiconductor wafer 800. As a result, the p-type first epitaxial layer 810, which becomes the first semiconductor layer 23, is formed on the semiconductor wafer 800.

As shown in FIG. 11, the method for manufacturing the TVS diode 10 includes a process of selectively introducing p-type impurities (for example, B) into the surface layer portion of the first epitaxial layer 810. This process selectively introduces p-type impurities into regions of the surface layer portion of the first epitaxial layer 810 where the first-terminal-side high-concentration region 31, the second-terminal-side high-concentration region 41 (refer to FIG. 3), and the third-terminal-side high-concentration region 51 are to be formed. In this process, p-type impurities may be selectively implanted into the surface layer portion of the first epitaxial layer 810, for example, through an ion implantation method with an ion implantation mask (not shown). As a result, a portion of the first-terminal-side high-concentration region 31 (first region 31A), a portion of the second-terminal-side high-concentration region 41, and a portion of the third-terminal-side high-concentration region 51 are formed.

Next, as shown in FIG. 12, p-type impurities are introduced into the region of the surface layer portion of the first epitaxial layer 810 where the internal region 64 is to be formed. In this process, p-type impurities may be selectively implanted into the surface layer portion of the first epitaxial layer 810 through the above-mentioned ion implantation method. As a result, a portion of the internal region 64 is formed.

Furthermore, the figures related to the method for manufacturing the TVS diode 10 of the first embodiment, including FIG. 11 and FIG. 12, show a portion of the first-terminal-side high-concentration region 31 (first region 31A), a portion of the third-terminal-side high-concentration region 51, and a portion of the internal region 64, but do not show a portion of the second-terminal-side high-concentration region 41. Additionally, the process shown in FIG. 12 may also be performed before the process shown in FIG. 11.

As shown in FIG. 13, the method for manufacturing the TVS diode 10 includes a process of forming a second epitaxial layer 820. In this process, Si is crystallized and grown from the first epitaxial layer 810 by an epitaxial growth method. As a result, the n-type second epitaxial layer 820, which becomes the second semiconductor layer 24, is formed on the first epitaxial layer 810. Furthermore, the second epitaxial layer 820 may also be p-type.

Next, the method for manufacturing the TVS diode 10 includes a process of selectively introducing p-type impurities into the second epitaxial layer 820. In this process, p-type impurities are selectively implanted into regions of the second epitaxial layer 820 where the first-terminal-side high-concentration region 31, the second-terminal-side high-concentration region 41, the third-terminal-side high-concentration region 51, and the internal region 64 are to be formed, for example, through an ion implantation method with an ion implantation mask (not shown). Similar to the process shown in FIG. 11, this process may also be divided into a process of selectively implanting p-type impurities into the region where the first-terminal-side high-concentration region 31, the second-terminal-side high-concentration region 41, and the third-terminal-side high-concentration region 51 are to be formed, and a process of selectively implanting p-type impurities into the region where the internal region 64 is to be formed.

Next, the method for manufacturing the TVS diode 10 includes a process of introducing n-type impurities into the region of the surface layer portion of the second epitaxial layer 820 where the diode pair region 60 is to be formed. As n-type impurities, at least one of As (arsenic) and P (phosphorus) may be used. The n-type impurities may be implanted into the surface layer portion of the second epitaxial layer 820 through an ion implantation method with an ion implantation mask (not shown). As a result, a portion of the high-concentration region 61 is formed in the surface layer portion of the second epitaxial layer 820. The high-concentration region 61 is formed to cover the entire area of the internal region 64 in the plan view. The high-concentration region 61 is formed to be in contact with the internal region 64. That is, the pn junction portion 60E is formed.

Next, the method for manufacturing the TVS diode 10 includes a process of diffusing the p-type impurities introduced in the surface layer portion of the first epitaxial layer 810, as well as the p-type impurities and n-type impurities introduced in the second epitaxial layer 820. In this process, the p-type and n-type impurities are diffused by a drive-in treatment method, for example. As a result, the p-type impurities introduced in the surface layer portion of the first epitaxial layer 810 diffuse into the second epitaxial layer 820.

As shown in FIG. 14, the method for manufacturing the TVS diode 10 includes a process of forming the third epitaxial layer 830. In this process, silicon (Si) is crystallized and grown from the second epitaxial layer 820 through an epitaxial growth method involving the introduction of n-type impurities. During this process, p-type and n-type impurities diffuse into Si that is in the process of crystallization and growth from the second epitaxial layer 820. As a result, the third epitaxial layer 830 is formed on the second epitaxial layer 820. Additionally, a portion of the first-terminal-side high-concentration region 31, a portion of the second-terminal-side high-concentration region 41, a portion of the third-terminal-side high-concentration region 51, and a portion of the high-concentration region 61 are formed at a boundary portion between the second epitaxial layer 820 and the third epitaxial layer 830.

Through the above processes, a semiconductor wafer structure 840, which includes the semiconductor wafer 800, the first epitaxial layer 810, the second epitaxial layer 820, and the third epitaxial layer 830, is formed. The semiconductor wafer structure 840 includes a first wafer surface 841 and a second wafer surface 842 on the opposite side of the first wafer surface 841. The first wafer surface 841 corresponds to the first surface 20S of the semiconductor chip 20, and the second wafer surface 842 corresponds to the second surface 20R of the semiconductor chip 20. The first wafer surface 841 is formed of the third epitaxial layer 830. The second wafer surface 842 is formed of the semiconductor wafer 800.

As shown in FIG. 15, the method for manufacturing the TVS diode 10 includes a process of forming a partition region and an outer peripheral region 110. In this process, p-type impurities are selectively implanted into the surface layer portion of the third epitaxial layer 830, for example, through an ion implantation method with an ion implantation mask 910. The ion implantation mask 910 comprises an opening portion 911 that exposes a region of the third epitaxial layer 830 where the first partition region 34, the second partition region 44 (refer to FIG. 3), the third partition region 54, and the outer peripheral region 110 are to be formed. The p-type impurities are implanted into the surface layer portion of the third epitaxial layer 830 through the opening portion 911. As a result, the p-type first partition region 34, the second partition region 44, the third partition region 54, and the outer peripheral region 110 are formed. By forming the first partition region 34 and the outer peripheral region 110, a first-terminal-side low-concentration region 32, surrounded by the first partition region 34 in the plan view, is formed. By forming the second partition region 44 and the outer peripheral region 110, a second-terminal-side low-concentration region 42, surrounded by the second partition region 44 in the plan view, is formed. By forming the third partition region 54 and the outer peripheral region 110, a third-terminal-side low-concentration region 52, surrounded by the third partition region 54 in the plan view, is formed. Furthermore, FIG. 15 shows the first partition region 34, the third partition region 54, and the outer peripheral region 110, but does not show the second partition region 44.

As shown in FIG. 16, the method for manufacturing the TVS diode 10 includes a process of forming a separation region 65. In this process, n-type impurities are selectively implanted into the surface layer portion of the third epitaxial layer 830, for example, through an ion implantation method with an ion implantation mask 920. The ion implantation mask 920 comprises an opening portion 921 that exposes a region in the surface layer portion of the third epitaxial layer 830 where the separation region 65 is to be formed. The n-type impurities are implanted into the surface layer portion of the third epitaxial layer 830 through the opening portion 921. As a result, the n-type separation region 65 is formed. By forming the separation region 65, the first low-concentration region 62A, the second low-concentration region 62B, and the third low-concentration region 62C, which are surrounded by the separation region 65 in the plan view, are formed.

As shown in FIG. 17, the method for manufacturing the TVS diode 10 includes a process of forming a terminal-side contact region. In this process, n-type impurities are selectively implanted into the surface layer portion of the third epitaxial layer 830 through an ion implantation method with an ion implantation mask 930, for example. The ion implantation mask 930 comprises an opening portion 931 that exposes a region in the surface layer portion of the third epitaxial layer 830 where the first-terminal-side contact region 33, the second-terminal-side contact region 43, and the third-terminal-side contact region 53 are to be formed. The opening portion 931 partially exposes each of the surface layer portions of the first-terminal-side low-concentration region 32, the second-terminal-side low-concentration region 42 (refer to FIG. 3), and the third-terminal-side low-concentration region 52 in the surface layer portion of the third epitaxial layer 830. The n-type impurities are implanted into each of the surface layer portions of the first-terminal-side low-concentration region 32, the second-terminal-side low-concentration region 42, and the third-terminal-side low-concentration region 52 through the opening portion 931. As a result, the n-type first-terminal-side contact region 33 is formed in the surface layer portion of the first-terminal-side low-concentration region 32. The n-type second-terminal-side contact region 43 (refer to FIG. 3) is formed in the surface layer portion of the second-terminal-side low-concentration region 42. The n-type third-terminal-side contact region 53 is formed in the surface layer portion of the third-terminal-side low-concentration region 52. Through the above processes, the first pin junction portion 30, the second pin junction portion 40, and the third pin junction portion 50 are formed. Furthermore, FIG. 17 shows the first-terminal-side contact region 33 and the third-terminal-side contact region 53, but does not show the second-terminal-side contact region 43.

As shown in FIG. 18, the method for manufacturing the TVS diode 10 includes a process of forming a contact region. In this process, p-type impurities are selectively implanted into the surface layer portion of the third epitaxial layer 830, for example, through an ion implantation method with an ion implantation mask 940. The ion implantation mask 940 comprises an opening portion 941 that exposes the regions in the surface layer portion of the third epitaxial layer 830 where the first contact region 63A, the second contact region 63B, and the third contact region 63C are to be formed. The opening portion 941 partially exposes each of the surface layer portions of the first low-concentration region 62A, the second low-concentration region 62B, and the third low-concentration region 62C in the surface layer portion of the third epitaxial layer 830. The p-type impurities are implanted into each of the surface layer portions of the first low-concentration region 62A, the second low-concentration region 62B, and the third low-concentration region 62C through the opening portion 941. As a result, the p-type first contact region 63A is formed in the surface layer portion of the first low-concentration region 62A. The p-type second contact region 63B is formed in the surface layer portion of the second low-concentration region 62B. The p-type third contact region 63C is formed in the surface layer portion of the third low-concentration region 62C. Through the above processes, the first reverse pin junction portion 60A, the second reverse pin junction portion 60B, and the third reverse pin junction portion 60C are formed.

As shown in FIG. 19 to FIG. 21, the method for manufacturing the TVS diode 10 includes a process of forming an insulating layer 850.

As shown in FIG. 19, the process of forming the insulating layer 850 includes a process of forming a first insulating layer 851. The first insulating layer 851 is formed on the first wafer surface 841 of the semiconductor wafer structure 840. The first insulating layer 851 is the insulating layer that forms the first insulating layer 71 of the insulating layer 70. The first insulating layer 851 may be formed by a CVD (Chemical Vapor Deposition) method or an oxidation treatment method (for example, a thermal oxidation treatment).

Next, as shown in FIG. 20, the process of forming the insulating layer 850 includes a process of forming a second insulating layer 852. The second insulating layer 852 is formed on the first insulating layer 851. The second insulating layer 852 is the insulating layer that forms the second insulating layer 72 of the insulating layer 70. The second insulating layer 852 may be formed by at least one of the CVD method and the oxidation treatment method.

Next, as shown in FIG. 21, the process of forming the insulating layer 850 includes a process of forming first to sixth opening portions 73A to 73F and a wiring opening portion 73G that partially expose the first wafer surface 841. In this process, a resist mask 950 comprising a predetermined pattern is first formed on the second insulating layer 852. The resist mask 950 exposes the regions where the first to sixth opening portions 73A to 73F and the wiring opening portion 73G of the insulating layer 70 are to be formed, while covering the other regions. Next, an etching method with the resist mask 950 is employed to remove the portions exposed from the resist mask 950. As a result, the first to sixth opening portions 73A to 73F and the wiring opening portion 73G are formed.

As shown in FIG. 22, the method for manufacturing the TVS diode 10 includes a process of forming connection electrodes and a process of forming the wiring 90. In one example, the process of forming the connection electrodes and the process of forming the wiring 90 are performed as a common process.

First, a metal layer is formed on the insulating layer 850. The metal layer covers the insulating layer 850 and fills the first to sixth opening portions 73A to 73F. Therefore, the metal layer is in contact with the first-terminal-side contact region 33, the second-terminal-side contact region 43, the third-terminal-side contact region 53, the first to third contact regions 63A to 63C, and the separation region 65. The metal layer forms the layers of the first to third connection electrodes 81 to 83 and the wiring 90.

Next, unnecessary portions of the metal layer are removed through an etching method using a resist mask (not shown) comprising a predetermined pattern. The resist mask covers the regions where the first to third connection electrodes 81 to 83 and the wiring 90 of the metal layer are to be formed, while exposing the other regions. Then, the portions of the metal layer that are exposed from the resist mask are removed. As a result, the first to third connection electrodes 81 to 83 and the wiring 90 are formed. Furthermore, in FIG. 22, the first connection electrode 81, the third connection electrode 83, and the wiring 90 are shown, while the second connection electrode 82 is not shown.

As shown in FIG. 23 to FIG. 25, the method for manufacturing the TVS diode 10 includes a process of forming a protective layer 860.

As shown in FIG. 23, the process of forming the protective layer 860 includes a process of forming a first protective layer 861. The first protective layer 861 is an insulating layer that forms the first protective layer 75 of the protective layer 74. The first protective layer 861 may be formed by a CVD method.

As shown in FIG. 24, the process of forming the protective layer 860 includes a process of forming a second protective layer 862. The second protective layer 862 is a resin layer that forms the second protective layer 76 of the protective layer 74. In one example, the second protective layer 862 is formed by applying a photosensitive resin (for example, PI) onto the first protective layer 861.

As shown in FIG. 25, the process of forming the protective layer 860 includes a process of forming first to third terminal opening portions 77A to 77C. The first to third terminal opening portions 77A to 77C are formed by exposing and developing the first protective layer 861 and the second protective layer 862. More specifically, a photoresist is formed on the second protective layer 862. Subsequently, opening portions that expose the regions of the second protective layer 862 where the first to third terminal opening portions 77A to 77C are to be formed are formed in the photoresist. Then, the second protective layer 862 and the first protective layer 861 exposed from the opening portions of the photoresist are removed by developing. As a result, the first to third terminal opening portions 77A to 77C are formed. Furthermore, FIG. 25 shows the first terminal opening portion 77A and the third terminal opening portion 77C, while the second terminal opening portion 77B (refer to FIG. 3) is not shown.

Although not shown, the method for manufacturing the TVS diode 10 includes a process of singulation. In this process, the semiconductor wafer structure 840, the insulating layer 850, and the protective layer 860 are cut using a dicing blade, for example. As a result, the semiconductor chip 20, the insulating layer 70, and the protective layer 74 (refer to FIG. 2) are formed. Through the above processes, the TVS diode 10 is manufactured.

### Function

Referring to FIG. 26 and FIG. 27, the function of the TVS diode 10 of the first embodiment is illustrated. FIG. 26 schematically shows a cross-sectional structure that enlarges the diode pair region 60 of the TVS diode 10 and its periphery. FIG. 27 schematically shows the cross-sectional structures of the second pin junction portion 40, the second reverse pin junction portion 60B, the third reverse pin junction portion 60C, and the third pin junction portion 50.

As shown in FIG. 26, the diode pair region 60 includes the first to third reverse pin junction portions 60A to 60C. The high-concentration region 61 forms a common Player in the first to third reverse pin junction portions 60A to 60C. Moreover, the internal region 64 is provided to overlap the first low-concentration region 62A, the second low-concentration region 62B, and the third low-concentration region 62C in the plan view. That is, the pn junction portion 60E formed of the high-concentration region 61 and the internal region 64 is provided to serve as a common pn junction portion for the pn junction portion connected in the reverse direction to the first reverse pin junction portion 60A, the pn junction portion connected in the reverse direction to the second reverse pin junction portion 60B, and the pn junction portion connected in the reverse direction to the third reverse pin junction portion 60C. Therefore, compared to a configuration where individual pn junction portions are provided for the pn junction portion connected in the reverse direction to the first reverse pin junction portion 60A, the pn junction portion connected in the reverse direction to the second reverse pin junction portion 60B, and the pn junction portion connected in the reverse direction to the third reverse pin junction portion 60C, the junction area between the high-concentration region 61 and the internal region 64 can be increased for the same chip size. Additionally, when the junction area between the high-concentration region 61 and the internal region 64 is maintained, miniaturization of the TVS diode 10 can be achieved.

Furthermore, as indicated by the thick arrow in FIG. 26, in the first reverse pin junction portion 60A, current flows in the order of the first contact region 63A, the first low-concentration region 62A, and the separation region 65. The current flowing through the separation region 65 flows into the wiring 90 that is in contact with the separation region 65. The wiring 90 is provided to surround the first to third reverse pin junction portions 60A to 60C in the plan view and to cover the outer edge of the high-concentration region 61. As a result, the current flowing through the wiring 90 can easily flow throughout the entire internal region 64 through the separation region 65. Furthermore, current similarly flows through the second reverse pin junction portion 60B and the third reverse pin junction portion 60C. Therefore, when current flows through the second reverse pin junction portion 60B and when current flows through the third reverse pin junction portion 60C, it becomes easier for current to flow throughout the entire internal region 64.

As shown in FIG. 27, by disposing a portion of the diode pair region 60 between the second pin junction portion 40 and the third pin junction portion 50, the amplification factor of the parasitic NPN transistor provided between the second pin junction portion 40 and the third pin junction portion 50 can be reduced. Consequently, the current flowing directly from the second pin junction portion 40 to the third pin junction portion 50 due to the parasitic NPN transistor being turned on is suppressed. Therefore, for example, when electrostatic discharge (ESD) is applied to the second terminal 102, the current flowing through the second terminal 102 flows into the first semiconductor layer 23 through the second connection electrode 82, the second reverse pin junction portion 60B, and the pn junction portion 60E. Then, it flows from the first semiconductor layer 23 through the third pin junction portion 50 and the third connection electrode 83 to the third terminal 103. Thus, when the second pin junction portion 40 and the third pin junction portion 50 are disposed with the diode pair region 60 in between, the current flows through the diode pair region 60 and the first semiconductor layer 23.

### Effect

According to the TVS diode 10 of the first embodiment, the following effects can be obtained.

(1-1) The TVS diode 10 includes a semiconductor chip 20 that comprises a first surface 20S and a second surface 20R opposite to the first surface. The semiconductor chip 20 includes a first pin junction portion 30 provided close to the first surface 20S, a second pin junction portion 40 of a first polarity direction disposed at a position spaced apart from the first pin junction portion 30 in a plan view when viewed from a thickness direction of the semiconductor chip 20 in a region close to the first surface 20S of the semiconductor chip 20, and a diode pair region 60 provided spaced apart from both the first pin junction portion 30 and the second pin junction portion 40 in the plan view. The diode pair region 60 includes an n-type high-concentration region 61 provided spaced apart from the first surface 20S toward the second surface 20R of the semiconductor chip 20, a first low-concentration region 62A and a second low-concentration region 62B of n-type that are provided spaced apart from each other at a position overlapping the high-concentration region 61 in the plan view in a region closer to the first surface 20S than the high-concentration region 61, a separation region 65 provided at a position overlapping the high-concentration region 61 in the plan view in a region closer to the first surface 20S than the high-concentration region 61 and separating the first low-concentration region 62A from the second low-concentration region 62B, a first contact region 63A of p-type provided in the surface layer portion of the first low-concentration region 62A, a second contact region 63B of p-type provided in the surface layer portion of the second low-concentration region 62B, and an internal region 64 of p-type in contact with the high-concentration region 61 and closer to the second surface 20R than the high-concentration region 61 at a position overlapping the high-concentration region 61 in the plan view. A first reverse pin junction portion 60A of the second polarity direction is formed of the high-concentration region 61, the first low-concentration region 62A, and the first contact region 63A. A second reverse pin junction portion 60B of the second polarity direction is formed of the high-concentration region 61, the second low-concentration region 62B, and the second contact region 63B. A pn junction portion 60E of the first polarity direction, which is connected in the reverse direction to the first reverse pin junction portion 60A and the second reverse pin junction portion 60B, is formed of the high-concentration region 61 and the internal region 64. The internal region 64 is provided to overlap both the first low-concentration region 62A and the second low-concentration region 62B in the plan view.

According to this configuration, the high-concentration region 61 forms a common P layer for the first reverse pin junction portion 60A and the second reverse pin junction portion 60B. The pn junction portion 60E formed of the high-concentration region 61 and the internal region 64 serves as both of a pn junction portion connected in the reverse direction to the first reverse pin junction portion 60A and a pn junction portion connected in the reverse direction to the second reverse pin junction portion 60B. Therefore, compared to a configuration where separate pn junction portions are provided for connecting in the reverse direction to the first reverse pin junction portion 60A and connecting in the reverse direction to the second reverse pin junction portion 60B, the junction area between the high-concentration region 61 and the internal region 64 can be increased with the same chip size. As a result, the improvement in surge absorption capability due to the junction area can be achieved. Consequently, the improvement in the electrical characteristics of the TVS diode 10 can be achieved.

(1-2) The separation region 65 includes an exposed surface 65S exposed from the first surface 20S of the semiconductor chip 20. The TVS diode 10 includes a wiring 90 in contact with the exposed surface 65S.

According to this configuration, the current flowing through the first pin junction portion 30 and the second pin junction portion 40 flows to the wiring 90 through the separation region 65. The current flowing to the wiring 90 flows throughout the entire internal region 64 through the separation region 65. As such, in comparison with a configuration in which the current flows throughout the entire internal region 64 by passing through the high-concentration region 61 instead of through the wiring 90, the current flows throughout the entire internal region 64 with low resistance. As a result, the improvement in surge absorption capability while reducing clamp voltage can be achieved.

(1-3) The separation region 65 includes a first separation region 65A overlapping the first connection electrode 81 in the plan view, a second separation region 65B overlapping the second connection electrode 82 in the plan view, and a wiring connection region 65P where the wiring 90 is connected. The wiring connection region 65P is provided to partially surround both the first reverse pin junction portion 60A and the second reverse pin junction portion 60B individually in the plan view.

According to this configuration, it becomes easier for current to flow from each of the first reverse pin junction portion 60A and the second reverse pin junction portion 60B to the wiring 90 through the wiring connection region 65P. As a result, current can flow throughout the entire internal region 64 with low resistance, thereby achieving the improvement in surge absorption capability and reduction of clamp voltage.

(1-4) The wiring 90 is provided to partially surround both the first connection electrode 81 and the second connection electrode 82 individually in the plan view.

According to this configuration, the wiring 90 can insulate the first connection electrode 81 and the second connection electrode 82 while increasing the area in contact with the separation region 65. Therefore, the current flows from the high-concentration region 61 to the internal region 64 throughout the entire wiring 90, so that the current easily flows throughout the entire internal region 64 with low resistance.

(1-5) An area of the wiring 90 in the plan view is larger than an area of the first connection electrode 81 in the plan view.

According to this configuration, the area of the wiring 90 in contact with the separation region 65 can be increased. Therefore, the current flows from the high-concentration region 61 to the internal region 64 throughout the entire wiring 90, so that the current easily flows throughout the entire internal region 64 with low resistance.

(1-6) The area of the wiring 90 in the plan view is smaller than the area of the separation region 65 in the plan view.

According to this configuration, the area of the wiring 90 that extends beyond the separation region 65 in the plan view can be reduced or become zero. Therefore, the current path from the wiring 90 to the separation region 65 becomes shorter, allowing current to flow throughout the entire internal region 64 with low resistance.

(1-7) The area of the wiring 90 in the plan view is 75% or more and 97% or less of the area of the separation region 65 in the plan view.

According to this configuration, the area of the wiring 90 in contact with the separation region 65 can be increased. As a result, compared to the case where the area of the wiring 90 in the plan view is less than 75% of the area of the separation region 65, the current flowing through the first pin junction portion 30 and the second pin junction portion 40 is more likely to flow from the separation region 65 to the entire area of the wiring 90. Therefore, the current flows from the high-concentration region 61 to the internal region 64 through the entire wiring 90, so that the current easily flows throughout the entire internal region 64 with low resistance.

(1-8) The outer edge of the internal region 64 is located inward compared to the outer edge of the high-concentration region 61 in the plan view.

According to this configuration, compared to a configuration where the outer edge of the internal region 64 is at the same position as the outer edge of the high-concentration region 61 in the plan view, electric field concentration at the outer edge of the internal region 64 can be suppressed. Therefore, improvement in ESD tolerance can be achieved.

(1-9) In the plan view, the outer edge of the internal region 64 includes a plurality of corner portions. Each of the plurality of corner portions is curved in the plan view.

According to this configuration, electric field concentration at each corner portion of the internal region 64 can be suppressed. Therefore, improvement in ESD tolerance can be achieved.

(1-10) The TVS diode 10 includes a semiconductor chip 20 comprising a first surface 20S and a second surface 20R opposite to the first surface. The semiconductor chip 20 includes a first pin junction portion 30 and a second pin junction portion 40 of a first polarity direction provided in a region close to the first surface 20S of the semiconductor chip 20, and a diode pair region 60 that includes a first reverse pin junction portion 60A and a second reverse pin junction portion 60B of a second polarity direction provided in a region close to the first surface 20S of the semiconductor chip 20, and a pn junction portion 60E of the first polarity direction provided at a position overlapping the first reverse pin junction portion 60A and the second reverse pin junction portion 60B in the plan view when viewed from a thickness direction of the semiconductor chip 20 and forming a diode pair with the first reverse pin junction portion 60A and the second reverse pin junction portion 60B, and is provided spaced apart from both the first pin junction portion 30 and the second pin junction portion 40 in the plan view. The diode pair region 60 is disposed between the first pin junction portion 30 and the second pin junction portion 40 in the plan view.

According to this configuration, the diode pair region 60 is disposed between the first pin junction portion 30 and the second pin junction portion 40, which allows for the reduction of the amplification factor of the parasitic NPN transistor provided between the first pin junction portion 30 and the second pin junction portion 40. As a result, the current flowing directly from the first pin junction portion 30 to the second pin junction portion 40 and the current flowing directly from the second pin junction portion 40 to the first pin junction portion 30 due to the parasitic NPN transistor being turned on can be suppressed. Therefore, the improvement in ESD tolerance can be achieved.

(1-11) The diode pair region 60 includes a first region 66A where a first reverse pin junction portion 60A is provided, and a second region 66B where a second reverse pin junction portion 60B is provided. The second region 66B includes a region that is positioned to be shifted in the Y direction relative to the first region 66A. The first region 66A and the second pin junction portion 40 are adjacent in the X direction in the plan view. The second region 66B and the first pin junction portion 30 are adjacent in the X direction in the plan view.

According to this configuration, the distance between the first pin junction portion 30 and the second pin junction portion 40 can be increased, and the area of the diode pair region 60 can be enlarged. Thus, improvements in surge absorption capability can be achieved and improvements in ESD tolerance can be achieved.

(1-12) The first connection electrode 81 and the second connection electrode 82 are arranged apart from each other in the X direction in the plan view. Each of the first connection electrode 81 and the second connection electrode 82 extends in the Y direction in the plan view.

According to this configuration, the shapes of the first connection electrode 81 and the second connection electrode 82 in the plan view can be simplified. Additionally, a reduction in the area of the region where the first connection electrode 81 and the second connection electrode 82 overlap the separation region 65 can be achieved. This allows for an increase in the area of the wiring 90 that is in contact with the separation region 65.

(1-13) The semiconductor chip 20 includes a third pin junction portion 50 of the first polarity direction provided close to the first surface 20S of the semiconductor chip 20, and a third reverse pin junction portion 60C of the second polarity direction provided close to the first surface 20S of the semiconductor chip 20 and forming a diode pair with the pn junction portion 60E. In the plan view, the third pin junction portion 50 and the third reverse pin junction portion 60C are located side by side in the Y direction and are electrically connected to each other. The third pin junction portion 50 and the third reverse pin junction portion 60C are disposed to be adjacent to each other on the opposite side of the second pin junction portion 40 and the second reverse pin junction portion 60B relative to the first pin junction portion 30 and the first reverse pin junction portion 60A in the X direction in the plan view. The third pin junction portion 50 is adjacent to the second reverse pin junction portion 60B in the X direction in the plan view. The third reverse pin junction portion 60C is adjacent to the second pin junction portion 40 in the X direction in the plan view. The diode pair region 60 includes a region disposed between the second pin junction portion 40 and the third pin junction portion 50 in a direction that intersects both the X direction and the Y direction in the plan view.

According to this configuration, the diode pair region 60 is disposed between the second pin junction portion 40 and the third pin junction portion 50, which allows for the reduction of the amplification factor of the parasitic NPN transistor formed between the second pin junction portion 40 and the third pin junction portion 50. As a result, the current flowing directly from the second pin junction portion 40 to the third pin junction portion 50 and the current flowing directly from the third pin junction portion 50 to the second pin junction portion 40 due to the parasitic NPN transistor being turned on can be suppressed. Therefore, the improvement in the ESD tolerance can be achieved.

(1-14) The high-concentration region 61 includes a first region 66A where the first reverse pin junction portion 60A is provided, a second region 66B where the second reverse pin junction portion 60B is provided, and a third region 66C where the third reverse pin junction portion 60C is provided. The second region 66B includes a region positioned to be shifted in the Y direction relative to both the first region 66A and the third region 66C. The second region 66B includes a portion disposed between the first pin junction portion 30 and the third pin junction portion 50 in the X direction. The first region 66A and the third region 66C include a portion adjacent to the second pin junction portion 40 in the X direction.

According to this configuration, both the distance between the first pin junction portion 30 and the second pin junction portion 40 and the distance between the second pin junction portion 40 and the third pin junction portion 50 can be increased, and the area of the diode pair region 60 can be increased. Thus, the improvement in surge absorption capability can be achieved and the improvement in ESD tolerance can be achieved.

(1-15) The first connection electrode 81, the second connection electrode 82, and the third connection electrode 83 are disposed spaced apart from each other in the X direction in the plan view. Each of the first connection electrode 81, the second connection electrode 82, and the third connection electrode 83 extends in the Y direction in the plan view.

According to this configuration, the shape of each of the first connection electrode 81, the second connection electrode 82, and the third connection electrode 83 in the plan view can be simplified. Additionally, the area of the regions where the first connection electrode 81, the second connection electrode 82, and the third connection electrode 83 overlap the separation region 65 can be reduced. This allows for an increase in the area of the wiring 90 that is in contact with the separation region 65.

### Second Embodiment

Referring to FIG. 28 to FIG. 33, the TVS diode 10 of the second embodiment is described. The TVS diode 10 of the second embodiment differs from the TVS diode 10 of the first embodiment mainly in the configurations of the first pin junction portion 30, the second pin junction portion 40, and the third pin junction portion 50. In the following, the common components with the first embodiment are denoted by the same reference numerals, and their descriptions are omitted.

FIG. 28 and FIG. 29 schematically show the cross-sectional structure of the TVS diode 10 of the second embodiment. FIG. 28 mainly shows the first pin junction portion 30, the third pin junction portion 50, and the diode pair region 60. FIG. 29 mainly shows the first pin junction portion 30, the second pin junction portion 40, and the diode pair region 60. FIG. 30 schematically shows an enlarged structure of the first pin junction portion 30 and its periphery in FIG. 28. FIG. 31 is a graph showing the relationship between the position of the first pin junction portion 30 in the Z-direction and the impurity concentration. FIG. 32 and FIG. 33 schematically show an example of the cross-sectional structure of the manufacturing process of the TVS diode 10 of the second embodiment.

As shown in FIG. 28, the first pin junction portion 30 includes a p-type first buffer region 35. The first buffer region 35 is provided between the first-terminal-side high-concentration region 31 and the first-terminal-side low-concentration region 32 in the Z direction. The first buffer region 35 is in contact with the first-terminal-side high-concentration region 31. The first buffer region 35 is in contact with the first-terminal-side low-concentration region 32. The first partition region 34 is provided to surround the first buffer region 35 in the plan view. In the second embodiment, the first pin junction portion 30 is formed of the first-terminal-side contact region 33, the first-terminal-side low-concentration region 32, and the first buffer region 35. That is, the first-terminal-side contact region 33 forms the N layer, the first-terminal-side low-concentration region 32 forms the I layer, and the first buffer region 35 forms the Player.

As shown in FIG. 29, the second pin junction portion 40 includes a p-type second buffer region 45. The second buffer region 45 is provided between the second-terminal-side high-concentration region 41 and the second-terminal-side low-concentration region 42 in the Z direction. The second buffer region 45 is in contact with the second-terminal-side high-concentration region 41. The second buffer region 45 is in contact with the second-terminal-side low-concentration region 42. The second partition region 44 is provided to surround the second buffer region 45 in the plan view. In the second embodiment, the second pin junction portion 40 is formed of the second-terminal-side contact region 43, the second-terminal-side low-concentration region 42, and the second buffer region 45. That is, the second-terminal-side contact region 43 forms the N layer, the second-terminal-side low-concentration region 42 forms the I layer, and the second buffer region 45 forms the Player.

As shown in FIG. 28, the third pin junction portion 50 includes a p-type third buffer region 55. The third buffer region 55 is provided between the third-terminal-side high-concentration region 51 and the third-terminal-side low-concentration region 52 in the Z direction. The third buffer region 55 is in contact with the third-terminal-side high-concentration region 51. The third buffer region 55 is in contact with the third-terminal-side low-concentration region 52. The third partition region 54 is provided to surround the third buffer region 55 in the plan view. In the second embodiment, the third pin junction portion 50 is formed of the third-terminal-side contact region 53, the third-terminal-side low-concentration region 52, and the third buffer region 55. That is, the third-terminal-side contact region 53 forms the N layer, the third-terminal-side low-concentration region 52 forms the I layer, and the third buffer region 55 forms the Player.

Furthermore, the first pin junction portion 30, the second pin junction portion 40, and the third pin junction portion 50 have the same configuration with each other. Therefore, in the following, the first pin junction portion 30 is described in detail, and a detailed description of the second pin junction portion 40 and the third pin junction portion 50 is omitted.

As shown in FIG. 30, the first buffer region 35 is provided at a boundary portion between the second semiconductor layer 24 and the third semiconductor layer 25. That is, the boundary between the first buffer region 35 and the first-terminal-side high-concentration region 31 is positioned in the second semiconductor layer 24 in the Z direction. Therefore, the thickness of the first-terminal-side high-concentration region 31 is thinner than the thickness of the first-terminal-side high-concentration region 31 of the first embodiment (refer to FIG. 2).

The boundary between the first buffer region 35 and the first-terminal-side low-concentration region 32 is positioned closer to the first surface 20S of the semiconductor chip 20 than the boundary between the high-concentration region 61 of the diode pair region 60 and the first low-concentration region 62A. As a result, the thickness of the first-terminal-side low-concentration region 32 is thinner than the thickness of the first-terminal-side low-concentration region 32 of the first embodiment (refer to FIG. 2). In one example, the thickness of the first-terminal-side low-concentration region 32 is thinner than the thickness of the first low-concentration region 62A. The thickness of the first-terminal-side low-concentration region 32 is thinner than the thickness of the first buffer region 35.

As shown in FIG. 31, the p-type impurity concentration in the first buffer region 35 may be 1×10¹⁴ cm⁻³ or more and 5×10¹⁷ cm⁻³ or less. The p-type impurity concentration in the first buffer region 35 has a concentration gradient that decreases from the first-terminal-side high-concentration region 31 to the first-terminal-side low-concentration region 32 in the Z direction. Therefore, the p-type impurity concentration in the first buffer region 35 reaches its maximum value at the boundary between the first buffer region 35 and the first-terminal-side high-concentration region 31 and its minimum value at the boundary between the first buffer region 35 and the first-terminal-side low-concentration region 32. Consequently, the first buffer region 35 has a p-type impurity concentration that is lower than the p-type impurity concentration in the first-terminal-side high-concentration region 31. Additionally, the p-type impurity concentration in the first buffer region 35 may be equal to the n-type impurity concentration in the first-terminal-side low-concentration region 32 at the boundary between the first buffer region 35 and the first-terminal-side low-concentration region 32. In one example, the p-type impurity concentration at the boundary between the first buffer region 35 and the first-terminal-side low-concentration region 32 may be 1×10¹⁴ cm⁻³. As shown in FIG. 31, the p-type impurity concentration in the first buffer region 35 is greater than or equal to the n-type impurity concentration in the first-terminal-side low-concentration region 32.

Furthermore, the p-type impurity concentration in the second buffer region 45 and the p-type impurity concentration in the third buffer region 55 have the same concentration gradient as the p-type impurity concentration in the first buffer region 35. Therefore, the second buffer region 45 has a p-type impurity concentration that is lower than the p-type impurity concentration in the second-terminal-side high-concentration region 41. The p-type impurity concentration in the second buffer region 45 has a concentration gradient that decreases from the second-terminal-side high-concentration region 41 to the second-terminal-side low-concentration region 42 in the Z direction. The p-type impurity concentration in the second buffer region 45 is greater than or equal to the n-type impurity concentration in the second-terminal-side low-concentration region 42. The third buffer region 55 has a p-type impurity concentration that is lower than the p-type impurity concentration in the third-terminal-side high-concentration region 51. The p-type impurity concentration in the third buffer region 55 has a concentration gradient that decreases from the third-terminal-side high-concentration region 51 to the third-terminal-side low-concentration region 52 in the Z direction. The p-type impurity concentration in the third buffer region 55 is greater than or equal to the n-type impurity concentration in the third-terminal-side low-concentration region 52.

### [Method for Manufacturing a TVS Diode]

An example of the method for manufacturing the TVS diode 10 of the second embodiment is described. The second embodiment differs from the first embodiment in that processes for forming the first buffer region 35, the second buffer region 45, and the third buffer region 55 are added. These processes are described below.

The processes for forming the first buffer region 35, the second buffer region 45, and the third buffer region 55 are performed after the separation region 65, the first-terminal-side contact region 33, the second-terminal-side contact region 43, and the third-terminal-side contact region 53 are formed. The process for forming the first buffer region 35 is described below.

FIG. 32 and FIG. 33 show the cross-sectional structures in the process after the formation of the first-terminal-side contact region 33, the second-terminal-side contact region 43, and the third-terminal-side contact region 53. Furthermore, the second pin junction portion 40 is not shown in FIG. 32 and FIG. 33. Please refer to FIG. 29 for the second pin junction portion 40.

As shown in FIG. 32, due to the n-type impurities that form the separation region 65, the first-terminal-side contact region 33, the second-terminal-side contact region 43, and the third-terminal-side contact region 53, an auto-doped layer 36 is formed at an end of the first-terminal-side low-concentration region 32 that is close to the first-terminal-side high-concentration region 31. The n-type impurity concentration in this auto-doped layer 36 is higher than the n-type impurity concentration in the first-terminal-side low-concentration region 32, as shown in FIG. 31. In one example, the peak of the n-type impurity concentration in the auto-doped layer 36 is about 1×10¹⁶ cm⁻³.

As shown in FIG. 33, in the process of forming the first buffer region 35, p-type impurities are implanted into the first-terminal-side high-concentration region 31 using an ion implantation method with an ion implantation mask 970, for example. Herein, by adjusting the implantation energy (the acceleration voltage of the ions), the p-type impurities are implanted into the auto-doped layer 36. This results in the formation of the first buffer region 35 in the auto-doped layer 36. Furthermore, since the processes for forming the second buffer region 45 and the third buffer region 55 are similar to the process for forming the first buffer region 35, the description is omitted.

### Function

Referring to FIG. 31 and FIG. 32, the function of the TVS diode 10 of the second embodiment is described. The following describes the first pin junction portion 30, but the same applies to the second pin junction portion 40 and the third pin junction portion 50.

As shown in FIG. 31 and FIG. 32, the auto-doped layer 36 formed during the manufacturing process of the TVS diode 10 has an n-type impurity concentration higher than the n-type impurity concentration in the first-terminal-side low-concentration region 32. Therefore, the junction capacitance between the auto-doped layer 36 and the first-terminal-side high-concentration region 31 in the first pin junction portion 30 is greater than the junction capacitance between the first-terminal-side low-concentration region 32 and the first-terminal-side high-concentration region 31.

Thus, in the TVS diode 10 of the second embodiment, the p-type first buffer region 35 is provided between the first-terminal-side high-concentration region 31 and the first-terminal-side low-concentration region 32. As a result, the n-type impurities in the auto-doped layer 36 are neutralized by the p-type impurities in the first buffer region 35. Consequently, in the first pin junction portion 30, instead of the junction between the auto-doped layer 36 and the first-terminal-side high-concentration region 31, the junction is between the first buffer region 35 and the first-terminal-side low-concentration region 32. This eliminates the region with a high n-type impurity concentration in the first-terminal-side low-concentration region 32, thereby suppressing the increase in junction capacitance of the first pin junction portion 30.

### Effect

According to the TVS diode 10 of the second embodiment, the following effects can be obtained.

(2-1) The TVS diode 10 includes a semiconductor chip 20 that comprises a first surface 20S and a second surface 20R opposite to the first surface 20S. The semiconductor chip 20 includes a first pin junction portion 30 of a first polarity direction provided in a region close to the first surface 20S of the semiconductor chip 20, a diode pair region 60 including a first reverse pin junction portion 60A of a second polarity direction provided spaced apart from the first pin junction portion 30 in the plan view when viewed from the thickness direction of the semiconductor chip 20, a pn junction portion 60E of the first polarity direction that forms a diode pair with the first reverse pin junction portion 60A, a p-type first-terminal-side high-concentration region 31 provided spaced apart from the first surface 20S toward the second surface 20R of the semiconductor chip 20, an n-type first-terminal-side low-concentration region 32 provided at a position overlapping the first-terminal-side high-concentration region 31 in the plan view in a region closer to the first surface 20S than the first-terminal-side high-concentration region 31, an n-type first-terminal-side contact region 33 provided in the surface layer portion of the first-terminal-side low-concentration region 32, and a p-type first buffer region 35 that is in contact with the first-terminal-side high-concentration region 31 between the first-terminal-side high-concentration region 31 and the first-terminal-side low-concentration region 32 in the thickness direction of the semiconductor chip 20. A pin diode is formed of the first-terminal-side contact region 33, the first-terminal-side low-concentration region 32, and the first buffer region 35.

According to this configuration, even if a region of the first-terminal-side low-concentration region 32 with a high n-type impurity concentration is formed close to the first-terminal-side high-concentration region 31 during the manufacturing process of the TVS diode 10, the first buffer region 35 eliminates the region with the high n-type impurity concentration. Therefore, the increase in junction capacitance of the first pin junction portion 30 can be suppressed.

(2-2) The first buffer region 35 has a lower p-type impurity concentration than the first-terminal-side high-concentration region 31.

According to this configuration, the junction capacitance between the first buffer region 35 and the first-terminal-side low-concentration region 32 can be reduced, thereby achieving a reduction in the junction capacitance of the first pin junction portion 30.

(2-3) The p-type impurity concentration in the first buffer region 35 decreases in the thickness direction of the semiconductor chip 20 from the first-terminal-side high-concentration region 31 toward the first-terminal-side low-concentration region 32.

According to this configuration, the p-type impurity concentration in the first buffer region 35 reaches a minimum value at a boundary portion with the first-terminal-side low-concentration region 32. As a result, the junction capacitance between the first buffer region 35 and the first-terminal-side low-concentration region 32 can be reduced, thereby achieving a reduction in the junction capacitance of the first pin junction portion 30.

(2-4) The semiconductor chip 20 includes a second pin junction portion 40 of the second polarity direction provided at a position spaced apart from the first pin junction portion 30 in the plan view in a region close to the first surface 20S of the semiconductor chip 20, a p-type second-terminal-side high-concentration region 41 provided spaced apart from the first-terminal-side high-concentration region 31 in the plan view and at a position spaced apart from the first surface 20S toward the second surface 20R of the semiconductor chip 20, an n-type second-terminal-side low-concentration region 42 provided at a position overlapping the second-terminal-side high-concentration region 41 in the plan view in a region closer to the first surface 20S than the second-terminal-side high-concentration region 41, an n-type second-terminal-side contact region 43 provided in the surface layer portion of the second-terminal-side low-concentration region 42, and a p-type second buffer region 45 that is in contact with the second-terminal-side high-concentration region 41 between the second-terminal-side high-concentration region 41 and the second-terminal-side low-concentration region 42 in the thickness direction of the semiconductor chip 20. The second buffer region 45, the second-terminal-side low-concentration region 42, and the second-terminal-side contact region 43 form the second pin junction portion 40.

According to this configuration, even if a region of the low-concentration region 42 with a high n-type impurity concentration is formed close to the second-terminal-side high-concentration region 41 during the manufacturing process of the TVS diode 10, the region with the high n-type impurity concentration is eliminated by the second buffer region 45. Therefore, the increase in junction capacitance in the second pin junction portion 40 can be suppressed.

(2-5) The second buffer region 45 has a lower p-type impurity concentration than the second-terminal-side high-concentration region 41.

According to this configuration, the junction capacitance between the second buffer region 45 and the second-terminal-side low-concentration region 42 can be reduced, thereby achieving a reduction in the junction capacitance of the second pin junction portion 40.

(2-6) The p-type impurity concentration in the second buffer region 45 decreases from the second-terminal-side high-concentration region 41 to the second-terminal-side low-concentration region 42 in the thickness direction of the semiconductor chip 20.

According to this configuration, the p-type impurity concentration in the second buffer region 45 reaches a minimum value at a boundary portion with the second-terminal-side low-concentration region 42. As a result, the junction capacitance between the second buffer region 45 and the second-terminal-side low-concentration region 42 can be reduced, thereby achieving a decrease in the junction capacitance of the second pin junction portion 40.

(2-7) The semiconductor chip 20 includes a third pin junction portion 50 of the first polarity direction provided at a position spaced apart from both the first pin junction portion 30 and the second pin junction portion 40 in the plan view in a region close to the first surface 20S of the semiconductor chip 20, a p-type third-terminal-side high-concentration region 51 provided spaced apart from both the first-terminal-side high-concentration region 31 and the second-terminal-side high-concentration region 41 in the plan view at a position spaced apart from the first surface 20S toward the second surface 20R of the semiconductor chip 20, an n-type third-terminal-side low-concentration region 52 provided at a position overlapping the third-terminal-side high-concentration region 51 in the plan view in a region closer to the first surface 20S than the third-terminal-side high-concentration region 51, an n-type third-terminal-side contact region 53 provided in the surface layer portion of the low-concentration region 52, and a p-type third buffer region 55 that is in contact with the third-terminal-side high-concentration region 51 between the high-concentration region 51 and the low-concentration region 52 in the thickness direction of the semiconductor chip 20. The third pin junction portion 50 is formed of the third buffer region 55, the third-terminal-side low-concentration region 52, and the third-terminal-side contact region 53.

According to this configuration, even if a region of the low-concentration region 52 with a high n-type impurity concentration is formed close to the third-terminal-side high-concentration region 51 during the manufacturing process of the TVS diode 10, the region with the high n-type impurity concentration is eliminated by the third buffer region 55. Therefore, the increase in junction capacitance of the third pin junction portion 50 can be suppressed.

(2-8) The third buffer region 55 has a lower p-type impurity concentration than the third-terminal-side high-concentration region 51.

According to this configuration, the junction capacitance between the third buffer region 55 and the third-terminal-side low-concentration region 52 can be reduced, thereby achieving a reduction in the junction capacitance of the third pin junction portion 50.

(2-9) The p-type impurity concentration in the third buffer region 55 decreases from the third-terminal-side high-concentration region 51 to the third-terminal-side low-concentration region 52 in the thickness direction of the semiconductor chip 20.

According to this configuration, the p-type impurity concentration in the third buffer region 55 reaches a minimum at a boundary portion with the third-terminal-side low-concentration region 52. As a result, the junction capacitance between the third buffer region 55 and the third-terminal-side low-concentration region 52 can be reduced, thereby achieving a decrease in the junction capacitance of the third pin junction portion 50.

### Third Embodiment

Referring to FIG. 34 to FIG. 39, the third embodiment of the TVS diode 10 is described. The TVS diode 10 of the third embodiment differs from the TVS diode 10 of the first embodiment mainly in the configurations of the first pin junction portion 30, the second pin junction portion 40, and the third pin junction portion 50. In the following, common components with the first embodiment are denoted by the same reference numerals, and the description is omitted.

FIG. 34 schematically shows the planar structure of the semiconductor chip 20 in the TVS diode 10 of the third embodiment. FIG. 35 schematically shows the cross-sectional structure of the TVS diode 10 taken along line F35-F35 in FIG. 34. FIG. 36 schematically shows the cross-sectional structure of the TVS diode 10 taken along line F36-F36 in FIG. 34. FIG. 37 to FIG. 39 schematically show an example of the cross-sectional structure of the manufacturing process of the TVS diode 10 of the third embodiment.

As shown in FIG. 34 and FIG. 35, the first pin junction portion 30 includes a first separation trench structure 120A instead of the first partition region 34 (refer to FIG. 2). The first separation trench structure 120A is configured to partition the first pin junction portion 30 from the diode pair region 60, for example.

The first separation trench structure 120A includes a first separation trench 121A, a first separation insulating layer 122A, and a first separation electrode 123A.

The first separation trench 121A is annular surrounding the first-terminal-side high-concentration region 31 in the plan view. In one example, the first separation trench 121A has a rectangular ring shape in the plan view. The first separation trench 121A is formed by digging down from the first surface 20S toward the second surface 20R of the semiconductor chip 20. The first separation trench 121A penetrates through the third semiconductor layer 25 and the second semiconductor layer 24 and reaches the first semiconductor layer 23. In one example, the bottom wall of the first separation trench 121A is positioned closer to the second surface 20R of the semiconductor chip 20 than the boundary between the first-terminal-side high-concentration region 31 and the first semiconductor layer 23 in the Z direction. Therefore, the bottom wall of the first separation trench 121A exposes the first semiconductor layer 23.

The first separation trench 121A includes an inner peripheral wall and an outer peripheral wall. The inner peripheral wall of the first separation trench 121A exposes the first-terminal-side low-concentration region 32 and the first-terminal-side high-concentration region 31. The outer peripheral wall of the first separation trench 121A exposes the first to third semiconductor layers 23 to 25. As a result, the first separation trench 121A separates the first-terminal-side low-concentration region 32 and the first-terminal-side high-concentration region 31 from the second semiconductor layer 24 and the third semiconductor layer 25.

Both the inner peripheral wall and the outer peripheral wall of the first separation trench 121A may be provided perpendicular to the first surface 20S of the semiconductor chip 20. Additionally, both the inner peripheral wall and the outer peripheral wall of the first separation trench 121A may taper from the first surface 20S toward the bottom wall.

The width dimension of the first separation trench 121A may be 0.1 μm or more and 3 μm or less. In one example, the width dimension of the first separation trench 121A is 1.5 μm or more and 2.5 μm or less. Herein, the width dimension of the first separation trench 121A is defined by the distance between the inner peripheral wall and the outer peripheral wall in a direction orthogonal to the direction in which the first separation trench 121A extends in the plan view.

The depth dimension of the first separation trench 121A may be 1 μm or more and 50 μm or less. In one example, the depth dimension of the first separation trench 121A is 15 μm or more and 35 μm or less. Herein, the depth dimension of the first separation trench 121A is defined by the distance between the first surface 20S of the semiconductor chip 20 and the bottom surface of the first separation trench 121A in the Z direction.

The first separation insulating layer 122A is provided within the first separation trench 121A. More specifically, the first separation insulating layer 122A is a film along the inner wall of the first separation trench 121A. As a result, the first separation insulating layer 122A partitions a recess space within the first separation trench 121A.

The first separation insulating layer 122A may include at least one of a SiO₂ layer and a SiN layer. The first separation insulating layer 122A may comprise a laminated structure formed by laminating a SiO₂ layer and a SiN layer in any order. The first separation insulating layer 122A may also comprise a single-layer structure formed of either a SiO₂ layer or a SiN layer. The first separation insulating layer 122A may be formed of the same insulating material as the first insulating layer 71. In one example, the first separation insulating layer 122A comprises a single-layer structure formed of a SiO₂ layer.

The first separation electrode 123A is embedded in the first separation trench 121A with the first separation insulating layer 122A in between. The first separation electrode 123A is annular surrounding the first-terminal-side high-concentration region 31 in the plan view. In one example, the first separation electrode 123A has a rectangular ring shape in the plan view. The first separation electrode 123A is formed of polysilicon, for example. The first separation electrode 123A is in an electrically floating state.

As shown in FIG. 34 and FIG. 36, the second pin junction portion 40 includes a second separation trench structure 120B instead of the second partition region 44 (refer to FIG. 3). The second separation trench structure 120B is configured to partition the second pin junction portion 40 from the diode pair region 60, for example. The second separation trench structure 120B includes the second separation trench 121B, the second separation insulating layer 122B, and the second separation electrode 123B. The second separation trench 121B is provided on the first surface 20S of the semiconductor chip 20 to partition the second pin junction portion 40 from the diode pair region 60. The second separation insulating layer 122B is provided within the second separation trench 121B. The second separation electrode 123B is embedded in the second separation trench 121B with the second separation insulating layer 122B in between. The second separation electrode 123B is in an electrically floating state. Furthermore, the configurations of the second separation trench 121B, the second separation insulating layer 122B, and the second separation electrode 123B are the same as those of the first separation trench 121A, the first separation insulating layer 122A, and the first separation electrode 123A, respectively, so the detailed descriptions are omitted.

As shown in FIG. 34 and FIG. 35, the third pin junction portion 50 includes a third separation trench structure 120C instead of the third partition region 54 (refer to FIG. 2). The third separation trench structure 120C is configured to partition the third pin junction portion 50 from the diode pair region 60, for example. The third separation trench structure 120C includes the third separation trench 121C, the third separation insulating layer 122C, and the third separation electrode 123C. The third separation trench 121C is provided on the first surface 20S of the semiconductor chip 20 to partition the third pin junction portion 50 from the diode pair region 60. The third separation insulating layer 122C is provided within the third separation trench 121C. The third separation electrode 123C is embedded in the third separation trench 121C with the third separation insulating layer 122C in between. The third separation electrode 123C is in an electrically floating state. The configurations of the third separation trench 121C, the third separation insulating layer 122C, and the third separation electrode 123C are the same as those of the first separation trench 121A, the first separation insulating layer 122A, and the first separation electrode 123A, respectively, so the descriptions are omitted.

### [Method for Manufacturing a TVS Diode]

An example of the method for manufacturing the TVS diode 10 of the third embodiment is described. The method for manufacturing the TVS diode 10 of the third embodiment differs from that of the first embodiment mainly in including a process of forming a first separation trench structure 120A, a second separation trench structure 120B, and a third separation trench structure 120C instead of a process of forming the first partition region 34, the second partition region 44, and the third partition region 54. The process is described below.

FIG. 37 to FIG. 39 show a process of forming the first separation trench structure 120A and the third separation trench structure 120C. Furthermore, although not shown, the second separation trench structure 120B is formed in a similar manner as the first separation trench structure 120A and the third separation trench structure 120C.

As shown in FIG. 37, this process includes the process of forming the first separation trench 121A and the third separation trench 121C. More specifically, a hard mask (not shown) with a predetermined pattern is first formed on the first surface 20S of the semiconductor chip 20. The hard mask exposes the regions of the first surface 20S where each of the separation trenches 121A, 121B, and 121C is to be formed while covering the other regions. The hard mask may be formed by a CVD method or an oxidation treatment method. The patterning of the hard mask may be performed by an etching method using an etching mask. Next, the regions of the first surface 20S of the semiconductor chip 20 that are exposed from the hard mask are removed through an etching method using the hard mask. The etching method may be a dry etching method. An example of the dry etching method may be a Reactive Ion Etching (RIE) method. As a result, the first separation trench 121A, the second separation trench 121B, and the third separation trench 121C are formed. Afterwards, the hard mask is removed.

As shown in FIG. 38, the process of forming the first separation trench structure 120A and the third separation trench structure 120C includes the process of forming an insulating layer 870. The insulating layer 870 is formed in the form of a film along the first surface 20S of the semiconductor chip 20 and the inner walls of each of the separation trenches 121A, 121B, and 121C. The insulating layer 870 is the insulating layer that forms the first separation insulating layer 122A and the third separation insulating layer 122C. Furthermore, although not shown, the insulating layer 870 is the insulating layer that forms the second separation insulating layer 122B. The insulating layer 870 may be formed by a CVD method or an oxidation treatment method (for example, a thermal oxidation treatment method). In one example, the insulating layer 870 is formed by a thermal oxidation treatment method.

As shown in FIG. 39, the process of forming the first separation trench structure 120A and the third separation trench structure 120C includes the process of forming the first separation electrode 123A and the third separation electrode 123C. In this process, an electrode layer 880 is first formed on the insulating layer 870. The electrode layer 880 is the layer that forms the first separation electrode 123A and the third separation electrode 123C. Furthermore, although not shown, the electrode layer 880 is the layer that forms the second separation electrode 123B. The electrode layer 880 is formed of polysilicon, for example. The electrode layer 880 is embedded in each of the separation trenches 121A, 121B, and 121C with the insulating layer 870 in between. The electrode layer 880 may be formed by a CVD method, for example.

Next, although not shown, unnecessary portions of the electrode layer 880 are removed by an etching method. Portions of the electrode layer 880 other than those embedded in the separation trenches 121A and 121C are removed. The electrode layer 880 is removed until the insulating layer 870 is exposed. As a result, the first separation electrode 123A and the third separation electrode 123C are formed. Through the above processes, the first separation trench structure 120A and the third separation trench structure 120C are formed. Additionally, by removing the portions of the electrode layer 880 other than those embedded in the second separation trench 121B, the second separation electrode 123B is formed. This results in the formation of the second separation trench structure 120B.

Subsequently, although not shown, a process of forming the insulating layer 850 is performed. The first insulating layer 851 of the insulating layer 850 covers the first separation trench structure 120A, the second separation trench structure 120B, and the third separation trench structure 120C. As a result, each of the separation electrodes 123A, 123B, and 123C is covered by the insulating layer 870 and the first insulating layer 851.

### Effect

According to the TVS diode 10 of the third embodiment, the following effects can be obtained.

(3-1) The semiconductor chip 20 includes a first separation trench 121A provided on the first surface 20S to partition the first pin junction portion 30 from the diode pair region 60, and a second separation trench 121B provided on the first surface 20S to partition the second pin junction portion 40 from the diode pair region 60. The TVS diode 10 includes a first separation insulating layer 122A provided in the first separation trench 121A and a second separation insulating layer 122B provided in the second separation trench 121B.

According to this configuration, each of the insulation between the first pin junction portion 30 and the diode pair region 60 and the insulation between the second pin junction portion 40 and the diode pair region 60 can be enhanced. This allows for a reduction in the distance between the first pin junction portion 30 as well as the second pin junction portion 40 and the diode pair region 60. Therefore, if the chip size is the same, the area of the diode pair region 60 in the plan view can be increased, thereby achieving the improvement in surge absorption performance. On the other hand, if the area of the diode pair region 60 in the plan view remains the same, the reduction in distance between the first pin junction portion 30 as well as the second pin junction portion 40 and the diode pair region 60 allows for miniaturization of the TVS diode 10.

### Fourth Embodiment

Referring to FIG. 40 to FIG. 43, the TVS diode 10 of the fourth embodiment is described. The TVS diode 10 of the fourth embodiment differs from the TVS diode 10 of the first embodiment mainly in the planar structure of the TVS diode 10. In the following, common components with the first embodiment are denoted by the same reference numerals, and their descriptions are omitted.

FIG. 40 schematically shows the planar structure of the semiconductor chip 20 in the TVS diode 10 of the fourth embodiment. FIG. 41 schematically shows the planar structure of the first to third connection electrodes 81 to 83 and the wiring 90 of the TVS diode 10. FIG. 42 schematically shows the cross-sectional structure of the TVS diode 10 taken along the line F42-F42 in FIG. 40. FIG. 43 schematically shows the planar structure of the TVS diode 10.

As shown in FIG. 40, in the TVS diode 10 of the fourth embodiment, the first pin junction portion 30, the second pin junction portion 40, and the third pin junction portion 50 are disposed side by side with the diode pair region 60 in the Y direction. The first pin junction portion 30, the second pin junction portion 40, and the third pin junction portion 50 are disposed closer to the fourth side surface 20D in the plan view than the diode pair region 60. In other words, the diode pair region 60 is disposed closer to the third side surface 20C in the plan view than the first pin junction portion 30, the second pin junction portion 40, and the third pin junction portion 50.

The first pin junction portion 30, the second pin junction portion 40, and the third pin junction portion 50 are disposed in a line in the X direction. More specifically, the first pin junction portion 30, the second pin junction portion 40, and the third pin junction portion 50 are arranged at the same position as each other in the Y direction while being spaced apart from each other in the X direction. As shown in FIG. 42, the cross-sectional structure of each of the first pin junction portion 30, the second pin junction portion 40, and the third pin junction portion 50 is similar to that of the first embodiment. Furthermore, the partition regions between the first-terminal-side low-concentration region 32 and the second-terminal-side low-concentration region 42 form the first partition region 34 and the second partition region 44. The partition regions between the second-terminal-side low-concentration region 42 and the third-terminal-side low-concentration region 52 form the second partition region 44 and the third partition region 54.

As shown in FIG. 40, the diode pair region 60 is rectangular in the plan view. In one example, the diode pair region 60 has a rectangular shape with its longitudinal direction in the X direction (the arrangement direction of the first pin junction portion 30, the second pin junction portion 40, and the third pin junction portion 50) and its lateral direction in the Y direction. The diode pair region 60 is provided with the first reverse pin junction portion 60A, the second reverse pin junction portion 60B, and the third reverse pin junction portion 60C. Each of the reverse pin junction portions 60A, 60B, 60C is disposed at a position overlapping the high-concentration region 61 in the plan view.

The first reverse pin junction portion 60A, the second reverse pin junction portion 60B, and the third reverse pin junction portion 60C are arranged spaced apart from each other in the X direction. The first reverse pin junction portion 60A is disposed at a position overlapping the first pin junction portion 30 when viewed from the Y direction. The second reverse pin junction portion 60B is disposed at a position overlapping the second pin junction portion 40 when viewed from the Y direction. The third reverse pin junction portion 60C is disposed at a position overlapping the third pin junction portion 50 when viewed from the Y direction. As shown in FIG. 42, the cross-sectional structure of each of the reverse pin junction portions 60A, 60B, 60C is similar to that of the first embodiment.

As shown in FIG. 40, the separation region 65 is provided to surround each of the first low-concentration region 62A, the second low-concentration region 62B, and the third low-concentration region 62C. Similar to the first embodiment, the separation region 65 includes the first to third separation regions 65A to 65C and the wiring connection region 65P. The first separation region 65A is provided in the separation region 65 between the first contact region 63A and the first-terminal-side contact region 33 in the Y direction. The second separation region 65B is provided in the separation region 65 between the second contact region 63B and the second-terminal-side contact region 43 in the Y direction. The third separation region 65C is provided in the separation region 65 between the third contact region 63C and the third-terminal-side contact region 53 in the Y direction. The wiring connection region 65P is provided to partially surround each of the reverse pin junction portions 60A, 60B, 60C individually in the plan view.

As indicated by the dashed line in FIG. 40, the outer edge of the internal region 64 is located inward from the outer edge of the high-concentration region 61 in the plan view. In one example, the internal region 64 is a rectangular shape that is slightly smaller than the high-concentration region 61 (diode pair region 60) in the plan view. Therefore, the internal region 64 is provided to overlap each of the reverse pin junction portions 60A, 60B, 60C in the plan view. More specifically, the internal region 64 is provided to overlap each of the first low-concentration region 62A, the second low-concentration region 62B, and the third low-concentration region 62C in the plan view. As shown in FIG. 42, the cross-sectional structure of the pn junction portion 60E is similar to that of the first embodiment.

As shown in FIG. 41, the first connection electrode 81 includes a pin connection portion 81A, a wiring portion 81B, and a reverse pin connection portion 81C, similar to the first embodiment. In one example, the pin connection portion 81A is a rectangular shape that covers the entire area of the first-terminal-side contact region 33 in the plan view. The wiring portion 81B extends along the Y direction from the pin connection portion 81A toward the third side surface 20C in the plan view. The wiring portion 81B is connected offset toward the second side surface 20B relative to the center of the pin connection portion 81A in the X direction. In one example, the reverse pin connection portion 81C covers the entire area of the first contact region 63A in the plan view.

The second connection electrode 82 includes a pin connection portion 82A, a wiring portion 82B, and a reverse pin connection portion 82C, similar to the first embodiment. The wiring portion 82B extends along the Y direction from the pin connection portion 82A toward the third side surface 20C. In one example, the center of the wiring portion 82B in the X direction is at the same position as the center of the pin connection portion 82A. In one example, the reverse pin connection portion 82C covers the entire area of the second contact region 63B in the plan view.

The third connection electrode 83 includes a pin connection portion 83A, a wiring portion 83B, and a reverse pin connection portion 83C, similar to the first embodiment. The wiring portion 83B extends along the Y direction from the pin connection portion 83A toward the third side surface 20C. In one example, the wiring portion 83B is connected offset toward the first side surface 20A relative to the center of the pin connection portion 83A in the X direction. In one example, the reverse pin connection portion 83C covers the entire area of the third contact region 63C in the plan view.

The wiring 90 is comb-shaped in the plan view. The wiring 90 includes a first recess 96A, a second recess 96B, and a third recess 96C, similar to the first embodiment. Each of the recesses 96A to 96C opens toward the fourth side surface 20D in the Y direction. Furthermore, the wiring 90 includes first to fourth tooth portions 97A to 97D and a connection portion 97E. The first to fourth tooth portions 97A to 97D are arranged spaced apart from each other in the X direction in the plan view. The connection portion 97E is disposed closer to the third side surface 20C than the first to fourth tooth portions 97A to 97D. The connection portion 97E connects the first to fourth tooth portions 97A to 97D. The first to fourth tooth portions 97A to 97D are arranged in this order from the first side surface 20A toward the second side surface 20B. The first to fourth tooth portions 97A to 97D extend along the Y direction from the connection portion 97E toward the fourth side surface 20D. The first recess 96A is formed by the first tooth portion 97A, the second tooth portion 97B, and the connection portion 97E. The second recess 96B is formed by the second tooth portion 97B, the third tooth portion 97C, and the connection portion 97E. The third recess 96C is formed by the third tooth portion 97C, the fourth tooth portion 97D, and the connection portion 97E.

The wiring portion 81B of the first connection electrode 81 is disposed in the first recess 96A. The wiring portion 82B of the second connection electrode 82 is disposed in the second recess 96B. The wiring portion 83B of the third connection electrode 83 is disposed in the third recess 96C. Thus, the wiring 90 is provided to partially surround the first connection electrode 81, the second connection electrode 82, and the third connection electrode 83 individually in the plan view.

As shown in FIG. 43, the first to third terminal opening portions 77A to 77C of the TVS diode 10 of the fourth embodiment are arranged at the same position as each other in the Y direction and spaced apart from each other in the X direction. The first to third terminal opening portions 77A to 77C are disposed closer to the fourth side surface 20D than the third side surface 20C in the plan view. The first terminal opening portion 77A is disposed at a position overlapping the first-terminal-side contact region 33 (refer to FIG. 40) in the plan view. The second terminal opening portion 77B is disposed at a position overlapping the second-terminal-side contact region 43 (refer to FIG. 40) in the plan view. The third terminal opening portion 77C is disposed at a position overlapping the third-terminal-side contact region 53 in the plan view. Furthermore, according to the TVS diode 10 of the fourth embodiment, similar effects to those of the first embodiment can be obtained.

### Fifth Embodiment

Referring to FIG. 44 to FIG. 46, the TVS diode 10 of the fifth embodiment is described. The TVS diode 10 of the fifth embodiment mainly differs from the TVS diode 10 of the first embodiment in its planar structure. In the following, common components with the first embodiment are denoted by the same reference numerals, and their descriptions are omitted.

FIG. 44 schematically shows the planar structure of the semiconductor chip 20 in the TVS diode 10 of the fifth embodiment. FIG. 45 schematically shows the planar structure of the first to third connection electrodes 81 to 83 and the wiring 90 of the TVS diode 10. FIG. 46 schematically shows the planar structure of the TVS diode 10.

As shown in FIG. 44, the TVS diode 10 of the fifth embodiment includes the first pin junction portion 30, the second pin junction portion 40, the first reverse pin junction portion 60A, the second reverse pin junction portion 60B, and the pn junction portion 60E. In other words, the TVS diode 10 of the fifth embodiment is configured by omitting the third pin junction portion 50 and the third reverse pin junction portion 60C (refer to FIG. 2 together) from the first embodiment. Furthermore, although not shown, the cross-sectional structures of the first pin junction portion 30 and the second pin junction portion 40 are similar to those of the first embodiment.

The diode pair region 60 (high-concentration region 61) includes the first region 66A, the second region 66B, and the first connection region 67A. In other words, the diode pair region 60 (high-concentration region 61) of the fifth embodiment is configured by omitting the third region 66C and the second connection region 67B from the first embodiment. As indicated by the dashed line in FIG. 44, the outer edge of the internal region 64 is located inward from the outer edge of the high-concentration region 61 in the plan view. In one example, the internal region 64 is slightly smaller in the plan view than the high-concentration region 61 (diode pair region 60). Therefore, the internal region 64 is provided to overlap each reverse pin junction portion 60A and 60B in the plan view. More specifically, the internal region 64 is provided to overlap each of the first low-concentration region 62A and the second low-concentration region 62B in the plan view. The cross-sectional structure of each reverse pin junction portion 60A and 60B is similar to that of the first embodiment.

As shown in FIG. 45, the TVS diode 10 includes the first connection electrode 81, the second connection electrode 82, and the wiring 90. In other words, the TVS diode 10 of the fifth embodiment is configured by omitting the third connection electrode 83 from the first embodiment. Additionally, the planar structure of the wiring 90 differs from that of the first embodiment. The configurations of the first connection electrode 81 and the second connection electrode 82 are similar to those of the first embodiment.

The wiring 90 includes the first region 91, the second region 92, and the first connection region 94. The wiring 90 also includes the first recess 96A and the second recess 96B. In other words, the wiring 90 of the fifth embodiment is configured by omitting the third region 93, the second connection region 95, and the third recess 96C from the first embodiment.

As shown in FIG. 46, the TVS diode 10 of the fifth embodiment includes a first terminal opening portion 77A that exposes a portion of the first connection electrode 81 and a second terminal opening portion 77B that exposes a portion of the second connection electrode 82. The first terminal opening portion 77A is disposed in the corner portion of the semiconductor chip 20 close to the first side surface 20A and the fourth side surface 20D in the plan view. The second terminal opening portion 77B is disposed in the corner portion of the semiconductor chip 20 close to the second side surface 20B and the fourth side surface 20D in the plan view. The first terminal opening portion 77A is disposed at a position overlapping the first-terminal-side contact region 33 (refer to FIG. 44) in the plan view. The second terminal opening portion 77B is disposed at a position overlapping the second-terminal-side contact region 43 (refer to FIG. 44) in the plan view. Furthermore, the TVS diode 10 of the fifth embodiment achieves effects similar to those of the first embodiment.

### Sixth Embodiment

Referring to FIG. 47 to FIG. 49, the TVS diode 10 of the sixth embodiment is described. The TVS diode 10 of the sixth embodiment mainly differs from the TVS diode 10 of the first embodiment in its planar structure. In the following, common components with the first embodiment are denoted with the same reference numbers, and their descriptions are omitted.

FIG. 47 schematically shows the planar structure of the semiconductor chip 20 in the TVS diode 10 of the sixth embodiment. FIG. 48 schematically shows the planar structure of the first to third connection electrodes 81 to 83 and the wiring 90 of the TVS diode 10. FIG. 49 schematically shows the planar structure of the TVS diode 10.

As shown in FIG. 47, the TVS diode 10 of the sixth embodiment includes the first pin junction portion 30, the second pin junction portion 40, the first reverse pin junction portion 60A, the second reverse pin junction portion 60B, and the pn junction portion 60E. In other words, the TVS diode 10 of the third embodiment is configured by omitting the third pin junction portion 50 and the third reverse pin junction portion 60C (refer to FIG. 2) from the first embodiment.

The first pin junction portion 30 and the second pin junction portion 40 are disposed spaced apart from each other in the Y direction. The diode pair region 60 is provided between the first pin junction portion 30 and the second pin junction portion 40 in the Y direction, spaced apart from both the first pin junction portion 30 and the second pin junction portion 40.

The first pin junction portion 30 and the second pin junction portion 40 have rectangular shapes, with the longitudinal direction in the X direction and the lateral direction in the Y direction (the arrangement direction of the first pin junction portion 30 and the second pin junction portion 40). Therefore, both the first-terminal-side low-concentration region 32 and the second-terminal-side low-concentration region 42 have substantially rectangular shapes in the plan view, with the longitudinal direction in the X direction and the lateral direction in the Y direction. Both the first-terminal-side contact region 33 and the second-terminal-side contact region 43 have substantially rectangular shapes in the plan view, with the longitudinal direction in the X direction and the lateral direction in the Y direction. Each of the four corner portions of each of the first- and second-terminal-side low-concentration regions 32, 42 and the first- and second-terminal-side contact regions 33, 43 are curved. The cross-sectional structures of the first pin junction portion 30 and the second pin junction portion 40 are the same as those of the first embodiment.

The diode pair region 60 (high-concentration region 61) is rectangular in the plan view. In one example, the diode pair region 60 (high-concentration region 61) is rectangular in the plan view, with its longitudinal direction in the X direction and its lateral direction in the Y direction. The diode pair region 60 is provided with the first reverse pin junction portion 60A and the second reverse pin junction portion 60B. In one example, the first reverse pin junction portion 60A and the second reverse pin junction portion 60B are arranged at the same position as each other in the Y direction and spaced apart from each other in the X direction. The first low-concentration region 62A and the second low-concentration region 62B are arranged at the same position as each other in the Y direction and spaced apart from each other in the X direction. The first contact region 63A and the second contact region 63B are arranged at the same position as each other in the Y direction and spaced apart from each other in the X direction. Each of the low-concentration regions 62A, 62B has an substantially elliptical shape, with its lateral direction in the X direction (the arrangement direction of the first low-concentration region 62A and the second low-concentration region 62B) and its longitudinal direction in the Y direction. Each of the contact regions 63A, 63B has an substantially elliptical shape, with its lateral direction in the X direction (the arrangement direction of the first contact region 63A and the second contact region 63B) and its longitudinal direction in the Y direction.

As indicated by the dashed line in FIG. 47, the outer edge of the internal region 64 is located inward to the outer edge of the high-concentration region 61 in the plan view. In one example, the internal region 64 is a rectangular shape that is smaller than the high-concentration region 61 (diode pair region 60) in the plan view. Therefore, the internal region 64 is provided to overlap each of the reverse pin junction portions 60A and 60B in the plan view. More specifically, the internal region 64 is provided to overlap each of the first low-concentration region 62A and the second low-concentration region 62B in the plan view. The cross-sectional structure of the pn junction portion 60E is similar to that of the first embodiment.

As shown in FIG. 48, the TVS diode 10 includes a first connection electrode 81, a second connection electrode 82, and a wiring 90. In other words, the TVS diode 10 of the sixth embodiment has a configuration in which the third connection electrode 83 is omitted from the first embodiment. Additionally, the planar structure of the wiring 90 differs from that of the first embodiment.

The first connection electrode 81 includes a pin connection portion 81A, a wiring portion 81B, and a reverse pin connection portion 81C. The wiring portion 81B and the reverse pin connection portion 81C are similar to those of the first connection electrode 81 of the first embodiment. The pin connection portion 81A has a substantially rectangular shape with its longitudinal direction in the X direction and its lateral direction in the Y direction in the plan view. The pin connection portion 81A covers the entire area of the first-terminal-side contact region 33 in the plan view.

The second connection electrode 82 includes a pin connection portion 82A, a wiring portion 82B, and a reverse pin connection portion 82C. The wiring portion 82B and the reverse pin connection portion 82C are similar to those of the second connection electrode 82 of the first embodiment. The pin connection portion 82A has a substantially rectangular shape with its longitudinal direction in the X direction and its lateral direction in the Y direction in the plan view. The pin connection portion 82A covers the entire area of the second-terminal-side contact region 43 in the plan view.

The wiring 90 is provided to partially surround both the first connection electrode 81 and the second connection electrode 82 individually in the plan view. The wiring 90 includes a first recess 96A and a second recess 96B. The first recess 96A is provided to surround the first connection electrode 81 in the plan view. The second recess 96B is provided to surround the second connection electrode 82 in the plan view.

As shown in FIG. 49, the first terminal opening portion 77A and the second terminal opening portion 77B of the TVS diode 10 of the sixth embodiment are arranged at the same position as each other in the X direction and spaced apart from each other in the Y direction. The first terminal opening portion 77A is disposed at an end of the semiconductor chip 20 closer to the fourth side surface 20D among its two ends in the Y direction in the plan view. The second terminal opening portion 77B is disposed at an end of the semiconductor chip 20 closer to the third side surface 20C among its two ends in the Y direction in the plan view. Each of the first terminal opening portion 77A and the second terminal opening portion 77B has a substantially elliptical shape with its longitudinal direction in the Y direction and its lateral direction in the X direction in the plan view. The first terminal opening portion 77A is disposed at a position overlapping the first-terminal-side contact region 33 (refer to FIG. 47). The second terminal opening portion 77B is disposed at a position overlapping the second-terminal-side contact region 43 (refer to FIG. 47). Furthermore, according to the TVS diode 10 of the sixth embodiment, effects similar to those of the first embodiment can be obtained.

### Seventh Embodiment

Referring to FIG. 50 to FIG. 53, the TVS diode 10 of the seventh embodiment is described. The TVS diode 10 of the seventh embodiment mainly differs from that of the TVS diode 10 of the first embodiment in the planar structure of the TVS diode 10. In the following, the common components with the first embodiment are denoted by the same reference numerals, and their descriptions are omitted.

FIG. 50 schematically shows the planar structure of the semiconductor chip 20 in the TVS diode 10 of the seventh embodiment. FIG. 51 schematically shows the cross-sectional structure of the TVS diode 10 taken along line F51-F51 in FIG. 50. FIG. 52 schematically shows the planar structure of the first to third connection electrodes 81 to 83 and the wiring 90 of the TVS diode 10. FIG. 53 schematically shows the planar structure of the TVS diode 10.

As shown in FIG. 50, the TVS diode 10 of the seventh embodiment has a configuration in which a fourth pin junction portion 130 and a fourth reverse pin junction portion 60D are added to the TVS diode 10 of the first embodiment.

The fourth pin junction portion 130 is disposed closer to the second side surface 20B and the third side surface 20C than the third pin junction portion 50 in the plan view. The fourth pin junction portion 130 is disposed at the same position in the Y direction as the second pin junction portion 40. In the plan view, the third region 66C of the diode pair region 60 is disposed between the second pin junction portion 40 and the fourth pin junction portion 130. Therefore, it can be said that the second pin junction portion 40 and the fourth pin junction portion 130 are disposed opposite to each other with the diode pair region 60 in between in the plan view.

As shown in FIG. 51, the fourth pin junction portion 130 includes a fourth-terminal-side high-concentration region 131, a fourth-terminal-side low-concentration region 132, a fourth-terminal-side contact region 133, and a fourth partition region 134. The fourth pin junction portion 130 is formed of the fourth-terminal-side high-concentration region 131, the fourth-terminal-side low-concentration region 132, and the fourth-terminal-side contact region 133. As shown in FIG. 50 and FIG. 51, the configuration of the fourth pin junction portion 130 is similar to that of the third pin junction portion 50. Additionally, in the seventh embodiment, the configurations of the first pin junction portion 30, the second pin junction portion 40, and the third pin junction portion 50 are the similar to those of the first embodiment. Therefore, the first pin junction portion 30, the second pin junction portion 40, the third pin junction portion 50, and the fourth pin junction portion 130 have the same configuration as each other. Therefore, the detailed descriptions of the fourth-terminal-side high-concentration region 131, the fourth-terminal-side low-concentration region 132, the fourth-terminal-side contact region 133, and the fourth partition region 134 are omitted. Furthermore, in the fourth pin junction portion 130, the p-type fourth-terminal-side high-concentration region 131 forms the P layer of the pin diode, the n-type fourth-terminal-side low-concentration region 132 forms the I layer of the pin diode, and the n-type fourth-terminal-side contact region 133 forms the N layer of the pin diode. That is, the fourth-terminal-side high-concentration region 131, the fourth-terminal-side low-concentration region 132, and the fourth-terminal-side contact region 133 form a pin junction in the Z direction. Therefore, in the fourth pin junction portion 130, the fourth-terminal-side high-concentration region 131, the fourth-terminal-side low-concentration region 132, and the fourth-terminal-side contact region 133 form a pin diode (diode 208) of the first polarity direction.

In the example shown in FIG. 51, the shortest distance DE between the fourth partition region 134 of the fourth pin junction portion 130 and the third partition region 54 of the third pin junction portion 50 is equal to the shortest distance DB between the second partition region 44 of the second pin junction portion 40 and the third partition region 54. Additionally, the shortest distance DE is equal to the shortest distance DA between the first partition region 34 of the first pin junction portion 30 and the second partition region 44. The shortest distance DF between the fourth partition region 134 and the second partition region 44 is equal to the shortest distance DC between the first partition region 34 and the third partition region 54. Furthermore, each of the shortest distances DE and DF may be arbitrarily changed. In one example, the shortest distance DE may differ from at least one of the shortest distance DA and the shortest distance DB. The shortest distance DF may also differ from the shortest distance DC.

As shown in FIG. 50, the diode pair region 60 (high-concentration region 61) includes the fourth region 66D and the third connection region 67C. The fourth region 66D is provided to be shifted in the Y direction relative to the third region 66C. More specifically, the fourth region 66D is provided closer to the second side surface 20B and the fourth side surface 20D relative to the third region 66C. The fourth region 66D is provided at the same position in the Y direction as the second region 66B.

The fourth region 66D includes the first to fourth sides 66DA to 66DD. The first side 66DA is the side of the fourth region 66D close to the first side surface 20A and extends in the Y direction in the plan view. The second side 66DB is the side of the fourth region 66D close to the second side surface 20B and extends in the Y direction in the plan view. The third side 66DC is the side of the fourth region 66D close to the third side surface 20C and extends in the X direction in the plan view. The fourth side 66DD is the side of the fourth region 66D close to the fourth side surface 20D and extends in the X direction in the plan view. The first side 66BA and the fourth side 66BD are disposed closer to the fourth side surface 20D than the third region 66C in the Y direction.

The fourth region 66D includes a corner portion between the first side 66DA and the fourth side 66DD, a corner portion between the second side 66DB and the fourth side 66DD, and a corner portion between the second side 66DB and the third side 66DC. Each of the corner portions is curved in the plan view.

The third connection region 67C is provided between the third region 66C and the fourth region 66D. The third connection region 67C is the region that connects the third region 66C and the fourth region 66D. The third region 66C and the third connection region 67C are disposed between the third pin junction portion 50 and the fourth pin junction portion 130 in a direction that intersects both the X direction and the Y direction in the plan view.

Due to the provision of the fourth region 66D and the third connection region 67C, the shape of the third region 66C in the plan view differs from that of the first embodiment. Specifically, the corner portion between the second side 66CB and the fourth side 66CD is omitted from the third region 66C.

In the example shown in FIG. 50, the width dimension (dimension in the X direction) WD of the fourth region 66D is equal to the width dimension WA of the first region 66A. The width dimension WB of the second region 66B is larger than the width dimension WD of the fourth region 66D. The width dimension WC of the third region 66C is larger than the width dimension WD of the fourth region 66D. The width dimension WB of the second region 66B is equal to the width dimension WC of the third region 66C.

Furthermore, each of the width dimension WA of the first region 66A, the width dimension WB of the second region 66B, the width dimension WC of the third region 66C, and the width dimension WD of the fourth region 66D may be arbitrarily changed. In one example, the width dimension WA of the first region 66A may be equal to the width dimension WC of the third region 66C. In one example, the width dimension WD of the fourth region 66D may be equal to the width dimension WB of the second region 66B. The width dimension WD of the fourth region 66D may differ from the width dimension WA of the first region 66A.

The fourth region 66D is provided with the fourth reverse pin junction portion 60D. The fourth reverse pin junction portion 60D is located side by side with the fourth pin junction portion 130 in the Y direction. The fourth reverse pin junction portion 60D is disposed to be shifted relative to the third reverse pin junction portion 60C in the Y direction. The fourth reverse pin junction portion 60D includes a portion overlapping the third reverse pin junction portion 60C when viewed from the X direction.

As shown in FIG. 51, the fourth inverse pin junction portion 60D includes the fourth low-concentration region 62D and the fourth contact region 63D. The configurations of the fourth low-concentration region 62D and the fourth contact region 63D are similar to those of the third low-concentration region 62C and the third contact region 63C, for example. In the fourth inverse pin junction portion 60D, the p-type fourth contact region 63D forms the P layer of the pin diode, the n-type fourth low-concentration region 62D forms the I layer of the pin diode, and the n-type high-concentration region 61 forms the N layer of the pin diode. That is, the fourth contact region 63D, the fourth low-concentration region 62D, and the high-concentration region 61 form a pin junction in the Z direction. Therefore, in the fourth inverse pin junction portion 60D, a pin diode (diode 209) of the second polarity direction is formed of the high-concentration region 61, the fourth low-concentration region 62D, and the fourth contact region 63D.

As indicated by the dashed line in FIG. 50, the outer edge of the internal region 64 is located inward from the outer edge of the high-concentration region 61 in the plan view. In one example, the internal region 64 has a rectangular shape that is slightly smaller than the high-concentration region 61 (diode pair region 60) in the plan view. Therefore, the internal region 64 is provided to overlap each of the inverse pin junction portions 60A, 60B, 60C, and 60D in the plan view. More specifically, the internal region 64 is provided to overlap each of the first low-concentration region 62A, the second low-concentration region 62B, the third low-concentration region 62C, and the fourth low-concentration region 62D in the plan view. The cross-sectional structure of the pn junction portion 60E is similar to that of the first embodiment.

As shown in FIG. 52, the TVS diode 10 of the seventh embodiment has a configuration in which the fourth connection electrode 84 is added to the TVS diode 10 of the first embodiment.

The fourth connection electrode 84 is disposed closer to the second side surface 20B than the center of the semiconductor chip 20 in the X direction in the plan view. The first connection electrode 81 extends along the Y direction. The fourth connection electrode 84 includes a pin connection portion 84A and a wiring portion 84B that extends in the Y direction from the pin connection portion 84A toward the fourth side surface 20D. In one example, the pin connection portion 84A and the wiring portion 84B are integrated.

The pin connection portion 84A is disposed to overlap the fourth pin junction portion 130 (refer to FIG. 50) in the plan view. The pin connection portion 84A is rectangular in the plan view. The pin connection portion 84A is disposed within the fourth-terminal-side low-concentration region 132 of the fourth pin junction portion 130 in the plan view. The pin connection portion 84A is slightly larger than the fourth-terminal-side contact region 133 of the fourth pin junction portion 130 in the plan view.

The wiring portion 84B is strip-shaped with a width in the X direction in the plan view. The width dimension of the wiring portion 84B is smaller than the X direction dimension of the pin connection portion 84A. The wiring portion 84B is disposed to be shifted in the X direction relative to the pin connection portion 84A. More specifically, a virtual line CL5 extended in the Y direction at the center of the width of the wiring portion 84B is positioned closer to the first side surface 20A than a virtual line CL6 extended in the Y direction at the center of the X direction of the pin connection portion 84A.

The wiring portion 84B is provided to cover the fourth contact region 63D of the fourth inverse pin junction portion 60D in the plan view. In one example, the wiring portion 84B covers the entirety of the fourth contact region 63D in the plan view. Therefore, the width dimension of the wiring portion 84B is larger than the width dimension of the fourth contact region 63D. On the other hand, the width dimension of the wiring portion 84B is smaller than the width dimension of the fourth low-concentration region 62D. The front end portion of the wiring portion 84B is curved in the plan view.

A reverse pin connection portion 84C is provided at a position of the wiring portion 84B overlapping the fourth contact region 63D. The reverse pin connection portion 84C is connected to the fourth contact region 63D. In one example, the configuration of the fourth connection electrode 84 is similar to that of the first connection electrode 81.

As shown in FIG. 51, the fourth connection electrode 84 electrically connects the fourth-terminal-side contact region 133 of the fourth pin junction portion 130 with the fourth contact region 63D of the fourth reverse pin junction portion 60D. The fourth connection electrode 84 is in contact with the fourth-terminal-side contact region 133 through the seventh opening portion 73H of the insulating layer 70. The fourth connection electrode 84 is in contact with the fourth contact region 63D through the eighth opening portion 73J of the insulating layer 70.

As shown in FIG. 52, due to the provision of the fourth connection electrode 84, the shape of the third connection electrode 83 differs from that of the first embodiment. In the seventh embodiment, the configuration of the third connection electrode 83 is similar to that of the second connection electrode 82. That is, the center of the wiring portion 83B of the third connection electrode 83 in the X direction is at the same position as the center of the pin connection portion 83A in the X direction.

The wiring 90 includes a fourth region 98, a third connection region 99, and a fourth recess 96D.

The fourth region 98 is provided to overlap the fourth region 66D of the diode pair region 60 in the plan view (refer to FIG. 50). The portions of the outer peripheral edge of the fourth region 98 corresponding to the first side 66DA, the second side 66DB, and the fourth side 66DD of the fourth region 66D (refer to FIG. 50 together) are provided to overlap the first side 66DA, the second side 66DB, and the fourth side 66DD in the plan view.

The fourth recess 96D is provided to avoid the fourth connection electrode 84 in the plan view. The fourth recess 96D opens toward the third side surface 20C. As a result, the fourth region 98 is provided to partially surround the fourth connection electrode 84 in the plan view. Additionally, the fourth recess 96D is provided to avoid the fourth low-concentration region 62D of the fourth region 66D of the diode pair 60 (high-concentration region 61) in the plan view (refer to FIG. 50 together). Therefore, the fourth region 98 is provided to surround the fourth low-concentration region 62D in the plan view.

By providing the fourth recess 96D, it can be said that the fourth region 98 is partially connected to the separation region 65 in the fourth region 66D. More specifically, as shown in FIG. 50, the separation region 65 in the fourth region 66D includes the wiring connection region 65P where the wiring 90 is connected and the fourth separation region 65D that overlaps the fourth connection electrode 84 in the plan view. The fourth separation region 65D is provided at the end closer to the fourth pin junction portion 130 among both ends of the fourth region 66D in the Y direction. The fourth separation region 65D is the region of the fourth region 66D between the fourth low-concentration region 62D and the third side 66DC in the plan view. The wiring connection region 65P is provided to partially surround the fourth low-concentration region 62D in the plan view. That is, the wiring connection region 65P is provided to partially surround the fourth reverse pin junction portion 60D in the plan view. Therefore, the fourth region 98 connected to the wiring connection region 65P (refer to FIG. 51) is provided to partially surround the fourth reverse pin junction portion 60D in the plan view.

As shown in FIG. 52, the third connection region 99 is provided to overlap the third connection region 67C of the diode pair region 60 in the plan view (refer to FIG. 51). The shape and size of the third connection region 99 are the same as those of the first connection region 67A. The third connection region 99 is connected across the entire area of the third connection region 67C. In other words, the third connection region 67C is formed of the wiring connection region 65P.

As shown in FIG. 53, the TVS diode 10 of the seventh embodiment has a configuration in which a fourth terminal opening portion 77D has been added to the TVS diode 10 of the first embodiment. The arrangement and configuration of the first to third terminal opening portions 77A to 77C are similar to the first embodiment.

The fourth terminal opening portion 77D is disposed to be shifted in both the X direction and the Y direction relative to the third terminal opening portion 77C in the plan view. Specifically, the fourth terminal opening portion 77D is disposed closer to the second side surface 20B and the third side surface 20C than the third terminal opening portion 77C in the plan view. In one example, the fourth terminal opening portion 77D is disposed at the same position in the Y direction as the second terminal opening portion 77B.

As shown in FIG. 51, the fourth terminal opening portion 77D exposes the pin connection portion 84A of the fourth connection electrode 84, similar to the first to third terminal opening portions 77A to 77C. The fourth terminal opening portion 77D is disposed at a position overlapping the fourth-terminal-side contact region 133 in the plan view. Furthermore, according to the TVS diode 10 of the seventh embodiment, effects similar to those of the first embodiment can be obtained.

### Eighth Embodiment

Referring to FIG. 54 to FIG. 56, the TVS diode 10 of the eighth embodiment is described. The TVS diode 10 of the eighth embodiment mainly differs from that of the TVS diode 10 of the seventh embodiment in the planar structure of the TVS diode 10. In the following, common components with the seventh embodiment are denoted by the same reference numerals, and their descriptions are omitted.

As shown in FIG. 54, in the TVS diode 10 of the eighth embodiment, the first pin junction portion 30, the second pin junction portion 40, the third pin junction portion 50, and the fourth pin junction portion 130 are disposed at the four corner portions of the first surface 20S of the semiconductor chip 20 in the plan view. The first pin junction portion 30 is disposed at a corner portion of the first surface 20S of the semiconductor chip 20 close to the first side surface 20A and the fourth side surface 20D. The second pin junction portion 40 is disposed at a corner portion of the first surface 20S of the semiconductor chip 20 close to the first side surface 20A and the third side surface 20C. The third pin junction portion 50 is disposed at a corner portion of the first surface 20S of the semiconductor chip 20 close to the second side surface 20B and the fourth side surface 20D. The fourth pin junction portion 130 is disposed at a corner portion of the first surface 20S of the semiconductor chip 20 close to the second side surface 20B and the third side surface 20C. The cross-sectional structure of each of the first pin junction portion 30, the second pin junction portion 40, the third pin junction portion 50, and the fourth pin junction portion 130 is similar to that of the seventh embodiment.

The diode pair region 60 (high-concentration region 61) is cross-shaped in the plan view. The diode pair region 60 includes the first to fourth regions 66A to 66D and the first to fourth reverse pin junction portions 60A to 60D, similar to the seventh embodiment.

The first region 66A is the region where the first reverse pin junction portion 60A is provided. The first region 66A includes a portion located between the first pin junction portion 30 and the second pin junction portion 40 in the Y direction. In other words, the first pin junction portion 30 and the second pin junction portion 40 are disposed facing each other with the first region 66A in between. Additionally, the first reverse pin junction portion 60A includes a portion located between the first pin junction portion 30 and the second pin junction portion 40 in the Y direction.

Both the first low-concentration region 62A and the first contact region 63A of the first reverse pin junction portion 60A have substantially rectangular shapes with the longitudinal direction in the X direction and the lateral direction in the Y direction in the plan view. In one example, when viewed from the Y direction, both the first low-concentration region 62A and the first contact region 63A include a region that extend beyond the first pin junction portion 30 and the second pin junction portion 40.

The second region 66B is the region where the second reverse pin junction portion 60B is provided. The second region 66B includes a portion located between the second pin junction portion 40 and the fourth pin junction portion 130 in the X direction. In other words, the second pin junction portion 40 and the fourth pin junction portion 130 are disposed facing each other with the second region 66B in between. Additionally, the second reverse pin junction portion 60B includes a portion located between the second pin junction portion 40 and the fourth pin junction portion 130 in the X direction.

Both the second low-concentration region 62B and the second contact region 63B of the second reverse pin junction portion 60B have substantially rectangular shapes with the lateral direction in the X direction and the longitudinal direction in the Y direction in the plan view. In one example, when viewed from the X direction, both the second low-concentration region 62B and the second contact region 63B include a region that extend beyond the second pin junction portion 40 and the fourth pin junction portion 130.

The third region 66C is the region where the third reverse pin junction portion 60C is provided. The third region 66C includes a portion located between the first pin junction portion 30 and the third pin junction portion 50 in the X direction. In other words, the first pin junction portion 30 and the third pin junction portion 50 are disposed facing each other with the third region 66C in between. Additionally, the third reverse pin junction portion 60C includes a portion located between the first pin junction portion 30 and the third pin junction portion 50 in the X direction.

Both the third low-concentration region 62C and the third contact region 63C of the third reverse pin junction portion 60C have substantially rectangular shapes with the lateral direction in the X direction and the longitudinal direction in the Y direction in the plan view. In one example, when viewed from the X direction, both the third low-concentration region 62C and the third contact region 63C include a region that extend beyond the first pin junction portion 30 and the third pin junction portion 50.

The fourth region 66D is the region where the fourth reverse pin junction portion 60D is provided. The fourth region 66D includes a portion located between the third pin junction portion 50 and the fourth pin junction portion 130 in the Y direction. In other words, the third pin junction portion 50 and the fourth pin junction portion 130 are disposed facing each other with the fourth region 66D in between. Additionally, the fourth reverse pin junction portion 60D includes a portion located between the third pin junction portion 50 and the fourth pin junction portion 130 in the Y direction.

Both the fourth low-concentration region 62D and the fourth contact region 63D of the fourth reverse pin junction portion 60D have substantially rectangular shapes with the longitudinal direction in the X direction and the lateral direction in the Y direction in the plan view. In one example, when viewed from the Y direction, both the fourth low-concentration region 62D and the fourth contact region 63D include a region that extend beyond the third pin junction portion 50 and the fourth pin junction portion 130.

Each of the regions of the diode pair region 60 (high-concentration region 61) connecting the first region 66A and the second region 66B, connecting the first region 66A and the third region 66C, connecting the second region 66B and the fourth region 66D, and connecting the third region 66C and the fourth region 66D is curved in the plan view. Additionally, the corner portions of each of the first to fourth regions 66A to 66D are curved in the plan view. The radius of curvature of each of the region connecting the first region 66A and the second region 66B, the region connecting the first region 66A and the third region 66C, the region connecting the second region 66B and the fourth region 66D, and the region connecting the third region 66C and the fourth region 66D is larger than the radius of curvature of the corner portions of each of the first to fourth regions 66A to 66D.

As indicated by the dashed line in FIG. 54, the outer edge of the internal region 64 is located inward relative to the outer edge of the high-concentration region 61 in the plan view. In one example, the internal region 64 has a rectangular shape that is slightly smaller than the high-concentration region 61 (diode pair region 60) in the plan view. Therefore, the internal region 64 is provided to overlap each of the reverse pin junction portions 60A, 60B, 60C, and 60D in the plan view. More specifically, the internal region 64 is provided to overlap each of the first low-concentration region 62A, the second low-concentration region 62B, the third low-concentration region 62C, and the fourth low-concentration region 62D in the plan view. The cross-sectional structure of the pn junction portion 60E (refer to FIG. 2) is similar to that of the first embodiment.

As shown in FIG. 55, the shapes of the first to fourth connection electrodes 81 to 84 in the plan view in the eighth embodiment differ from those of the first to fourth connection electrodes 81 to 84 in the seventh embodiment.

The first connection electrode 81 includes a pin connection portion 81A, a wiring portion 81B, and a reverse pin connection portion 81C. The pin connection portion 81A covers the entire area of the first-terminal-side contact region 33 of the first pin junction portion 30 in the plan view. The pin connection portion 81A is in contact with the first-terminal-side contact region 33. The pin connection portion 81A is rectangular in the plan view. The wiring portion 81B extends along the Y direction from the pin connection portion 81A toward the third side surface 20C. The reverse pin connection portion 81C covers the entire area of the first contact region 63A of the first reverse pin junction portion 60A in the plan view. The reverse pin connection portion 81C is in contact with the first contact region 63A. The reverse pin connection portion 81C has a substantially rectangular shape with its longitudinal direction in the X direction and its lateral direction in the Y direction. Herein, in the eighth embodiment, the first to fourth connection electrodes 81 to 84 have the same shape as each other in the plan view. Therefore, detailed descriptions of the second to fourth connection electrodes 82 to 84 are omitted.

The shape in the plan view of the wiring 90 of the eighth embodiment differs from that of the wiring 90 of the seventh embodiment. The wiring 90 is provided to partially surround the first to fourth connection electrodes 81 to 84 individually. More specifically, the wiring 90 includes the first to fourth recesses 96A to 96D, similar to the seventh embodiment. The first recess 96A of the wiring 90 is provided to avoid the reverse pin connection portion 81C of the first connection electrode 81 in the plan view. The first recess 96A opens toward the pin connection portion 81A so that the wiring portion 81B can pass through. As a result, the wiring 90 is provided to partially surround the reverse pin connection portion 81C and the wiring portion 81B of the first connection electrode 81. The second recess 96B is provided to avoid the reverse pin connection portion 82C of the second connection electrode 82 in the plan view. The second recess 96B opens toward the pin connection portion 82A so that the wiring portion 82B can pass through. As a result, the wiring 90 is provided to partially surround the reverse pin connection portion 82C and the wiring portion 82B of the second connection electrode 82. The third recess 96C is provided to avoid the reverse pin connection portion 83C of the third connection electrode 83 in the plan view. The third recess 96C opens toward the pin connection portion 83A so that the wiring portion 83B can pass through. As a result, the wiring 90 is provided to partially surround the reverse pin connection portion 83C and the wiring portion 83B of the third connection electrode 83. The fourth recess 96D is provided to avoid the reverse pin connection portion 84C of the fourth connection electrode 84 in the plan view. The fourth recess 96D opens toward the pin connection portion 84A so that the wiring portion 84B can pass through. As a result, the wiring 90 is provided to partially surround the reverse pin connection portion 84C and the wiring portion 84B of the fourth connection electrode 84.

Additionally, the first recess 96A is provided to surround the first low-concentration region 62A (refer to FIG. 54) of the diode pair region 60 (high-concentration region 61) in the plan view. The second recess 96B is provided to surround the second low-concentration region 62B (refer to FIG. 54) in the plan view. The third recess 96C is provided to surround the third low-concentration region 62C (refer to FIG. 54) in the plan view. The fourth recess 96D is provided to surround the fourth low-concentration region 62D (refer to FIG. 54) in the plan view.

The wiring 90 is partially connected to the separation region 65 of the diode pair region 60 (high-concentration region 61). More specifically, as shown in FIG. 54, the separation region 65 includes the first to fourth separation regions 65A to 65D where wiring 90 is not connected, and the wiring connection region 65P where wiring 90 is connected. The first separation region 65A is a portion of the separation region 65 covered by the wiring portion 81B (refer to FIG. 55) in the region corresponding to the first region 66A. The second separation region 65B is a portion of the separation region 65 covered by the wiring portion 82B (refer to FIG. 55) in the region corresponding to the second region 66B. The third separation region 65C is a portion of the separation region 65 covered by the wiring portion 83B (refer to FIG. 55) in the region corresponding to the third region 66C. The fourth separation region 65D is a portion of the separation region 65 covered by the wiring portion 84B (refer to FIG. 55) in the region corresponding to the fourth region 66D. Thus, the wiring connection region 65P is provided to partially surround the first to fourth low-concentration regions 62A to 62D individually in the plan view. Therefore, the wiring 90 connected to the wiring connection region 65P is provided to partially surround the first to fourth low-concentration regions 62A to 62D individually in the plan view.

As shown in FIG. 56, the first to fourth terminal opening portions 77A to 77D of the TVS diode 10 of the eighth embodiment are disposed at the four corner portions of the first surface 20S of the semiconductor chip 20 in the plan view. The first terminal opening portion 77A is disposed at the corner portions of the first surface 20S of the semiconductor chip 20 close to the first side surface 20A and close to the fourth side surface 20D. The second terminal opening portion 77B is disposed at the corner portions of the first surface 20S of the semiconductor chip 20 close to the first side surface 20A and close to the third side surface 20C. The third terminal opening portion 77C is disposed at the corner portions of the first surface 20S of the semiconductor chip 20 close to the second side surface 20B and close to the fourth side surface 20D. The fourth terminal opening portion 77D is disposed at the corner portions of the first surface 20S of the semiconductor chip 20 close to the second side surface 20B and close to the third side surface 20C.

The first terminal opening portion 77A is disposed at a position overlapping the first-terminal-side contact region 33 (refer to FIG. 54) in the plan view. The second terminal opening portion 77B is disposed at a position overlapping the second-terminal-side contact region 43 (refer to FIG. 54) in the plan view. The third terminal opening portion 77C is disposed at a position overlapping the third-terminal-side contact region 53 (refer to FIG. 54) in the plan view. The fourth terminal opening portion 77D is disposed at a position overlapping the fourth-terminal-side contact region 133 (refer to FIG. 54) in the plan view. Furthermore, according to the TVS diode 10 of the eighth embodiment, effects similar to those of the first embodiment can be obtained.

### MODIFIED EXAMPLES

The above embodiments can be modified and implemented as follows. Additionally, the above embodiments and the following modified examples can be implemented in combination with each other to the extent that there is no technical contradiction.
The second and third embodiments can be combined with each other. That is, the first pin junction portion 30 may include the first buffer region 35 and the first separation trench structure 120A. The second pin junction portion 40 may include the second buffer region 45 and the second separation trench structure 120B. The third pin junction portion 50 may include the third buffer region 55 and the third separation trench structure 120C. In this case, the first partition region 34 may be omitted from the first pin junction portion 30. The second partition region 44 may be omitted from the second pin junction portion 40. The third partition region 54 may be omitted from the third pin junction portion 50.
In the fourth to eighth embodiments, at least one configuration of the second and third embodiments may be applied.
In the third embodiment, at least one of the first separation electrode 123A, the second separation electrode 123B, and the third separation electrode 123C may be omitted.
In the third embodiment, at least one of the first separation insulating layer 122A, the second separation insulating layer 122B, and the third separation insulating layer 122C may be omitted.
In the third embodiment, the size of the high-concentration region 61 may be arbitrarily changed. FIG. 57 shows the cross-sectional structure of the TVS diode 10 with a modified size of the high-concentration region 61. As shown in FIG. 57, the high-concentration region 61 may be expanded to a position adjacent to the first separation trench 121A and the second separation trench 121B. Furthermore, although not shown, the high-concentration region 61 may also be expanded to a position adjacent to the third separation trench 121C. With such an expansion of the high-concentration region 61, the internal region 64 may also be expanded. According to the modified TVS diode 10 shown in FIG. 57, the junction area between the high-concentration region 61 and the internal region 64 increases, thereby achieving the improvement in the surge absorption performance of the TVS diode 10.

Furthermore, in the modified example shown in FIG. 57, the high-concentration region 61 may be expanded, for example, to a position adjacent to the first separation trench 121A while being provided at a position spaced apart from the second separation trench 121B. In another example, the high-concentration region 61 may be expanded to a position adjacent to the second separation trench 121B while being provided at a position spaced apart from the first separation trench 121A.
In the second embodiment, the TVS diode 10 may have a configuration that includes the first pin junction portion 30 and a diode pair region 60 that includes the first reverse pin junction portion 60A and the pn junction portion 60E. That is, the second pin junction portion 40, the third pin junction portion 50, the second reverse pin junction portion 60B, and the third reverse pin junction portion 60C may be omitted from the TVS diode 10. FIG. 58 schematically shows the cross-sectional structure of the modified example of the TVS diode 10, which includes the first pin junction portion 30 and the diode pair region 60 that includes the first reverse pin junction portion 60A and the pn junction portion 60E.

As shown in FIG. 58, the outer edge of the internal region 64 in the diode pair region 60 is located inward from the outer edge of the high-concentration region 61 in the plan view. The outer edge of the internal region 64 is disposed at a position overlapping the separation region 65 in the plan view.

Although not shown, the high-concentration region 61 is rectangular in the plan view. The high-concentration region 61 includes four corner portions. Each corner portion of the high-concentration region 61 is curved in the plan view. In one example, the internal region 64 is rectangular in the plan view. The internal region 64 is slightly smaller than the high-concentration region 61 in the plan view. Therefore, the inner edge of the internal region 64 is located inward from the outer edge of the high-concentration region 61 in the plan view. The internal region 64 is provided at a position overlapping the first low-concentration region 62A in the plan view. The outer edge of the internal region 64 includes four corner portions. Each of the four corner portions is curved in the plan view.
In the first and third embodiments, the TVS diode 10 may include a configuration that includes the first pin junction portion 30 and the diode pair region 60 which includes the first reverse pin junction portion 60A and the pn junction portion 60E. That is, the second pin junction portion 40 and the third pin junction portion 50, as well as the second reverse pin junction portion 60B and the third reverse pin junction portion 60C may be omitted from the TVS diode 10.
In the second embodiment, the p-type impurity concentration in the first buffer region 35 may be arbitrarily changed. In one example, the p-type impurity concentration in the first buffer region 35 may be equal to or greater than the p-type impurity concentration in the first-terminal-side high-concentration region 31. In one example, the minimum value of the p-type impurity concentration in the first buffer region 35 may be less than the n-type impurity concentration in the first-terminal-side low-concentration region 32. Furthermore, the p-type impurity concentrations in the second buffer region 45 and the third buffer region 55 may also be changed in a similar manner.
In the second embodiment, the concentration gradient of the p-type impurity concentration in the first buffer region 35 may be arbitrarily changed. In one example, the p-type impurity concentration in the first buffer region 35 may be approximately constant in the Z direction. Furthermore, the p-type impurity concentrations of the second buffer region 45 and the third buffer region 55 may also be changed in a similar manner.
In the first to third and seventh embodiments, the shape of the diode pair region 60 (high-concentration region 61) in the plan view may be arbitrarily changed. In one example, the shape of the diode pair region 60 (high-concentration region 61) in the plan view may be rectangular.
In the second embodiment, the diode pair region 60 (high-concentration region 61) may be formed of a first diode pair region, a second diode pair region, and a third diode pair region that are disposed spaced apart from each other. The first diode pair region is provided with the first reverse pin junction portion 60A. The second diode pair region is provided with the second reverse pin junction portion 60B. The third diode pair region is provided with the third reverse pin junction portion 60C. In this case, the internal region 64 may be formed of a first internal region, a second internal region, and a third internal region that are disposed spaced apart from each other. The first internal region is in contact with the high-concentration region of the first diode pair region. The second internal region is in contact with the high-concentration region of the second diode pair region. The third internal region is in contact with the high-concentration region of the third diode pair region.
In each embodiment, the internal region 64 may be provided to overlap only one of the first low-concentration region 62A, the second low-concentration region 62B, and the third low-concentration region 62C in the plan view. In another example, the internal region 64 may be provided to overlap both the first low-concentration region 62A and the third low-concentration region 62C in the plan view, while not overlapping the second low-concentration region 62B. In another example, the internal region 64 may be provided to overlap both the second low-concentration region 62B and the third low-concentration region 62C in the plan view, while not overlapping the first low-concentration region 62A.
In the first to third, fifth, and seventh embodiments, the arrangement of the first pin junction portion 30, the second pin junction portion 40, the third pin junction portion 50, and the first to third reverse pin junction portions 60A to 60C can be arbitrarily changed. In one example, the first pin junction portion 30 and the first reverse pin junction portion 60A may not be located side by side in the Y direction in the plan view. In one example, the first pin junction portion 30 and the first reverse pin junction portion 60A may be disposed to be shifted in the X direction in the plan view. In one example, the second pin junction portion 40 and the second reverse pin junction portion 60B may not be located side by side in the Y direction in the plan view. In one example, the second pin junction portion 40 and the second reverse pin junction portion 60B may be disposed to be shifted in the X direction in the plan view. In one example, the third pin junction portion 50 and the third reverse pin junction portion 60C may not be located side by side in the Y direction in the plan view. In one example, the third pin junction portion 50 and the third reverse pin junction portion 60C may be disposed to be shifted in the X direction in the plan view.

In another example, the first pin junction portion 30 and the second reverse pin junction portion 60B may not be adjacent in the X direction in the plan view. In one example, when viewed from the X direction, the first pin junction portion 30 may be disposed to be shifted in the Y direction so as not to overlap the second reverse pin junction portion 60B. In another example, the third pin junction portion 50 and the second reverse pin junction portion 60B may not be adjacent in the X direction in the plan view. In one example, when viewed from the X direction, the third pin junction portion 50 may be disposed to be shifted in the Y direction so as not to overlap the second reverse pin junction portion 60B. In another example, the first reverse pin junction portion 60A and the second pin junction portion 40 may not be adjacent in the X direction in the plan view. In one example, when viewed from the X direction, the second pin junction portion 40 may be disposed to be shifted in the Y direction so as not to overlap the first reverse pin junction portion 60A. In another example, the third reverse pin junction portion 60C and the second pin junction portion 40 may not be adjacent in the X direction in the plan view. In one example, when viewed from the X direction, the second pin junction portion 40 may be disposed to be shifted in the Y direction so as not to overlap the third reverse pin junction portion 60C.
In the seventh embodiment, the fourth pin junction portion 130 and the fourth reverse pin junction portion 60D may not be located side by side in the Y direction in the plan view. In one example, the fourth pin junction portion 130 and the fourth reverse pin junction portion 60D may be disposed to be shifted in the X direction in the plan view.

In another example, the fourth pin junction portion 130 and the third reverse pin junction portion 60C may not be adjacent in the X direction in the plan view. In one example, when viewed from the X direction, the fourth pin junction portion 130 may be disposed to be shifted in the Y direction so as not to overlap the third reverse pin junction portion 60C. In another example, the fourth reverse pin junction portion 60D and the fourth pin junction portion 130 may not be adjacent in the X direction in the plan view. In one example, when viewed from the X direction, the third pin junction portion 50 may be disposed to be shifted in the Y direction so as not to overlap the fourth reverse pin junction portion 60D.
In each embodiment, the position of the outer edge of the internal region 64 in the plan view can be arbitrarily changed. In one example, the outer edge of the internal region 64 may be provided to overlap the outer edge of the high-concentration region 61 in the plan view. In one example, the outer edge of the internal region 64 may include portions that extend beyond the high-concentration region 61 in the plan view. In one example, at least a portion of the outer edge of the internal region 64 may be disposed at a position different from the separation region 65 in the plan view.
In each embodiment, at least one of the multiple corner portions at the outer edge of the internal region 64 may be formed at a right angle rather than curved in the plan view.
In each embodiment, the size and shape of the separation region 65 in the plan view can be arbitrarily changed. The separation region 65 may be provided around the entirety of an outer periphery portion of the high-concentration region 61. That is, the separation region 65 may not include portions surrounding the first reverse pin junction portion 60A in the plan view. The separation region 65 may not include portions surrounding the second reverse pin junction portion 60B in the plan view. The separation region 65 may not include portions surrounding the third reverse pin junction portion 60C in the plan view. The separation region 65 may not include portions surrounding the fourth reverse pin junction portion 60D in the plan view.
In each embodiment, the size of wiring 90 can be changed arbitrarily. In one example, the area of wiring 90 in the plan view may be less than 75% of the area of the separation region 65 in the plan view. In one example, the area of the wiring 90 in the plan view may be greater than 97% of the area of the separation region 65 in the plan view. In one example, the area of the wiring 90 in the plan view may be equal to or greater than the area of the separation region 65 in the plan view. In one example, the area of the wiring 90 in the plan view may be less than or equal to the area of the first connection electrode 81 in the plan view. The area of the wiring 90 in the plan view may be less than or equal to the area of the second connection electrode 82 in the plan view.
In the first to third embodiments, the shape of the wiring 90 in the plan view can be changed arbitrarily. In one example, the wiring 90 may not necessarily partially surround at least one of the first connection electrode 81 and the second connection electrode 82 in the plan view.
In the fourth embodiment, the shape of the wiring 90 in the plan view can be changed arbitrarily. In one example, the wiring 90 may be provided in a region overlapping an outer periphery portion of the separation region 65 in the plan view, and may not necessarily be provided in at least one of the regions between the first reverse pin junction portion 60A and the second reverse pin junction portion 60B and between the second reverse pin junction portion 60B and the third reverse pin junction portion 60C. In another example, the wiring 90 may be provided only between the first reverse pin junction portion 60A and the second reverse pin junction portion 60B, and between the second reverse pin junction portion 60B and the third reverse pin junction portion 60C.
In the fifth embodiment, the shape of the wiring 90 in the plan view can be changed arbitrarily. For example, the wiring 90 may be provided in a region overlapping an outer periphery portion of the separation region 65 in the plan view while not being provided at a portion overlapping the first connection region 67A. In another example, the wiring 90 may be provided only in the portion overlapping the first connection region 67A.
In the sixth embodiment, the shape of the wiring 90 in the plan view can be changed arbitrarily. In one example, the wiring 90 may be provided in a region overlapping an outer periphery portion of the separation region 65 in the plan view while not being provided between the first reverse pin junction portion 60A and the second reverse pin junction portion 60B. In another example, the wiring 90 may be provided only between the first reverse pin junction portion 60A and the second reverse pin junction portion 60B.
In the seventh embodiment, the shape of the wiring 90 in the plan view can be changed arbitrarily. In one example, the wiring 90 may be provided in a region overlapping an outer periphery portion of the separation region 65 in the plan view while not being provided in at least one of the regions overlapping the first to third connection regions 67A to 67C. In another example, the wiring 90 may be provided only in the regions overlapping the first to third connection regions 67A to 67C in the plan view. In another example, the wiring 90 may be provided only in the region overlapping the first connection region 67A and the region overlapping the second connection region 67B. In another example, the wiring 90 may be provided only in the region overlapping the second connection region 67B and the region overlapping the third connection region 67C. In another example, the wiring 90 may be provided only in the region overlapping the first connection region 67A and the region overlapping the third connection region 67C. In another example, the wiring 90 may be provided only in any one of the regions overlapping the first to third connection regions 67A to 67C.
In the eighth embodiment, the wiring 90 may be provided in a region overlapping an outer periphery portion of the separation region 65 in the plan view while not being provided in the center of the separation region 65. In another example, the wiring 90 may be provided only in the center of the separation region 65.
In each embodiment, the wiring 90 may be omitted from the TVS diode 10. FIG. 59 schematically shows a planar structure with the wiring 90 omitted from the TVS diode 10 of the first embodiment. FIG. 60 schematically shows a cross-sectional structure obtained by cutting the TVS diode 10 along line F60-F60 in FIG. 59. As shown in FIG. 59, a protective layer 74 is provided between the first to third connection electrodes 81 to 83. Therefore, as shown in FIG. 60, the separation region 65 of the diode pair region 60 is covered by the insulating layer 70. The separation region 65 is in contact with the insulating layer 70.
In each embodiment, a structure in which the conductivity types in the semiconductor chip 20 are reversed may be adopted. That is, the p-type region may be made into an n-type region, and the n-type region may be made into a p-type region. In this case, the p-type becomes an example of the “first conductivity type,” and the n-type becomes an example of the “second conductivity type.”
The TVS diode 10 may include a configuration including, for example, the first pin junction portion 30 and the diode pair region 60 including the first reverse pin junction portion 60A and the pn junction portion 60E, and excluding the second pin junction portion 40, the third pin junction portion 50, the fourth pin junction portion 130, the second reverse pin junction portion 60B, the third reverse pin junction portion 60C, and the fourth reverse pin junction portion 60D, as long as the outer edge of the internal region 64 is located inward from the outer edge of the high-concentration region 61 in the plan view.
In each embodiment, the TVS diode 10 may include terminals for mounting the TVS diode 10 on, for example, a circuit board. An example of the TVS diode 10 including terminals is shown in FIG. 61 to FIG. 63. FIG. 61 schematically shows the planar structure of the modified TVS diode 10. FIG. 62 schematically shows a cross-sectional structure obtained by cutting the TVS diode 10 along line F62-F62 in FIG. 61. FIG. 63 schematically shows a cross-sectional structure obtained by cutting the TVS diode 10 along line F63-F63 in FIG. 61.

As shown in FIG. 61 to FIG. 63, the TVS diode 10 includes a first terminal 101, a second terminal 102, and a third terminal 103 provided on the protective layer 74.

As shown in FIG. 61, the first terminal 101, the second terminal 102, and the third terminal 103 are disposed spaced apart from each other. More specifically, the first terminal 101 and the third terminal 103 are disposed at the same position as each other in the Y direction and spaced apart from each other in the X direction. The first terminal 101 and the third terminal 103 are disposed closer to the fourth side surface 20D than the center of the first surface 20S of the semiconductor chip 20 in the Y direction. The first terminal 101 is disposed closer to the first side surface 20A than the center of the first surface 20S in the X direction. The third terminal 103 is disposed closer to the second side surface 20B than the center of the first surface 20S in the X direction.

The second terminal 102 is disposed at different positions in the X and Y directions relative to both the first terminal 101 and the third terminal 103. The second terminal 102 is disposed closer to the third side surface 20C than the center of the first surface 20S in the Y direction of the semiconductor chip 20. The second terminal 102 is disposed at the center of the first surface 20S in the X direction. Therefore, it can be said that the second terminal 102 is disposed between the first terminal 101 and the third terminal 103 in the X direction when viewed from the Y direction.

As shown in FIG. 62 and FIG. 63, the first terminal 101 is provided at a position overlapping the first pin junction portion 30 in the plan view. The second terminal 102 is provided at a position overlapping the second pin junction portion 40 in the plan view. The third terminal 103 is provided at a position overlapping the third pin junction portion 50 in the plan view.

The first terminal 101 is provided at a position overlapping the pin connection portion 81A of the first connection electrode 81 in the plan view. The second terminal 102 is provided at a position overlapping the pin connection portion 82A of the second connection electrode 82 in the plan view. The third terminal 103 is provided at a position overlapping the pin connection portion 83A of the third connection electrode 83 in the plan view.

The first terminal 101 is electrically connected to the first connection electrode 81 through the first terminal opening portion 77A. The first terminal 101 is provided within the first terminal opening portion 77A and includes a first contact portion 101A that contacts the first connection electrode 81, and a first mounting portion 101B provided on the protective layer 74. In one example, the first contact portion 101A and the first mounting portion 101B are integrated.

The second terminal 102 is electrically connected to the second connection electrode 82 through the second terminal opening portion 77B. The second terminal 102 is provided within the second terminal opening portion 77B and includes a second contact portion 102A that contacts the second connection electrode 82, and a second mounting portion 102B provided on the protective layer 74. In one example, the second contact portion 102A and the second mounting portion 102B are integrated.

The third terminal 103 is electrically connected to the third connection electrode 83 through the third terminal opening portion 77C. The third terminal 103 is provided within the third terminal opening portion 77C and includes a third contact portion 103A that contacts the third connection electrode 83, and a third mounting portion 103B provided on the protective layer 74. In one example, the third contact portion 103A and the third mounting portion 103B are integrated.

Each of the first to third terminals 101 to 103 comprises a laminated structure that includes, for example, a Ni (nickel) layer, a Pd (palladium) layer, and an Au (gold) layer laminated in this order from the first surface 20S side of the semiconductor chip 20.

Furthermore, in the fifth and sixth embodiments, the TVS diode 10 may include the first terminal 101 and the second terminal 102, similar to the examples shown in FIGS. 61 to 63. Furthermore, in the seventh and eighth embodiments, the TVS diode 10 may include the first terminal 101, the second terminal 102, the third terminal 103, and a fourth terminal, similar to the examples shown in FIGS. 61 to 63.

One or more of the various examples described in this disclosure can be combined to the extent that there is no technical contradiction.

The term “on” used in this disclosure includes the meanings of “on” and “above,” unless it is clearly indicated otherwise by the context. Therefore, for example, the expression “the first element is disposed on the second element” intends that in some embodiments, the first element may be directly disposed on the second element in contact with the second element, while in other embodiments, the first element may be disposed above the second element without contacting the second element. That is, the term “on” does not exclude the structure where other elements are formed between the first element and the second element.

The Z direction used in this disclosure does not necessarily have to be the vertical direction, nor does it have to be completely aligned with the vertical direction. Therefore, the various structures according to the present disclosure are not limited to the “up” and “down” in the Z direction described in this disclosure being the “up” and “down” in the vertical direction. For example, the X direction may be vertical, or the Y direction may be vertical.

### APPENDIX

The technical ideas that can be understood from this disclosure are described below. Furthermore, the components described in the appendix are referenced with reference numerals corresponding to the components in the above embodiments for the ease of understanding, but not for the purpose of limitation. The reference numerals are shown as examples for the ease of understanding, and the components described in each appendix should not be limited to those indicated by the reference numerals.

### Appendix A1

A TVS diode (10) including a semiconductor chip (20) that comprises a first surface (20S) and a second surface (20R) opposite to the first surface (20S),
wherein the semiconductor chip (20) includes:
a first pin junction portion (30) of a first polarity direction provided close to the first surface (20S),
a second pin junction portion (40) of the first polarity direction disposed at a position spaced apart from the first pin junction portion (30) in a plan view when viewed from a thickness direction (Z) of the semiconductor chip (20) in a region close to the first surface (20S) of the semiconductor chip (20), and
a diode pair region (60) provided spaced apart from both the first pin junction portion (30) and the second pin junction portion (40) in the plan view,
the diode pair region (60) includes:
a high-concentration region 61 of a first conductivity type provided spaced apart from the first surface (20S) toward the second surface (20R) of the semiconductor chip (20),
a first low-concentration region (62A) and a second low-concentration region (62B) of the first conductivity type provided spaced apart from each other at a position overlapping the high-concentration region (61) in the plan view in a region closer to the first surface (20S) than the high-concentration region (61), and having an impurity concentration lower than that of the high-concentration region (61),
a separation region (65) provided at a position overlapping the high-concentration region (61) in the plan view in a region closer to the first surface (20S) than the high-concentration region (61) and separating the first low-concentration region (62A) from the second low-concentration region (62B),
a first contact region (63A) of a second conductivity type provided in a surface layer portion of the first low-concentration region (62A),
a second contact region (63B) of the second conductivity type provided in a surface layer portion of the second low-concentration region (62B), and
an internal region (64) of the second conductivity type in contact with the high-concentration region (61) at a position overlapping the high-concentration region (61) in the plan view and closer to the second surface (20R) than the high-concentration region (61),
wherein the first reverse pin junction portion (60A) of the second polarity direction is formed of the high-concentration region (61), the first low-concentration region (62A), and the first contact region (63A),
the second reverse pin junction portion (60B) of the second polarity direction is formed of the high-concentration region (61), the second low-concentration region (62B), and the second contact region (63B),
a pn junction portion (60E) of the first polarity direction, which is connected in the reverse direction to the first reverse pin junction portion (60A) and the second reverse pin junction portion (60B), is formed of the high-concentration region (61) and the internal region (64), and
the internal region (64) is provided to overlap both the first low-concentration region (62A) and the second low-concentration region (62B) in the plan view.

### Appendix A2

The TVS diode according to appendix A1, wherein the first polarity direction is a direction in which a forward current flows from the second surface (20R) to the first surface (20S) in the thickness direction (Z) of the semiconductor chip (20), and
the second polarity direction is a direction in which a forward current flows in the thickness direction (Z) of the semiconductor chip (20) in a direction opposite to the first polarity direction.

### Appendix A3

The TVS diode according to appendix A1 or A2, wherein the separation region (65) includes an exposed surface (65S) exposed from the first surface (20S), and
includes a wiring (90) in contact with the exposed surface (65S).

### Appendix A4

The TVS diode according to appendix A3, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region closer to the first surface (20S) than the first-terminal-side high-concentration region (31);
a second-terminal-side high-concentration region (41) of the second conductivity type provided at a position spaced apart from the first-terminal-side high-concentration region (31) in the plan view and spaced apart from the first surface (20S) toward the second surface (20R) of the semiconductor chip (20);
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42); and
a second partition region (44) provided to surround the second-terminal-side low-concentration region (42) at a position overlapping the second-terminal-side high-concentration region (41) in the plan view in a region closer to the first surface (20S) than the second-terminal-side high-concentration region (41),
wherein the first-terminal-side high-concentration region (31), the first-terminal-side low-concentration region (32), and the first-terminal-side contact region (33) form the first pin junction portion (30), and
the second-terminal-side high-concentration region (41), the second-terminal-side low-concentration region (42), and the second-terminal-side contact region (43) form the second pin junction portion (40).

### Appendix A5

The TVS diode according to appendix A4 including:
an insulating layer (70) covering the first surface (20S);
a first connection electrode (81) provided on the insulating layer (70) and connecting the first contact region (63A) and the first-terminal-side contact region (33); and
a second connection electrode (82) provided on the insulating layer (70) connecting the second contact region (63B) and the second-terminal-side contact region (43).

### Appendix A6

The TVS diode according to appendix A5, wherein the separation region (65) includes:
a first separation region (65A) overlapping the first connection electrode (81) in the plan view;
a second separation region (65B) overlapping the second connection electrode (82) in the plan view; and
a wiring connection region (65P) where wiring (90) is connected,
wherein the wiring connection region (65P) is provided to partially surround both the first reverse pin junction portion (60A) and the second reverse pin junction portion (60B) individually in the plan view.

### Appendix A7

The TVS diode according to appendix A6, wherein the wiring (90) is provided to partially surround both the first connection electrode (81) and the second connection electrode (82) individually in the plan view.

### Appendix A8

The TVS diode according to appendix A6 or A7, wherein an area of the wiring (90) in the plan view is larger than an area of the first connection electrode (81) in the plan view.

### Appendix A9

The TVS diode according to any one of Appendices A5 to A8, wherein an area of the wiring (90) in the plan view is smaller than an area of the separation region (65) in the plan view.

### Appendix A10

The TVS diode according to appendix A9, wherein the area of the wiring (90) in the plan view is 75% or more and 97% or less of the area of the separation region (65) in the plan view.

### Appendix A11

The TVS diode according to any one of Appendices A5 to A10 including:
a protective layer (74) covering the first connection electrode (81) and the second connection electrode (82);
a first terminal (101) provided on the protective layer (74) and electrically connected to the first pin junction portion (30); and
a second terminal (102) provided on the protective layer (74) and electrically connected to the second pin junction portion (40),
wherein the protective layer (74) includes:
a first terminal opening portion (77A) partially exposing the first connection electrode (81); and
a second terminal opening portion (77B) partially exposing the second connection electrode (82),
wherein the first terminal (101) is electrically connected to the first connection electrode (81) through the first terminal opening portion (77A), and
the second terminal (102) is electrically connected to the second connection electrode (82) through the second terminal opening portion (77B).

### Appendix A12

The TVS diode according to any one of Appendices A1 to A11, wherein an outer edge of the internal region (64) is positioned inward from an outer edge of the high-concentration region (61) in the plan view.

### Appendix A13

The TVS diode according to Appendix A12, wherein in the plan view, the outer edge of the internal region (64) includes a plurality of corner portions, and
each of the corner portions is curved in the plan view.

### Appendix A14

The TVS diode according to Appendix A12 or A13, wherein the outer edge of the internal region (64) is disposed at a position overlapping the separation region (65) in the plan view.

### Appendix A15

The TVS diode according to any one of Appendices A1 to A3, wherein the semiconductor chip (20) includes:
a first-terminal-side high-concentration region (31) of the second conductivity type, provided spaced apart from the first surface (20S) toward the second surface (20R) of the semiconductor chip (20);
a first-terminal-side low-concentration region (32) of the first conductivity type, provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first separation trench (121A) provided on the first surface (20S) to surround the first-terminal-side high-concentration region (31), the first-terminal-side low-concentration region (32), and the first-terminal-side contact region (33);
a second-terminal-side high-concentration region (41) of the second conductivity type located spaced apart from the first surface (20S) toward the second surface (20R) of the semiconductor chip (20) and provided spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42); and
a second separation trench (121B) provided on the first surface (20S) to surround the second-terminal-side high-concentration region (41), the second-terminal-side low-concentration region (42), and the second-terminal-side contact region (43),
wherein the first pin junction portion (30) is formed of the first-terminal-side high-concentration region (31), the first-terminal-side low-concentration region (32), and the first-terminal-side contact region (33), and
the second pin junction portion (40) is formed of the second-terminal-side high-concentration region (41), the second-terminal-side low-concentration region (42), and the second-terminal-side contact region (43).

### Appendix A16

The TVS diode according to Appendix A15, wherein the semiconductor chip (20) includes:
a first separation insulating layer (122A) provided in the first separation trench (121A); and
a second separation insulating layer (122B) provided in the second separation trench (121B).

### Appendix A17

The TVS diode according to Appendix A16 including:
a first separation electrode (123A) embedded in the first separation trench (121A) with the first separation insulating layer (122A) in between; and
the second separation electrode (123B) embedded in the second separation trench (121B) with the second separation insulating layer (122B) in between,
wherein both the first separation electrode (123A) and the second separation electrode (123B) are in an electrically floating state.

### Appendix A18

The TVS diode according to any one of Appendices A15 to A17, wherein the high-concentration region (61) includes a region adjacent to at least one of the first separation trench (121A) and the second separation trench (121B) in the plan view.

### Appendix A19

The TVS diode according to any one of Appendices A1 to A3, wherein the semiconductor chip (20) includes a third pin junction portion (50) of the first polarity direction disposed at a position spaced apart from both the first pin junction portion (30) and the second pin junction portion (40) in the plan view in a region close to the first surface (20S) of the semiconductor chip (20),
the diode pair region (60) includes:
a third low-concentration region (62C) of the first conductivity type having a lower impurity concentration than the high-concentration region (61) and provided spaced apart from both the first low-concentration region (62A) and the second low-concentration region (62B) at a position overlapping the high-concentration region (61) in the plan view in a region closer to the first surface (20S) and the high-concentration region (61); and
a third contact region (63C) of the second conductivity type provided in a surface layer portion of the third low-concentration region (62C),
wherein the separation region (65) separates the first low-concentration region (62A) and the second low-concentration region (62B) from the third low-concentration region (62C),
the high-concentration region (61), the third low-concentration region (62C), and the third contact region (63C) form a third reverse pin junction portion (60C) of the second polarity direction,
the pn junction portion (60E) is configured to be connected in a reverse direction to the third reverse pin junction portion (60C), and
the internal region (64) is provided to overlap the first low-concentration region (62A), the second low-concentration region (62B), and the third low-concentration region (62C) in the plan view.

### Appendix A20

The TVS diode according to Appendix A19, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region closer to the first surface (20S) than the first-terminal-side high-concentration region (31);
a second-terminal-side high-concentration region (41) of the second conductivity type located at a position spaced apart from the first surface (20S) toward the second surface (20R) and provided spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42);
a second partition region (44) provided to surround the second-terminal-side low-concentration region (42) at a position overlapping the second-terminal-side high-concentration region (41) in the plan view in a region closer to the first surface (20S) than the second-terminal-side high-concentration region (41);
a third-terminal-side high-concentration region (51) of the second conductivity type located at a position spaced apart from the first surface (20S) toward the second surface (20R) and provided spaced apart from both the first-terminal-side high-concentration region (31) and the second-terminal-side high-concentration region (41) in the plan view;
a third-terminal-side low-concentration region (52) of the first conductivity type provided at a position overlapping the third-terminal-side high-concentration region (51) in the plan view in a region closer to the first surface (20S) than the third-terminal-side high-concentration region (51);
a third-terminal-side contact region (53) of the first conductivity type provided in the surface layer portion of the third-terminal-side low-concentration region (52); and
a third partition region (54) provided to surround the third-terminal-side low-concentration region (52) at a position overlapping the third-terminal-side high-concentration region (51) in the plan view in a region closer to the first surface (20S) than the third-terminal-side high-concentration region (51),
wherein the first-terminal-side high-concentration region (31), the first-terminal-side low-concentration region (32), and the first-terminal-side contact region (33) form the first pin junction portion (30),
the second-terminal-side high-concentration region (41), the second-terminal-side low-concentration region (42), and the second-terminal-side contact region (43) form the second pin junction portion (40), and
the third-terminal-side high-concentration region (51), the third-terminal-side low-concentration region (52), and the third-terminal-side contact region (53) form the third pin junction portion (50).

### Appendix A21

The TVS diode according to Appendix A20 including:
an insulating layer (70) covering the first surface (20S);
a first connection electrode (81) provided on the insulating layer (70) and connecting the first contact region (63A) and the first-terminal-side contact region (33);
a second connection electrode (82) provided on the insulating layer (70) and connecting the second contact region (63B) and the second-terminal-side contact region (43); and
a third connection electrode (83) provided on the insulating layer (70) and connecting the third contact region (63C) and the third-terminal-side contact region (53).

### Appendix A22

The TVS diode according to Appendix A21, wherein the separation region (65) includes an exposed surface (65S) exposed from the first surface (20S), and
includes a wiring (90) contacting the exposed surface (65S),
wherein the separation region (65) includes:
a first separation region (65A) overlapping the first connection electrode (81) in the plan view;
a second separation region (65B) overlapping the second connection electrode (82) in the plan view;
a third separation region (65C) overlapping the third connection electrode (83) in the plan view; and
a wiring connection region (65P) where the wiring (90) is connected,
wherein the wiring connection region (65P) is provided to partially surround each of the first reverse pin junction portion (60A), the second reverse pin junction portion (60B), and the third reverse pin junction portion (60C) individually in the plan view.

### Appendix A23

The TVS diode according to Appendix A22, wherein the wiring (90) is provided to partially surround each of the first connection electrode (81), the second connection electrode (82), and the third connection electrode (83) individually in the plan view.

### Appendix A24

The TVS diode according to Appendix A19, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first separation trench (121A) provided on the first surface (20S) to surround the first-terminal-side high-concentration region (31), the first-terminal-side low-concentration region (32), and the first-terminal-side contact region (33);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42);
a second separation trench (121B) provided on the first surface (20S) to surround the second-terminal-side high-concentration region (41), the second-terminal-side low-concentration region (42), and the second-terminal-side contact region (43);
a third-terminal-side high-concentration region (51) of the second conductivity type provided at a position spaced apart from the first surface (20S) toward the second surface (20R) of the semiconductor chip (20) and separated from both the first-terminal-side high-concentration region (31) and the second-terminal-side high-concentration region (41) in the plan view;
a third-terminal-side low-concentration region (52) of the first conductivity type provided at a position overlapping the third-terminal-side high-concentration region (51) in the plan view in a region closer to the first surface (20S) than the third-terminal-side high-concentration region (51);
a third-terminal-side contact region (53) of the first conductivity type provided in a surface layer portion of the third-terminal-side low-concentration region (52); and
a third separation trench (121C) provided on the first surface (20S) to surround the third-terminal-side high-concentration region (51), the third-terminal-side low-concentration region (52), and the third-terminal-side contact region (53),
wherein the first-terminal-side high-concentration region (31), the first-terminal-side low-concentration region (32), and the first-terminal-side contact region (33) form the first pin junction portion (30),
the second-terminal-side high-concentration region (41), the second-terminal-side low-concentration region (42), and the second-terminal-side contact region (43) form the second pin junction portion (40), and
the third-terminal-side high-concentration region (51), the third-terminal-side low-concentration region (52), and the third-terminal-side contact region (53) form the third pin junction portion (50).

### Appendix A25

The TVS diode according to Appendix A24, wherein the semiconductor chip (20) includes:
a first separation insulating layer (122A) provided in the first separation trench (121A);
a second separation insulating layer (122B) provided in the second separation trench (121B); and
a third separation insulating layer (122C) provided in the third separation trench (121C).

### Appendix A26

The TVS diode according to Appendix A25 includes
a first separation electrode (123A) embedded in the first separation trench (121A) with the first separation insulating layer (122A) in between;
a second separation electrode (123B) embedded in the second separation trench (121B) with the second separation insulating layer (122B) in between; and
a third separation electrode (123C) embedded in the third separation trench (121C) with the third separation insulating layer (122C) in between,
wherein each of the first separation electrode (123A), the second separation electrode (123B), and the third separation electrode (123C) is in an electrically floating state.

### Appendix A27

The TVS diode according to Appendix A19, wherein the semiconductor chip (20) includes a fourth pin junction portion (130) of the first polarity direction disposed spaced apart from each of the first pin junction portion (30), the second pin junction portion (40), and the third pin junction portion (50) in the plan view in a region close to the first surface (20S),
the diode pair region (60) includes:
a fourth low-concentration region (62D) of the first conductivity type provided spaced apart from each of the first low-concentration region (62A), the second low-concentration region (62B), and the third low-concentration region (62C) at a position overlapping the high-concentration region (61) in the plan view in a region closer to the first surface (20S) than the high-concentration region (61), and having a lower impurity concentration than the high-concentration region (61); and
a fourth contact region (63D) of the second conductivity type provided in a surface layer portion of the fourth low-concentration region (62D),
wherein the separation region (65) separates the first low-concentration region (62A), the second low-concentration region (62B), the third low-concentration region (62C), and the fourth low-concentration region (62D),
the high-concentration region (61), the fourth low-concentration region (62D), and the fourth contact region (63D) form a fourth reverse pin junction portion (60D) of the second polarity direction,
the pn junction portion (60E) is configured to be connected in the reverse direction to the fourth reverse pin junction portion (130), and
the internal region (64) is provided to overlap the first low-concentration region (62A), the second low-concentration region (62B), the third low-concentration region (62C), and the fourth low-concentration region (62D) in the plan view.

### Appendix A28

The TVS diode according to Appendix A27, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region closer to the first surface (20S) than the first-terminal-side high-concentration region (31);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42);
a second partition region (44) provided to surround the second-terminal-side low-concentration region (42) at a position overlapping the second-terminal-side high-concentration region (41) in the plan view in a region closer to the first surface (20S) than the second-terminal-side high-concentration region (41);
a third-terminal-side high-concentration region (51) of the second conductivity type provided at a position spaced apart from the first surface (20S) toward the second surface (20R) of the semiconductor chip (20) and spaced apart from both the first-terminal-side high-concentration region (31) and the second-terminal-side high-concentration region (41) in the plan view;
a third-terminal-side low-concentration region (52) of the first conductivity type provided at a position overlapping the third-terminal-side high-concentration region (51) in the plan view in a region closer to the first surface (20S) than the third-terminal-side high-concentration region (51);
a third-terminal-side contact region (53) of the first conductivity type provided in a surface layer portion of the third-terminal-side low-concentration region (52);
a third partition region (54) provided to surround the third-terminal-side low-concentration region (52) at a position overlapping the third-terminal-side high-concentration region (51) in the plan view in a region closer to the first surface (20S) than the third-terminal-side high-concentration region (51);
a fourth-terminal-side high-concentration region (131) of the second conductivity type provided at a position spaced apart from the first surface (20S) toward the second surface (20R) of the semiconductor chip (20) and spaced apart from each of the first-terminal-side high-concentration region (31), the second-terminal-side high-concentration region (41), and the third-terminal-side high-concentration region (51) in the plan view;
a fourth-terminal-side low-concentration region (132) of the first conductivity type provided at a position overlapping the fourth-terminal-side high-concentration region (131) in the plan view in a region closer to the first surface (20S) than the fourth-terminal-side high-concentration region (131);
a fourth-terminal-side contact region (133) of the first conductivity type provided in a surface layer portion of the fourth-terminal-side low-concentration region (132); and
a fourth partition region (134) provided to surround the fourth-terminal-side low-concentration region (132) at a position overlapping the fourth-terminal-side high-concentration region (131) in the plan view in a region closer to the first surface (20S) than the fourth-terminal-side high-concentration region (131),
wherein the first-terminal-side high-concentration region (31), the first-terminal-side low-concentration region (32), and the first-terminal-side contact region (33) form the first pin junction portion (30),
the second-terminal-side high-concentration region (41), the second-terminal-side low-concentration region (42), and the second-terminal-side contact region (43) form the second pin junction portion (40),
the third-terminal-side high-concentration region (51), the third-terminal-side low-concentration region (52), and the third-terminal-side contact region (53) form the third pin junction portion (50), and
the fourth-terminal-side high-concentration region (131), the fourth-terminal-side low-concentration region (132), and the fourth-terminal-side contact region (133) form the fourth pin junction portion (60D).

### Appendix A29

The TVS diode according to Appendix A28 including:
an insulating layer (70) covering the first surface (20S);
a first connection electrode (81) provided on the insulating layer (70) and connecting the first contact region (63A) and the first-terminal-side contact region (33);
a second connection electrode (82) provided on the insulating layer (70) and connecting the second contact region (63B) and the second-terminal-side contact region (43);
a third connection electrode (83) provided on the insulating layer (70) and connecting the third contact region (63C) and the third-terminal-side contact region (53); and
a fourth connection electrode (84) provided on the insulating layer (70) and connecting the fourth contact region (63D) and the fourth-terminal-side contact region (133).

### Appendix A30

The TVS diode according to Appendix A29, wherein the separation region (65) includes an exposed surface (65S) that is exposed from the first surface (20S), and
includes a wiring (90) that contacts the exposed surface (65S),
wherein the separation region (65) includes:
a first separation region (65A) overlapping the first connection electrode (81) in the plan view;
a second separation region (65B) overlapping the second connection electrode (82) in the plan view;
a third separation region (65C) overlapping the third connection electrode (83) in the plan view;
a fourth separation region (65D) overlapping the fourth connection electrode (84) in the plan view; and
a wiring connection region (65P) where the wiring (90) is connected,
wherein the wiring connection region (65P) is provided to partially surround each of the first reverse pin junction portion (60A), the second reverse pin junction portion (60B), the third reverse pin junction portion (60C), and the fourth reverse pin junction portion (60D) individually in the plan view.

### Appendix A31

The TVS diode according to Appendix A30, wherein the wiring (90) is provided to partially surround each of the first connection electrode (81), the second connection electrode (82), the third connection electrode (83), and the fourth connection electrode (84) individually in the plan view.

### Appendix A32

A TVS diode (10) including a semiconductor chip (20) comprising a first surface (20S) and a second surface (20R) opposite to the first surface (20S),
wherein the semiconductor chip (20) includes:
a first pin junction portion (30) of a first polarity direction provided in a region close to the first surface (20S) of the semiconductor chip (20); and
a diode pair region (60) including a first reverse pin junction portion (60A) of a second polarity direction provided spaced apart from the first pin junction portion (30) in a plan view when viewed from a thickness direction (Z) of the semiconductor chip (20), and a pn junction portion (60E) of the first polarity direction which forms a diode pair with the first reverse pin junction portion (60A),
the diode pair region (60) includes:
a first conductivity type high-concentration region (61) provided spaced apart from the first surface (20S) toward the second surface (20R) of the semiconductor chip (20);
a first low-concentration region (62A) of the first conductivity type provided at a position overlapping the high-concentration region (61) in the plan view in a region closer to the first surface (20S) than the high-concentration region (61) and having a impurity concentration lower than that of the high-concentration region (61);
a first contact region (63A) of a second conductivity type provided in a surface layer portion of the first low-concentration region (62A); and
an internal region (64) of the second conductivity type provided at a position overlapping the high-concentration region (61) in the plan view and in contact with the high-concentration region (61) closer to the second surface (20R) than the high-high concentration region (61),
wherein the high-concentration region (61), the first low-concentration region (62A), and the first contact region (63A) form a first reverse pin junction portion (60A) of the second polarity direction,
the high-concentration region (61) and the internal region (64) form a pn junction portion (60E) of the first polarity direction to be connected in a reverse direction to the first reverse pin junction portion (60A), and
the outer edge of the internal region (64) is located inward from the outer edge of the high-concentration region (61) in the plan view.

### Summary of Appendix A32

It is desirable to suppress electric field concentration at the pn junction portion.

### Appendix A33

The TVS diode according to Appendix A32, wherein in the plan view, the outer edge of the internal region (62) includes a plurality of corner portions, and
each of the corner portions is curved in the plan view.

### Appendix A34

The TVS diode according to Appendix A32 or A33 including a separation region (65) provided at a position overlapping the high-concentration region (61) in the plan view in a region closer to the first surface (20S) than the high-concentration region (61) and separating the first low-concentration region (62A) from the second low-concentration region (62B),
wherein the outer edge of the internal region (64) is disposed at a position overlapping the separation region (65) in the plan view.

### Appendix B1

A TVS diode (10) including a semiconductor chip (20) comprising a first surface (20S) and a second surface (20R) opposite to the first surface (20S),
wherein the semiconductor chip (20) includes:
a first pin junction portion (30) and a second pin junction portion (40) of a first polarity direction provided in a region close to the first surface (20S) of the semiconductor chip (20); and
a diode pair region (60) including a first reverse pin junction portion (60A) and a second reverse pin junction portion (60B) of a second polarity direction provided in a region close to the first surface (20S) of the semiconductor chip (20), and a pn junction portion (60E) of the first polarity direction provided at a position overlapping the first reverse pin junction portion (60A) and the second reverse pin junction portion (60B) in a plan view when viewed from a thickness direction (Z) of the semiconductor chip (20) and forming a diode pair with the first reverse pin junction portion (60A) and the second reverse pin junction portion (60B), and spaced apart from both the first pin junction portion (30) and the second pin junction portion (40) in the plan view,
the diode pair region (60) is disposed between the first pin junction portion (30) and the second pin junction portion (40) in the plan view.

### Appendix B2

The TVS diode according to Appendix B1, wherein
the first pin junction portion (30) and the first reverse pin junction portion (60A) are located side by side in a first direction (Y) in the plan view,
the second pin junction portion (40) and the second reverse pin junction portion (60B) are located side by side in the first direction (Y) in the plan view,
the first pin junction portion (30) and the second reverse pin junction portion (60B) are adjacent in a second direction (X) orthogonal to the first direction (Y) in the plan view,
the first reverse pin junction portion (60A) and the second pin junction portion (40) are adjacent in the second direction (X) in the plan view, and
the diode pair region (60) includes a region (67A) disposed between the first pin junction portion (30) and the second pin junction portion (40) in a direction that intersects both the first direction (X) and the second direction (Y) in the plan view.

### Appendix B3

The TVS diode according to Appendix B2, wherein the diode pair region (60) includes:
a first region (66A) where the first reverse pin junction portion (60A) is provided; and
a second region (66B) where the second reverse pin junction portion (60B) is provided,
wherein the second region (66B) includes a region positioned to be shifted in the first direction (Y) relative to the first region (66A).

### Appendix B4

The TVS diode according to Appendix B3, wherein the first region (66A) and the second pin junction portion (40) are adjacent in the second direction (X) in the plan view, and
the second region (66B) and the first pin junction portion (30) are adjacent in the second direction (X) in the plan view.

### Appendix B5

The TVS diode according to Appendix B1, wherein
the diode pair region (60) is disposed between the first pin junction portion (30) and the second pin junction portion (40) in the first direction (Y) in the plan view,
the first pin junction portion (30) is located side by side with both the first reverse pin junction portion (60A) and the second reverse pin junction portion (60B) in the plan view, and
the second pin junction portion (40) is located side by side with both the first reverse pin junction portion (60A) and the second reverse pin junction portion (60B) in the plan view.

### Appendix B6

The TVS diode according to any one of Appendices B2 to B4, wherein the diode pair region (60) includes:
a first conductivity type high-concentration region (61) provided spaced apart from the first surface (20S) toward the second surface (20R) of the semiconductor chip (20);
a first low-concentration region (62A) and a second low-concentration region (62B) of the first conductivity type provided spaced apart from each other at a position overlapping the high-concentration region (61) in the plan view in a region close to the first surface (20S) of the semiconductor chip (20) and having a impurity concentration lower than that of the high-concentration region (61);
a separation region (65) provided at a position overlapping the high-concentration region (61) in the plan view in a region closer to the first surface (20S) than the high-concentration region (61) and electrically separating the first low-concentration region (62A) from the second low-concentration region (62B);
a first contact region (63A) of the second conductivity type provided in a surface layer portion of the first low-concentration region (62A);
a second contact region (63B) of the second conductivity type provided in a surface layer portion of the second low-concentration region (62B); and
an internal region (64) of the second conductivity type at a position overlapping the high-concentration region (61) in the plan view, in contact with the high-concentration region (61) and closer to the second surface (20R) than the high-concentration region (61),
wherein the first reverse pin junction portion (60A) is formed of the high-concentration region (61), the first low-concentration region (62A), and the first contact region (63A),
the second reverse pin junction portion (60B) is formed of the high-concentration region (61), the second low-concentration region (62B), and the second contact region (63B), and
the pn junction portion (60E) is formed of the high-concentration region (61) and the internal region (64) and is connected in a reverse direction to the first reverse pin junction portion (60A) and the second reverse pin junction portion (60B).

### Appendix B7

The TVS diode according to Appendix B6 including:
an insulating layer (70) covering the first surface (20S);
a first connection electrode (81) provided on the insulating layer (70) and electrically connecting the first contact region (63A) and the first pin junction portion (30); and
a second connection electrode (82) provided on the insulating layer (70) and electrically connecting the second contact region (63B) and the second pin junction portion (40).

### Appendix B8

The TVS diode according to Appendix B7, wherein the first connection electrode (81) and the second connection electrode (82) are disposed spaced apart from each other in the second direction (X) in the plan view, and
each of the first connection electrode (81) and the second connection electrode (82) extends in the first direction (Y) in the plan view.

### Appendix B9

The TVS diode according to Appendix B7 or B8 including:
a protective layer (74) covering the first connection electrode (81) and the second connection electrode (82);
a first terminal (101) provided on the protective layer (74) and electrically connected to the first pin junction portion (30); and
a second terminal (102) provided on the protective layer (74) and electrically connected to the second pin junction portion (40),
wherein the protective layer (74) includes:
a first terminal opening portion (77A) partially exposing the first connection electrode (81); and
a second terminal opening portion (77B) partially exposing the second connection electrode (82),
wherein the first terminal (101) is electrically connected to the first connection electrode (81) through the first terminal opening portion (77A), and
the second terminal (102) is electrically connected to the second connection electrode (82) through the second terminal opening portion (77B).

### Appendix B10

The TVS diode according to any one of Appendices B2 to B4, wherein the semiconductor chip (20) includes:
a third pin junction portion (50) of the first polarity direction provided in a region close to the first surface (20S) of the semiconductor chip (20); and
a third reverse pin junction portion (60C) of the second polarity direction provided in a region close to the first surface (20S) of the semiconductor chip (20) and forming the diode pair with the pn junction portion (60E),
wherein the third pin junction portion (50) the third reverse pin junction portion (60C) are located side by side in the first direction (Y) in the plan view and are electrically connected to each other,
the third pin junction portion (50) and the third reverse pin junction portion (60C) are disposed to be adjacent to each other on the opposite side of the second pin junction portion (40) and the second reverse pin junction portion (60B) to the first pin junction portion (30) and the first reverse pin junction portion (60A) in the second direction (X) in the plan view,
the third pin junction portion (50) and the second reverse pin junction portion (60B) are adjacent in the second direction (X) in the plan view,
the third reverse pin junction portion (60C) and the second pin junction portion (40) are adjacent in the second direction (X) in the plan view, and
the diode pair region (60) includes a region (67B) disposed between the second pin junction portion (40) and the third pin junction portion (50) in a direction that intersects both the first direction (Y) and the second direction (X) in the plan view.

### Appendix B11

The TVS diode according to Appendix B10, wherein the diode pair region (60) includes:
a high-concentration region (61) of the first conductivity type provided spaced apart from the first surface (20S) toward the second surface (20R) of the semiconductor chip (20);
a first low-concentration region (62A), a second low-concentration region (62B), and a third low-concentration region (62C) of the first conductivity type provided spaced apart from each other at a position overlapping the high-concentration region (61) in the plan view in a region close to the first surface (20S) of the semiconductor chip (20), and having a lower impurity concentration than the high-concentration region (61);
a separation region (65) provided at a position overlapping the high-concentration region (61) in the plan view in a region closer to the first surface (20S) than the high-concentration region (61) and electrically separating the first low-concentration region (62A), the second low-concentration region (62B), and the third low-concentration region (62C);
a first contact region (63A) of the second conductivity type provided in a surface layer portion of the first low-concentration region (62A);
a second contact region (63B) of the second conductivity type provided in a surface layer portion of the second low-concentration region (62B);
a third contact region (63C) of the second conductivity type provided in a surface layer portion of the third low-concentration region (62C); and
an internal region (64) of the second conductivity type at a position overlapping the high-concentration region (61) in the plan view, in contact with the high-concentration region (61) and closer to the second surface (20R) than the high-concentration region (61),
wherein the first reverse pin junction portion (60A) is formed of the high-concentration region (61), the first low-concentration region (62A), and the first contact region (63A),
the second reverse pin junction portion (60B) is formed of the high-concentration region (61), the second low-concentration region (62B), and the second contact region (63B),
the third reverse pin junction portion (60C) is formed of the high-concentration region (61), the third low-concentration region (62C), and the third contact region (63C), and
the pn junction portion (60E), which is connected in a reverse direction to the first reverse pin junction portion (60A), the second reverse pin junction portion (60B), and the third reverse pin junction portion (60C), is formed of the high-concentration region (61) and the internal region (64).

### Appendix B12

The TVS diode according to Appendix B11, wherein the high-concentration region (61) includes:
a first region (66A) where the first reverse pin junction portion (60A) is provided;
a second region (66B) where the second reverse pin junction portion (60B) is provided; and
a third region (66C) where the third reverse pin junction portion (60C) is provided,
wherein the second region (66B) includes a region positioned to be shifted in the first direction (Y) relative to both the first region (66A) and the third region (66C).

### Appendix B13

The TVS diode according to Appendix B12, wherein the second region (66B) includes a portion disposed between the first pin junction portion (30) in the second direction (X) and the third pin junction portion (50), and
the first region (66A) and the third region (66C) include a portion adjacent to the second pin junction portion (40) in the second direction (X).

### Appendix B14

The TVS diode according to any one of Appendices B11 to B13, wherein the semiconductor chip (20) includes:
a first-terminal-side high-concentration region (31) of the second conductivity type provided spaced apart from the second surface (20R) toward the first surface (20S) of the semiconductor chip (20);
a first-terminal-side low-concentration region (32) of the first conductivity type provided at a position overlapping the first-terminal-side high-concentration region (31) in the plan view in a region close to the first surface (20S) of the semiconductor chip (20);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region close to the first surface (20S) of the semiconductor chip (20);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region close to the first surface (20S) of the semiconductor chip (20);
a second-terminal-side contact region (43) of the first conductivity type provided in a surface layer portion of the second-terminal-side low-concentration region (42);
a second partition region (44) provided to surround the second-terminal-side low-concentration region (42) at a position overlapping the second-terminal-side high-concentration region (41) in the plan view in a region close to the first surface (20S) of the semiconductor chip (20);
a third-terminal-side high-concentration region (51) of the second conductivity type provided at a position spaced apart from the first surface (20S) of the semiconductor chip toward the second surface (20R) and spaced apart from both the first-terminal-side high-concentration region (31) and the second-terminal-side high-concentration region (41) in the plan view;
a third-terminal-side low-concentration region (52) of a first conductivity type provided at a position overlapping the third-terminal-side high-concentration region (51) in the plan view in a region close to the first surface (20S) of the semiconductor chip (20);
a third-terminal-side contact region (53) of the first conductivity type provided in a surface layer portion of the third-terminal-side low-concentration region (52); and
a third partition region (54) provided to surround the third-terminal-side low-concentration region (52) at a position overlapping the third-terminal-side high-concentration region (51) in the plan view in a region close to the first surface (20S) of the semiconductor chip (20),
wherein the first-terminal-side high-concentration region (31), the first-terminal-side low-concentration region (32), and the first-terminal-side contact region (33) form the first pin junction portion (30),
the second-terminal-side high-concentration region (41), the second-terminal-side low-concentration region (42), and the second-terminal-side contact region (43) form the second pin junction portion (40), and
the third-terminal-side high-concentration region (51), the third-terminal-side low-concentration region (52), and the third-terminal-side contact region (53) form the third pin junction portion (50).

### Appendix B15

The TVS diode according to Appendix B14 including:
an insulating layer (70) covering the first surface (20S);
a first connection electrode (81) provided on the insulating layer (70) and connecting the first contact region (63A) and the first-terminal-side contact region (33);
a second connection electrode (82) provided on the insulating layer (70) and connecting the second contact region (63B) and the second-terminal-side contact region (43); and
a third connection electrode (83) provided on the insulating layer (70) and connecting the third contact region (63C) and the third-terminal-side contact region (53).

### Appendix B16

The TVS diode according to Appendix B15, wherein the first connection electrode (81), the second connection electrode (82), and the third connection electrode (83) are disposed spaced apart from each other in the second direction (X) in the plan view, and
each of the first connection electrode (81), the second connection electrode (82), and the third connection electrode (83) extends in the first direction (Y) in the plan view.

### Appendix B17

The TVS diode according to Appendix B15 or B16 including:
a protective layer (74) covering the first connection electrode (81), the second connection electrode (82), and the third connection electrode (83);
a first terminal (101) provided on the protective layer (74) and electrically connected to the first pin junction portion (30);
a second terminal (102) provided on the protective layer (74) and electrically connected to the second pin junction portion (40); and
a third terminal (103) provided on the protective layer (74) and electrically connected to the third pin junction portion (50),
wherein the protective layer (74) includes:
a first terminal opening portion (77A) partially exposing the first connection electrode (81);
a second terminal opening portion (77B) partially exposing the second connection electrode (82); and
a third terminal opening portion (77C) partially exposing the third connection electrode (83),
wherein the first terminal (101) is electrically connected to the first connection electrode (81) through the first terminal opening portion (77A),
the second terminal (102) is electrically connected to the second connection electrode (82) through the second terminal opening portion (77B), and
the third terminal (103) is electrically connected to the third connection electrode (83) through the third terminal opening portion (77C).

### Appendix B18

The TVS diode according to any one of Appendices B2 to B4, wherein the semiconductor chip (20) includes:
a third pin junction portion (50) and a fourth pin junction portion (130) of the first polarity direction provided in a region close to the first surface (20S) of the semiconductor chip (20); and
a third reverse pin junction portion (60C) and a fourth reverse pin junction portion (60D) of the second polarity direction provided in a region close to the first surface (20S) of the semiconductor chip (20) and forming the diode pair with the pn junction portion (60E),
wherein the third pin junction portion (50) and the third reverse pin junction portion (60C) are located side by side in the first direction (Y) in the plan view,
the fourth pin junction portion (130) and the fourth reverse pin junction portion (60D) are located side by side in the first direction (Y) in the plan view,
the third pin junction portion (50) and the third reverse pin junction portion (60C) are disposed to be adjacent to each other on the opposite side of the second pin junction portion (40) and the second reverse pin junction portion (60B) relative to the first pin junction portion (30) and the first reverse pin junction portion (60A) in the second direction (X) in the plan view,
the fourth pin junction portion (130) and the fourth reverse pin junction portion (60D) are disposed to be adjacent to each other on the opposite side of the third pin junction portion (50) and the third reverse pin junction portion (60C) relative to the second pin junction portion (40) and the second reverse pin junction portion (60B) in the second direction (X) in the plan view,
the third pin junction portion (50) and the second reverse pin junction portion (60B) are adjacent in the second direction (X) in the plan view,
the third reverse pin junction portion (60C) and the second pin junction portion (40) are adjacent in the second direction (X) in the plan view,
the fourth pin junction portion (130) and the third reverse pin junction portion (60C) are adjacent in the second direction (X) in the plan view,
the fourth reverse pin junction portion (60D) and the third pin junction portion (50) are adjacent in the second direction (X) in the plan view, and
the diode pair region (60) includes a region (67C) disposed between the third pin junction portion (50) and the fourth pin junction portion (130) in a direction that intersects both the first direction (X) and the second direction (Y) in the plan view.

### Appendix B19

The TVS diode according to Appendix B1, wherein the semiconductor chip (20) includes:
a third pin junction portion (50) and a fourth pin junction portion (130) of the first polarity direction provided in a region close to the first surface (20S) of the semiconductor chip (20); and
a third reverse pin junction portion (60C) and a fourth reverse pin junction portion (60D) of the second polarity direction provided in a region close to the first surface (20S) of the semiconductor chip (20) and forming the diode pair with the pn junction portion (60E),
wherein the first pin junction portion (30), the first reverse pin junction portion (60A), and the second pin junction portion (40) are located side by side in a first direction (Y) in the plan view, and the first reverse pin junction portion (60A) is disposed between the first pin junction portion (30) and the second pin junction portion (40) in the first direction (Y),
the third pin junction portion (50), the fourth reverse pin junction portion (60D), and the fourth pin junction portion (130) are located side by side in the first direction (Y) in the plan view, and the fourth reverse pin junction portion (60D) is disposed between the third pin junction portion (50) and the fourth pin junction portion (130) in the first direction (Y),
the first pin junction portion (30), the third reverse pin junction portion (60C), and the third pin junction portion (50) are located side by side in a second direction (X), which is orthogonal to the first direction (Y), in the plan view, and the third reverse pin junction portion (60C) is disposed between the first pin junction portion (30) and the third pin junction portion (50) in the second direction (X), and
the second pin junction portion (40), the second reverse pin junction portion (60B), and the fourth pin junction portion (130) are located side by side in the second direction (X) in the plan view, and the second reverse pin junction portion (60B) is disposed between the second pin junction portion (40) and the fourth pin junction portion (130) in the second direction (X).

### Appendix B20

The TVS diode according to any one of Appendices B1 to B19, wherein the first polarity direction is a direction in which a forward current flows from the second surface (20R) to the first surface (20S) in the thickness direction (Z) of the semiconductor chip (20), and
the second polarity direction is a direction in which a forward current flows opposite to the first polarity direction in the thickness direction (Z) of the semiconductor chip (20).

### Appendix B21

The TVS diode according to Appendix B18, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region close to the first surface (20S) of the semiconductor chip (20);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region close to the first surface (20S) of the semiconductor chip (20);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region close to the first surface (20S) of the semiconductor chip (20);
a second-terminal-side contact region (43) of the first conductivity type provided in a surface layer portion of the second-terminal-side low-concentration region (42);
a second partition region (44) provided to surround the second-terminal-side low-concentration region (42) at a position overlapping the second-terminal-side high-concentration region (41) in the plan view in a region close to the first surface (20S) of the semiconductor chip (20);
a third-terminal-side high-concentration region (51) of the second conductivity type provided at a position spaced apart from the first surface (20S) toward the second surface (20R) of the semiconductor chip (20) and spaced apart from both the first-terminal-side high-concentration region (31) and the second-terminal-side high-concentration region (41) in the plan view;
a third-terminal-side low-concentration region (52) of the first conductivity type provided at a position overlapping the third-terminal-side high-concentration region (51) in the plan view in a region close to the first surface (20S) of the semiconductor chip (20);
a third-terminal-side contact region (53) of the first conductivity type provided in a surface layer portion of the third-terminal-side low-concentration region (52);
a third partition region (54) provided to surround the third-terminal-side low-concentration region (52) at a position overlapping the third-terminal-side high-concentration region (51) in the plan view in a region close to the first surface (20S) of the semiconductor chip (20);
a fourth-terminal-side high-concentration region (131) of the second conductivity type provided at a position spaced apart from the first surface (20S) toward the second surface (20R) of the semiconductor chip (20) and spaced apart from each of the first-terminal-side high-concentration region (31), the second-terminal-side high-concentration region (41), and the third-terminal-side high-concentration region (51) in the plan view;
a fourth-terminal-side low-concentration region (132) of the first conductivity type provided at a position overlapping the fourth-terminal-side high-concentration region (131) in the plan view in a region close to the first surface (20S) of the semiconductor chip (20);
a fourth-terminal-side contact region (133) of the first conductivity type provided in a surface layer portion of the fourth-terminal-side low-concentration region (132); and
a fourth partition region (134) provided to surround the fourth-terminal-side low-concentration region (132) at a position overlapping the fourth-terminal-side high-concentration region (131) in the plan view in a region close to the first surface (20S) of the semiconductor chip (20),
wherein the first pin junction portion (30) is formed of the first-terminal-side high-concentration region (31), the first-terminal-side low-concentration region (32), and the first-terminal-side contact region (33),
the second pin junction portion (40) is formed of the second-terminal-side high-concentration region (41), the second-terminal-side low-concentration region (42), and the second-terminal-side contact region (43),
the third pin junction portion (50) is formed of the third-terminal-side high-concentration region (51), the third-terminal-side low-concentration region (52), and the third-terminal-side contact region (53), and
the fourth pin junction portion (130) is formed of the fourth-terminal-side high-concentration region (131), the fourth-terminal-side low-concentration region (132), and the fourth-terminal-side contact region (133).

### Appendix B22

The TVS diode according to Appendix B21, wherein the semiconductor chip (20) includes a diode pair region (60) including the first reverse pin junction portion (60A), the second reverse pin junction portion (60B), the third reverse pin junction portion (60C), the fourth reverse pin junction portion (60D), and the pn junction portion (60E),
the diode pair region (60) includes:
a high-concentration region (61) of the first conductivity type provided spaced apart from the first surface (20S) toward the second surface (20R) of the semiconductor chip (20);
a first low-concentration region (62A), a second low-concentration region (62B), a third low-concentration region (62C), and a fourth low-concentration region (62D) of the first conductivity type provided at a position overlapping the high-concentration region (61) in the plan view in a region close to the first surface (20S) of the semiconductor chip (20) and spaced apart from each other, and having an impurity concentration lower than that of the high-concentration region (61);
a separation region (65) provided at a position overlapping the high-concentration region (61) in the plan view in a region close to the first surface (20S) of the semiconductor chip (20), and electrically separating the first low-concentration region (62A), the second low-concentration region (62B), the third low-concentration region (62C), and the fourth low-concentration region (62D) from each other;
a first contact region (63A) of the second conductivity type provided on a surface layer portion of the first low-concentration region (62A);
a second contact region (63B) of the second conductivity type provided on a surface layer portion of the second low-concentration region (62B);
a third contact region (63C) of the second conductivity type provided on a surface layer portion of the third low-concentration region (62C);
a fourth contact region (63D) of the second conductivity type provided on a surface layer portion of the fourth low-concentration region (62D); and
an internal region (64) of the second conductivity type in contact with the high-concentration region (61) at a position overlapping the high-concentration region (61) in the plan view and closer to the second surface (20R) than the high-concentration region (61),
wherein the first reverse pin junction portion (60A) is formed of the high-concentration region (61), the first low-concentration region (62A), and the first contact region (63A),
the second reverse pin junction portion (60B) is formed of the high-concentration region (61), the second low-concentration region (62B), and the second contact region (63B),
the third reverse pin junction portion (60C) is formed of the high-concentration region (61), the third low-concentration region (62C), and the third contact region (63C),
the fourth reverse pin junction portion (60D) is formed of the high-concentration region (61), the fourth low-concentration region (62D), and the fourth contact region (63D), and
the pn junction portion (60E), connected in a reverse direction to each of the first reverse pin junction portion (60A), the second reverse pin junction portion (60B), the third reverse pin junction portion (60C), and the fourth reverse pin junction portion (60D), is formed of the high-concentration region (61) and the internal region (64).

### Appendix B23

The TVS diode according to Appendix B22, wherein the internal region (64) is provided to overlap the first low-concentration region (62A), the second low-concentration region (62B), the third low-concentration region (62C), and the fourth low-concentration region (62D) in the plan view.

### Appendix B24

The TVS diode according to Appendix B22 or B23 including:
an insulating layer (70) covering the first surface (20S);
a first connection electrode (81) provided on the insulating layer (70) and connecting the first contact region (63A) and the first-terminal-side contact region (33);
a second connection electrode (82) provided on the insulating layer (70) and connecting the second contact region (63B) and the second-terminal-side contact region (43);
a third connection electrode (83) provided on the insulating layer (70) and connecting the third contact region (63C) and the third-terminal-side contact region (53); and
a fourth connection electrode (84) provided on the insulating layer (70) and connecting the fourth contact region (63D) and the fourth-terminal-side contact region (133).

### Appendix B25

The TVS diode according to Appendix B24 including:
a protective layer (74) covering the first connection electrode (81), the second connection electrode (82), the third connection electrode (83), and the fourth connection electrode (84);
a first terminal (101) provided on the protective layer (74) and electrically connected to the first pin junction portion (30);
a second terminal (102) provided on the protective layer (74) and electrically connected to the second pin junction portion (40);
a third terminal (103) provided on the protective layer (74) and electrically connected to the third pin junction portion (50); and
a fourth terminal provided on the protective layer (74) and electrically connected to the fourth pin junction portion (130),
wherein the protective layer (74) includes:
a first terminal opening portion (77A) partially exposing the first connection electrode (81);
a second terminal opening portion (77B) partially exposing the second connection electrode (82);
a third terminal opening portion (77C) partially exposing the third connection electrode (83); and
a fourth terminal opening portion (77D) partially exposing the fourth connection electrode (84),
wherein the first terminal (101) is electrically connected to the first connection electrode (81) through the first terminal opening portion (77A),
the second terminal (102) is electrically connected to the second connection electrode (82) through the second terminal opening portion (77B),
the third terminal (103) is electrically connected to the third connection electrode (83) through the third terminal opening portion (77C), and
the fourth terminal is electrically connected to the fourth connection electrode (84) through the fourth terminal opening portion (77D).

### Appendix B26

The TVS diode according to any one of Appendices B1 to B9, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first partition region (34) provided to surround the first-terminal-side low-concentration region (32) at a position overlapping the first-terminal-side high-concentration region (31) in the plan view in a region closer to the first surface (20S) than the first-terminal-side high-concentration region (31);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42); and
a second partition region (44) provided to surround the second-terminal-side low-concentration region (42) at a position overlapping the second-terminal-side high-concentration region (41) in the plan view in a region closer to the first surface (20S) than the second-terminal-side high-concentration region (41),
wherein the first-terminal-side high-concentration region (31), the first-terminal-side low-concentration region (32), and the first-terminal-side contact region (33) form the first pin junction portion (30), and
the second-terminal-side high-concentration region (41), the second-terminal-side low-concentration region (42), and the second-terminal-side contact region (43) form the second pin junction portion (40).

### Appendix B27

The TVS diode according to any one of Appendices B1 to B9, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first separation trench (121A) provided on the first surface (20S) to surround the first-terminal-side high-concentration region (31), the first-terminal-side low-concentration region (32), and the first-terminal-side contact region (33);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42); and
a second separation trench (121B) provided on the first surface to surround the second-terminal-side high-concentration region (41), the second-terminal-side low-concentration region (42), and the second-terminal-side contact region (43),
wherein the first-terminal-side high-concentration region (31), the first-terminal-side low-concentration region (32), and the first-terminal-side contact region (33) form the first pin junction portion (30), and
the second-terminal-side high-concentration region (41), the second-terminal-side low-concentration region (42), and the second-terminal-side contact region (43) form the second pin junction portion (40).

### Appendix B28

The TVS diode according to Appendix B27, wherein the semiconductor chip (20) includes:
a first separation insulating layer (122A) provided in the first separation trench (121A); and
a second separation insulating layer (122B) provided in the second separation trench (121B).

### Appendix B29

The TVS diode according to Appendix B28 including:
a first separation electrode (123A) embedded in the first separation trench (121A) with the first separation insulating layer (122A) in between; and
a second separation electrode (123B) embedded in the second separation trench (121B) with the second separation insulating layer (122B) in between,
wherein both of the first separation electrode (123A) and the second separation electrode (123B) are in an electrically floating state.

### Appendix B30

The TVS diode according to Appendix B10, wherein the semiconductor chip (20) includes:
a first-terminal-side high-concentration region (31) of the second conductivity type provided spaced apart from the first surface (20S) toward the second surface (20R) of the semiconductor chip (20);
a first-terminal-side low-concentration region (32) of the first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32);
a first separation trench (121A) provided on the first surface (20S) to surround the first-terminal-side high-concentration region (31), the first-terminal-side low-concentration region (32), and the first-terminal-side contact region (33);
a second-terminal-side high-concentration region (41) of the second conductivity type provided at a position spaced apart from the first surface (20S) toward the second surface (20R) of the semiconductor chip (20) and spaced apart from the first-terminal-side high-concentration region (31) in the plan view;
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42);
a second separation trench (121B) provided on the first surface (20S) to surround the second-terminal-side high-concentration region (41), the second-terminal-side low-concentration region (42), and the second-terminal-side contact region (43);
a third-terminal-side high-concentration region (51) of the second conductivity type provided at a position spaced apart from the first surface (20S) toward the second surface (20R) of the semiconductor chip (20) and spaced apart from both the first-terminal-side high-concentration region (31) and the second-terminal-side high-concentration region (41) in the plan view;
a third-terminal-side low-concentration region (52) of the first conductivity type provided at a position overlapping the third-terminal-side high-concentration region (51) in the plan view in a region closer to the first surface (20S) than the third-terminal-side high-concentration region (51);
a third-terminal-side contact region (53) of the first conductivity type provided in a surface layer portion of the third-terminal-side low-concentration region (52); and
a third separation trench (121C) provided on the first surface (20S) to surround the third-terminal-side high-concentration region (51), the third-terminal-side low-concentration region (52), and the third-terminal-side contact region (53),
wherein the first-terminal-side high-concentration region (31), the first-terminal-side low-concentration region (32), and the first-terminal-side contact region (33) form the first pin junction portion (30),
the second-terminal-side high-concentration region (41), the second-terminal-side low-concentration region (42), and the second-terminal-side contact region (43) form the second pin junction portion (40), and
the third-terminal-side high-concentration region (51), the third-terminal-side low-concentration region (52), and the third-terminal-side contact region (53) form the third pin junction portion (50).

### Appendix B31

The TVS diode according to Appendix B30, wherein the semiconductor chip (20) includes:
a first separation insulating layer (122A) provided in the first separation trench (121A);
a second separation insulating layer (122B) provided in the second separation trench (121B); and
a third separation insulating layer (122C) provided in the third separation trench (121C).

### Appendix B32

The TVS diode according to Appendix B31 including:
a first separation electrode (123A) embedded in the first separation trench (121A) with the first separation insulating layer (122A) in between;
a second separation electrode (123B) embedded in the second separation trench (121B) with the second separation insulating layer (122B) in between; and
a third separation electrode (123C) embedded in the third separation trench (121C) with the third separation insulating layer (122C) in between,
wherein each of the first separation electrode (123A), the second separation electrode (123B), and the third separation electrode (123C) is in an electrically floating state.

### Appendix C1

A TVS diode (10) including a semiconductor chip (20) comprising a first surface (20S) and a second surface (20R) opposite to the first surface (20S),
wherein the semiconductor chip (20) includes:
a first pin junction portion (30) of a first polarity direction provided in a region close to the first surface (20S) of the semiconductor chip (20);
a diode pair region (60) including a first reverse pin junction portion (60A) of a second polarity direction provided spaced apart from the first pin junction portion (30) in a plan view viewed from a thickness direction (Z) of the semiconductor chip (20) and a pn junction portion (60E) of the first polarity direction that forms a diode pair with the first reverse pin junction portion (60A);
a first-terminal-side high-concentration region (31) of a second conductivity type provided spaced apart from the first surface (20S) toward the second surface (20R) of the semiconductor chip (20);
a first-terminal-side low-concentration region (32) of a first conductivity type provided at a position overlapping the first-terminal-side high-concentration region (31) in the plan view in a region closer to the first surface (20S) than the first-terminal-side high-concentration region (31);
a first-terminal-side contact region (33) of the first conductivity type provided in a surface layer portion of the first-terminal-side low-concentration region (32); and
a first buffer region (35) of the second conductivity type provided in contact with the first-terminal-side high-concentration region (31) between the first-terminal-side high-concentration region (31) and the first-terminal-side low-concentration region (32) in the thickness direction (Z) of the semiconductor chip (20),
wherein the first-terminal-side contact region (33), the first-terminal-side low-concentration region (32), and the first buffer region (35) form a pin diode.

### Appendix C2

The TVS diode according to Appendix C1, wherein the semiconductor chip (20) includes:
a first partition region (34) provided to surround the first-terminal-side low-concentration region (32) at a position overlapping the first-terminal-side high-concentration region (31) in the plan view in a region closer to the first surface (20S) than the first-terminal-side high-concentration region (31),
wherein the first partition region (34) is provided to surround the first buffer region (35) in the plan view.

### Appendix C3

The TVS diode according to Appendix C1 or C2, wherein the first buffer region (35) has a second conductivity type impurity concentration that is lower than that of the first-terminal-side high-concentration region (31).

### Appendix C4

The TVS diode according to any one of Appendices C1 to C3, wherein the second conductivity type impurity concentration in the first buffer region (35) decreases from the first-terminal-side high-concentration region (31) to the first-terminal-side low-concentration region (32) in the thickness direction (Z) of the semiconductor chip (20).

### Appendix C5

The TVS diode according to Appendix C3 or C4, wherein the second conductivity type impurity concentration in the first buffer region (35) is equal to or greater than the first conductivity type impurity concentration in the first-terminal-side low-concentration region (32).

### Appendix C6

The TVS diode according to any one of Appendices C1 to C5, wherein the diode pair region (60) includes:
a high-concentration region (61) of the first conductivity type provided spaced apart from the first surface (20S) toward the second surface (20R) of the semiconductor chip (20);
a first low-concentration region (62A) of the first conductivity type provided at a position overlapping the high-concentration region (61) in the plan view in a region closer to the first surface (20S) than the high-concentration region (61), and having a impurity concentration lower than that of the high-concentration region (61);
a first contact region (63A) of the second conductivity type provided in a surface layer portion of the first low-concentration region (62A); and
an internal region (64) of the second conductivity type in contact with the high-concentration region (61) at a position overlapping the high-concentration region (61) in the plan view and closer to the second surface (20R) than the high-concentration region (61),
wherein the first reverse pin junction portion (60A) is formed of the high-concentration region (61), the first low-concentration region (62A), and the first contact region (63A), and
the pn junction portion (60E), connected in a reverse direction to the first reverse pin junction portion (60A), is formed of the high-concentration region (61) and the internal region (64).

### Appendix C7

The TVS diode according to any one of Appendices C1 to C6, wherein the semiconductor chip (20) includes:
a second pin junction portion (40) of the first polarity direction provided at a position spaced apart from the first pin junction portion (30) in the plan view in a region close to the first surface (20S) of the semiconductor chip (20);
a second-terminal-side high-concentration region (41) of the second conductivity type provided at a position spaced apart from the first-terminal-side high-concentration region (31) in the plan view and at a position spaced apart from the first surface (20S) toward the second surface (20R) of the semiconductor chip (20);
a second-terminal-side low-concentration region (42) of the first conductivity type provided at a position overlapping the second-terminal-side high-concentration region (41) in the plan view in a region closer to the first surface (20S) than the second-terminal-side high-concentration region (41);
a second-terminal-side contact region (43) of the first conductivity type provided in a surface layer portion of the second-terminal-side low-concentration region (42); and
a second buffer region (45) of the first conductivity type in contact with the second-terminal-side high-concentration region (41) between the second-terminal-side high-concentration region (41) and the second-terminal-side low-concentration region (42) in the thickness direction (Z) of the semiconductor chip (20),
wherein the second pin junction portion (40) is formed of the second buffer region (45), the second-terminal-side low-concentration region (42), and the second-terminal-side contact region (43).

### Appendix C8

The TVS diode according to Appendix C7, wherein the semiconductor chip (20) includes a second partition region (44) provided to surround the second-terminal-side low-concentration region (42) at a position overlapping the second-terminal-side high-concentration region (41) in the plan view in a region closer to the first surface (20S) than the high-concentration region (41),
wherein the second partition region (44) is provided to surround the second buffer region (45) in the plan view.

### Appendix C9

The TVS diode according to Appendix C7 or C8, wherein the second buffer region (45) has a second conductivity type impurity concentration that is lower than that of the second-terminal-side high-concentration region (41).

### Appendix C10

The TVS diode according to any one of Appendices C7 to C9, wherein the second conductivity type impurity concentration in the second buffer region (45) decreases from the second-terminal-side high-concentration region (41) toward the second-terminal-side low-concentration region (42) in the thickness direction (Z) of the semiconductor chip (20).

### Appendix C11

The TVS diode according to Appendix C9 or C10, wherein the second conductivity type impurity concentration of the second buffer region (45) is equal to or greater than the first conductivity type impurity concentration of the second-terminal-side low-concentration region (42).

### Appendix C12

The TVS diode according to any one of Appendices C7 to C11, wherein the diode pair region (60) includes:
a second reverse pin junction portion (60B) of the second polarity direction that forms the diode pair with the pn junction portion (60E);
a high-concentration region (61) of the first conductivity type provided spaced apart from the first surface (20S) toward the second surface (20R) of the semiconductor chip (20);
a first low-concentration region (62A) and a second low-concentration region (62B) of the first conductivity type provided spaced apart from each other at a position overlapping the high-concentration region (61) in the plan view in a region closer than the first surface (20S) than the high-concentration region (61), and having a impurity concentration lower than that of the high-concentration region (61);
a separation region (65) provided at a position overlapping the high-concentration region (61) in the plan view in a region closer to the first surface (20S) than the high-concentration region (61) and electrically separating the first low-concentration region (62A) from the second low-concentration region (62B);
a first contact region (63A) of the second conductivity type provided in a surface layer portion of the first low-concentration region (62A);
a second contact region (63B) of the second conductivity type provided in a surface layer portion of the second low-concentration region (62B); and
an internal region (64) of the second conductivity type in contact with the high-concentration region (61) at a position overlapping the high-concentration region (61) in the plan view and closer to the second surface (20R) than the high-concentration region (61),
wherein the first reverse pin junction portion (60A) is formed of the high-concentration region (61), the first low-concentration region (62A), and the first contact region (63A),
the second reverse pin junction portion (60B) is formed of the high-concentration region (61), the second low-concentration region (62B), and the second contact region (63B), and
the pn junction portion (60E), connected in a reverse direction to the first reverse pin junction portion (60A) and the second reverse pin junction portion (60B), is formed of the high-concentration region (61) and the internal region (64).

### Appendix C13

The TVS diode according to Appendix C12, wherein an outer edge of the internal region (64) is located inward than an outer edge of the high-concentration region (61) in the plan view.

### Appendix C14

The TVS diode according to Appendix C13, wherein the outer edge of the internal region (64) is disposed at a position overlapping the separation region (65) in the plan view.

### Appendix C15

The TVS diode according to any one of Appendices C12 to C14, wherein the outer edge of the internal region (64) includes a plurality of corner portions in the plan view, and
each of the corner portions is curved in the plan view.

### Appendix C16

The TVS diode according to Appendix C7, wherein the semiconductor chip (20) includes:
a first separation trench (121A) provided on the first surface (20S) to partition the first pin junction portion (30) from the diode pair region (60); and
a second separation trench (121B) provided on the first surface (20S) to partition the second pin junction portion (40) from the diode pair region (60).

### Appendix C17

The TVS diode according to Appendix C16 including:
a first separation insulating layer (122A) provided in the first separation trench (121A); and
a second separation insulating layer (122B) provided in the second separation trench (121B).

### Appendix C18

The TVS diode according to Appendix C17 including:
a first separation electrode (123A) embedded in the first separation trench (121A) with the first separation insulating layer (122A) in between; and
a second separation electrode (123B) embedded in the second separation trench (121B) with the second separation insulating layer (122B) in between,
wherein both the first separation electrode (123A) and the second separation electrode (123B) are in an electrically floating state.

### Appendix C19

The TVS diode according to any one of Appendices C1 to C18, wherein the first polarity direction is the direction in which a forward current flows from the second surface (20R) to the first surface (20S) in the thickness direction (Z) of the semiconductor chip (20), and
the second polarity direction is the direction in which a forward current flows in the direction opposite to the first polarity direction in the thickness direction (Z) of the semiconductor chip (20).

### Appendix C20

The TVS diode according to any one of Appendices C7 to C18, wherein the semiconductor chip (20) includes:
a third pin junction portion (50) of the first polarity direction provided at a position spaced apart from both the first pin junction portion (30) and the second pin junction portion (40) in the plan view in a region close to the first surface (20S) of the semiconductor chip (20);
a third-terminal-side high-concentration region (51) of the second conductivity type provided at a position spaced apart from both the first-terminal-side high-concentration region (31) and the second-terminal-side high-concentration region (41) in the plan view at a position spaced apart from the first surface (20S) toward the second surface (20R);
a third-terminal-side low-concentration region (52) of the first conductivity type provided at a position overlapping the third-terminal-side high-concentration region (51) in the plan view in a region closer to the first surface (20S) than the third-terminal-side high-concentration region (51);
a third-terminal-side contact region (53) of the first conductivity type provided in a surface layer portion of the third-terminal-side low-concentration region (52); and
a third buffer region (55) of the first conductivity type in contact with the third-terminal-side high-concentration region (51) between the third-terminal-side high-concentration region (51) and the third-terminal-side low-concentration region (52) in the thickness direction (Z) of the semiconductor chip (20),
wherein the third pin junction portion (50) is formed of the third buffer region (55), the third-terminal-side low-concentration region (52), and the third-terminal-side contact region (53).

### Appendix C21

The TVS diode according to Appendix C20, wherein the semiconductor chip (20) includes a third partition region (54) provided to surround the third-terminal-side low-concentration region (52) at a position overlapping the high-concentration region (51) in the plan view in a region closer to the first surface (20S) than the third-terminal-side high-concentration region (51),
wherein the third partition region (54) is provided to surround the third buffer region (55) in the plan view.

### Appendix C22

The TVS diode according to Appendix C20 or C21, wherein the third buffer region (55) has a second conductivity type impurity concentration lower than that of the third-terminal-side high-concentration region (51).

### Appendix C23

The TVS diode according to Appendix C22, wherein the second conductivity type impurity concentration in the third buffer region (55) decreases from the third-terminal-side high-concentration region (51) toward the third-terminal-side low-concentration region (52) in the thickness direction (Z) of the semiconductor chip (20).

### Appendix C24

The TVS diode according to Appendix C23, wherein the second conductivity type impurity concentration in the third buffer region (55) is equal to or greater than the first conductivity type impurity concentration in the third-terminal-side low-concentration region (52).

### Appendix C25

The TVS diode according to any one of Appendices C20 to C24, wherein the diode pair region (60) includes:
a second reverse pin junction portion (60B) and a third reverse pin junction portion (60C) of the second polarity direction forming a diode pair with the pn junction portion (60E);
a high-concentration region (61) of the first conductivity type provided spaced apart from the first surface (20S) toward the second surface (20R) of the semiconductor chip (20);
a first low-concentration region (62A), a second low-concentration region (62B), and a third low-concentration region (62C) of the first conductivity type provided spaced apart from each other at a position overlapping the high-concentration region (61) in the plan view in a region closer to the first surface (20S) than the high-concentration region (61), and having a impurity concentration lower than that of the high-concentration region (61);
a separation region (65) provided at a position overlapping the high-concentration region (61) in the plan view in a region closer to the first surface (20S) than the high-concentration region (61) and electrically separating the first low-concentration region (62A), the second low-concentration region (62B), and the third low-concentration region (62C);
a first contact region (63A) of the second conductivity type provided in a surface layer portion of the first low-concentration region (62A);
a second contact region (63B) of the second conductivity type provided in a surface layer portion of the second low-concentration region (62B);
a third contact region (63C) of the second conductivity type provided in a surface layer portion of the third low-concentration region (62C); and
an internal region (64) of the second conductivity type in contact with the high-concentration region (61) at a position overlapping the high-concentration region (61) in the plan view and closer to the second surface (20R) than the high-concentration region (61),
wherein the first reverse pin junction portion (60A) is formed of the high-concentration region (61), the first low-concentration region (62A), and the first contact region (63A),
the second reverse pin junction portion (60B) is formed of the high-concentration region (61), the second low-concentration region (62B), and the second contact region (63B),
the third reverse pin junction portion (60C) is formed of the high-concentration region (61), the third low-concentration region (62C), and the third contact region (63C), and
the pn junction portion (60E), connected in a reverse direction to the first reverse pin junction portion (60A), the second reverse pin junction portion (60B), and the third reverse pin junction portion (60C), is formed of the high-concentration region (61) and the internal region (64).

The above illustration is merely exemplary. Those skilled in the art may recognize that, in addition to the components and methods (manufacturing processes) listed for the purpose of explaining the technology of the present disclosure, many more possible combinations and substitutions are possible. The present disclosure is intended to encompass all alternatives, modifications, and variations within the scope of the present disclosure, including the claims.

1. A TVS diode, comprising:
a semiconductor chip comprising a first surface and a second surface opposite to the first surface, the semiconductor chip including:
a first pin junction portion of a first polarity direction provided in a region close to the first surface of the semiconductor chip;
a diode pair region including a first reverse pin junction portion of a second polarity direction provided spaced apart from the first pin junction portion in a plan view when viewed from a thickness direction of the semiconductor chip, and a pn junction portion of the first polarity direction that forms a diode pair with the first reverse pin junction portion;
a first-terminal-side high-concentration region of a second conductivity type provided spaced apart from the first surface toward the second surface of the semiconductor chip;
a first-terminal-side low-concentration region of a first conductivity type provided at a position overlapping the first-terminal-side high-concentration region in the plan view in a region closer to the first surface than the first-terminal-side high-concentration region;
a first-terminal-side contact region of the first conductivity type provided in a surface layer portion of the first-terminal-side low-concentration region; and
a first buffer region of the second conductivity type in contact with the first-terminal-side high-concentration region between the first-terminal-side high-concentration region and the first-terminal-side low-concentration region in the thickness direction of the semiconductor chip,
wherein a pin diode is formed of the first-terminal-side contact region, the first-terminal-side low-concentration region, and the first buffer region.

2. The TVS diode of claim 1, wherein the semiconductor chip includes a first partition region provided to surround the first-terminal-side low-concentration region at a position overlapping the first-terminal-side high-concentration region in the plan view in a region closer to the first surface than the first-terminal-side high-concentration region,
wherein the first partition region is provided to surround the first buffer region in the plan view.

3. The TVS diode of claim 1, wherein the first buffer region has a second conductivity type impurity concentration lower than that of the first-terminal-side high-concentration region.

4. The TVS diode of claim 1, wherein a second conductivity type impurity concentration of the first buffer region decreases from the first-terminal-side high-concentration region toward the first-terminal-side low-concentration region in the thickness direction of the semiconductor chip.

5. The TVS diode of claim 3, wherein the second conductivity type impurity concentration of the first buffer region is equal to or higher than the first conductivity type impurity concentration of the first-terminal-side low-concentration region.

6. The TVS diode of claim 1, wherein the diode pair region includes:
a high-concentration region of the first conductivity type provided spaced apart from the first surface toward the second surface of the semiconductor chip;
a first low-concentration region of the first conductivity type provided at a position overlapping the high-concentration region in the plan view in a region closer to the first surface than the high-concentration region, and having an impurity concentration lower than that of the high-concentration region;
a first contact region of the second conductivity type provided in a surface layer portion of the first low-concentration region; and
an internal region of the second conductivity type in contact with the high-concentration region at a position overlapping the high-concentration region in the plan view and closer to the second surface than the high-concentration region,
wherein the first reverse pin junction portion is formed of the high-concentration region, the first low-concentration region, and the first contact region, and
the pn junction portion connected in a reverse direction to the first reverse pin junction portion is formed of the high-concentration region and the internal region.

7. The TVS diode of claim 1, wherein the semiconductor chip includes:
a second pin junction portion of the first polarity direction provided at a position spaced apart from the first pin junction portion in the plan view in a region close to the first surface of the semiconductor chip;
a second-terminal-side high-concentration region of the second conductivity type provided spaced apart from the first-terminal-side high-concentration region in the plan view and at a position spaced apart from the first surface toward the second surface of the semiconductor chip;
a second-terminal-side low-concentration region of the first conductivity type provided at a position overlapping the second-terminal-side high-concentration region in the plan view in a region closer to the first surface than the second-terminal-side high-concentration region;
a second-terminal-side contact region of the first conductivity type provided in a surface layer portion of the second-terminal-side low-concentration region; and
a second buffer region of the second conductivity type in contact with the second-terminal-side high-concentration region between the second-terminal-side high-concentration region and the second-terminal-side low-concentration region in the thickness direction of the semiconductor chip,
wherein the second pin junction portion is formed of the second buffer region, the second-terminal-side low-concentration region, and the second-terminal-side contact region.

8. The TVS diode of claim 7, wherein the semiconductor chip includes a second partition region provided to surround the second-terminal-side low-concentration region at a position overlapping the second-terminal-side high-concentration region in the plan view in a region closer to the first surface than the second-terminal-side high-concentration region,
wherein the second partition region is provided to surround the second buffer region in the plan view.

9. The TVS diode of claim 7, wherein the second buffer region has a second conductivity type impurity concentration lower than that of the second-terminal-side high-concentration region.

10. The TVS diode of claim 7, wherein a second conductivity type impurity concentration of the second buffer region decreases from the second-terminal-side high-concentration region toward the second-terminal-side low-concentration region in the thickness direction of the semiconductor chip.

11. The TVS diode of claim 9, wherein the second conductivity type impurity concentration of the second buffer region is equal to or higher than the first conductivity type impurity concentration of the second-terminal-side low-concentration region.

12. The TVS diode of claim 7, wherein the diode pair region includes:
a second reverse pin junction portion of the second polarity direction forming the diode pair with the pn junction portion;
a high-concentration region of the first conductivity type provided spaced apart from the first surface toward the second surface of the semiconductor chip;
a first low-concentration region and a second low-concentration region of the first conductivity type provided spaced apart from each other and at a position overlapping the high-concentration region in the plan view in a region closer to the first surface than the high-concentration region, and having an impurity concentration lower than that of the high-concentration region;
a separation region provided at a position overlapping the high-concentration region in the plan view in a region closer to the first surface than the high-concentration region and electrically separating the first low-concentration region from the second low-concentration region;
a first contact region of the second conductivity type provided in a surface layer portion of the first low-concentration region;
a second contact region of the second conductivity type provided in a surface layer portion of the second low-concentration region; and
an internal region of the second conductivity type in contact with the high-concentration region at a position overlapping the high-concentration region in the plan view closer to the second surface than the high-concentration region,
wherein the first reverse pin junction portion is formed of the high-concentration region, the first low-concentration region, and the first contact region,
the second reverse pin junction portion is formed of the high-concentration region, the second low-concentration region, and the second contact region, and
the pn junction portion connected in a reverse direction to the first reverse pin junction portion and the second reverse pin junction portion is formed of the high-concentration region and the internal region.

13. The TVS diode of claim 12, wherein an outer edge of the internal region is located inward from an outer edge of the high-concentration region in the plan view.

14. The TVS diode of claim 13, wherein the outer edge of the internal region is disposed at a position overlapping the separation region in the plan view.

15. The TVS diode of claim 12, wherein an outer edge of the internal region includes a plurality of corner portions in the plan view, and
each of the plurality of corner portions is curved in the plan view.

16. The TVS diode of claim 7, wherein the semiconductor chip includes:
a first separation trench provided on the first surface to partition the first pin junction portion from the diode pair region; and
a second separation trench provided on the first surface to partition the second pin junction portion from the diode pair region.

17. The TVS diode of claim 16, including:
a first separation insulating layer provided in the first separation trench; and
a second separation insulating layer provided in the second separation trench.

18. The TVS diode of claim 17, including:
a first separation electrode embedded in the first separation trench with the first separation insulating layer in between; and
a second separation electrode embedded in the second separation trench with the second separation insulating layer in between,
wherein both the first separation electrode and the second separation electrode are in an electrically floating state.

19. The TVS diode of claim 1, wherein
the first polarity direction is a direction in which a forward current flows from the second surface toward the first surface in the thickness direction of the semiconductor chip, and
the second polarity direction is a direction in which a forward current flows in a direction opposite to the first polarity direction in the thickness direction of the semiconductor chip.
